(19) United States
(12) Patent Application Publication
(10) Pub. No.: US 2026/0240032 A1
(43) Pub. Date: Aug. 13, 2026

(54) SEMICONDUCTOR SUBSTRATE

(71) Applicant: SONY SEMICONDUCTOR SOLUTIONS CORPORATION, KANAGAWA (JP)

(72) Inventors: HIROTAKA YOSHIOKA, KANAGAWA (JP); TAICHI YAMADA, KANAGAWA (JP); NOBUTOSHI FUJII, KANAGAWA (JP); SUGURU SAITO, KANAGAWA (JP); NAOKI KOMAI, KANAGAWA (JP); YURIKO MOMIUCHI, KANAGAWA (JP); JUN WATANABE, KANAGAWA (JP); TOKIHISA KANEGUCHI, KANAGAWA (JP); TATSUYA HORIKIRI, KANAGAWA (JP); KAN SHIMIZU, KANAGAWA (JP); KENGO KOTOO, KANAGAWA (JP); SHUNSUKE FURUSE, KANAGAWA (JP)

(21) Appl. No.: 19/153,566

(22) PCT Filed: Feb. 22, 2024
(86) PCT No.: PCT/JP2024/006446

§ 371 Date: Aug. 4, 2025

(30) Foreign Application Priority Data
Feb. 22, 2023 (JP) 2023-026277

(51) Int. Cl. H10W 72/90; H10W 90/00

(52) U.S. Cl. CPC H10W 72/923; H10W 72/934; H10W 72/952; H10W 90/792

(57) ABSTRACT

The present technique relates to a semiconductor substrate that makes it possible to suppress bonding defects in a configuration where two substrates are affixed. The semiconductor substrate includes: an insulating film; an electrode that is bonded to an electrode provided on another semiconductor substrate when the semiconductor substrate is affixed to the other semiconductor substrate, the electrode being provided in the insulating film; a barrier metal that is provided between the insulating film and the electrode; and a film that is provided between the barrier metal and the electrode. The present technique can be applied in a device in which a plurality of semiconductor substrates are stacked, e.g., an imaging device.

### TECHNICAL FIELD

The present technique relates to a semiconductor substrate, and relates, for example, to a semiconductor substrate which enables electrodes to be bonded to each other more reliably when two substrates are affixed.

### BACKGROUND ART

In a stacked image sensor, hybrid bonding is sometimes used to directly bond wafers to each other. In hybrid bonding, wafers are electrically bonded to each other by bonding metal connection pads formed in an interconnect layer (see PTL 1, for example).

### CITATION LIST

### Patent Literature

### [PTL 1]

### JP 2019-110260A

### SUMMARY

### Technical Problem

The connection pads are heat-treated after being overlaid on each other, and the metal constituting the connection pads expands during the heat treatment, which suppresses situations where the contact properties between the connection pads deteriorate. As miniaturization progresses, such connection pads are becoming smaller in size.

When the size of a connection pad is reduced, the capacitance of the metal constituting the connection pad decreases as well. Furthermore, when the capacitance of a metal decreases, the amount of expansion caused by the heat treatment decreases as well. Even when connection pads are miniaturized, it is desirable to ensure that the contact properties of the connection pad do not deteriorate.

Having been achieved in light of such circumstances, the present technique makes it possible to ensure that the contact properties of connection pads do not deteriorate.

### Solution to Problem

A first semiconductor substrate of one aspect of the present technique is a semiconductor substrate including: an insulating film; an electrode that is bonded to an electrode provided on another semiconductor substrate when the semiconductor substrate is affixed to the other semiconductor substrate, the electrode being provided in the insulating film; a barrier metal that is provided between the insulating film and the electrode; and a film that is provided between the barrier metal and the electrode.

A second semiconductor substrate of one aspect of the present technique is a semiconductor substrate including: an insulating film; an electrode that is bonded to an electrode provided on another semiconductor substrate when the semiconductor substrate is affixed to the other semiconductor substrate, the electrode being provided in the insulating film; and a barrier metal that is provided between the insulating film and the electrode, wherein an inclination of the barrier metal that is provided on one side wall of the electrode is different from an inclination of the barrier metal that is provided on another side wall of the electrode.

The first semiconductor substrate of one aspect of the present technique includes: an insulating film; an electrode that is bonded to an electrode provided on another semiconductor substrate when the semiconductor substrate is affixed to the other semiconductor substrate, the electrode being provided in the insulating film; a barrier metal that is provided between the insulating film and the electrode; and a film that is provided between the barrier metal and the electrode.

The second semiconductor substrate of one aspect of the present technique includes: an insulating film; an electrode that is bonded to an electrode provided on another semiconductor substrate when the semiconductor substrate is affixed to the other semiconductor substrate, the electrode being provided in the insulating film; and a barrier metal that is provided between the insulating film and the electrode, wherein an inclination of the barrier metal that is provided on one side wall of the electrode is different from an inclination of the barrier metal that is provided on another side wall of the electrode.

### BRIEF DESCRIPTION OF DRAWINGS

FIG. 1 is a diagram illustrating the configuration of one embodiment of an imaging device to which the present technique is applied.

FIG. 2 is a diagram illustrating an example of the cross-sectional configuration of a pixel.

FIG. 3 is a diagram illustrating interconnect connections.

FIG. 4 is a diagram illustrating an example of the configuration of a pixel according to Embodiment 1.

FIG. 5 is a diagram illustrating adhesion strength.

FIG. 6 is a diagram illustrating adhesion strength.

FIG. 7 is a diagram illustrating the manufacture of a pixel according to Embodiment 1.

FIG. 8 is a diagram illustrating an example of the configuration of a pixel according to Embodiment 2.

FIG. 9 is a diagram illustrating the manufacture of a pixel according to Embodiment 2.

FIG. 10 is a diagram illustrating an example of the configuration of a pixel according to Embodiment 3.

FIG. 11 is a diagram illustrating the manufacture of a pixel according to Embodiment 3.

FIG. 12 is a diagram illustrating an example of the configuration of a pixel according to Embodiment 4-1.

FIG. 13 is a diagram illustrating the manufacture of a pixel according to Embodiment 4-1.

FIG. 14 is a diagram illustrating an example of the configuration of a pixel according to Embodiment 4-2.

FIG. 15 is a diagram illustrating the manufacture of a pixel according to Embodiment 4-2.

FIG. 16 is a diagram illustrating an example of the configuration of a pixel according to Embodiment 5.

FIG. 17 is a diagram illustrating the manufacture of a pixel according to Embodiment 5.

FIG. 18 is a diagram illustrating an example of the configuration of a pixel according to Embodiment 6.

FIG. 19 is a diagram illustrating the manufacture of a pixel according to Embodiment 6.

FIG. 20 is a diagram illustrating an example of the configuration of a pixel according to Embodiment 7.

FIG. 21 is a diagram illustrating the manufacture of a pixel according to Embodiment 7.

FIG. 22 is a diagram illustrating the manufacture of a pixel according to Embodiment 7.

FIG. 23 is a diagram illustrating an example of the configuration of a pixel according to Embodiment 8.

FIG. 24 is a diagram illustrating an example of the configuration of a pixel according to Embodiment 8.

FIG. 25 is a diagram illustrating the manufacture of a pixel according to Embodiment 8.

FIG. 26 is a diagram illustrating the manufacture of a pixel according to Embodiment 8.

FIG. 27 is a diagram illustrating an example of the configuration of a pixel according to Embodiment 9.

FIG. 28 is a diagram illustrating the manufacture of a pixel according to Embodiment 9.

FIG. 29 is a diagram illustrating an example of the configuration of a pixel according to Embodiment 10.

FIG. 30 is a diagram illustrating an example of the configuration of a pixel according to Embodiment 10.

FIG. 31 is a diagram illustrating the manufacture of a pixel according to Embodiment 10.

FIG. 32 is a diagram illustrating the manufacture of a pixel according to Embodiment 10.

FIG. 33 is a diagram illustrating an example of the configuration of a pixel according to Embodiment 11.

FIG. 34 is a diagram illustrating the manufacture of a pixel according to Embodiment 11.

FIG. 35 is a diagram illustrating recessing.

FIG. 36 is a diagram illustrating a structure that suppresses recessing.

FIG. 37 is a diagram illustrating an example of the configuration of a pixel according to Embodiment 12.

FIG. 38 is a diagram illustrating the manufacture of a pixel according to Embodiment 12.

FIG. 39 is a diagram illustrating an example of the configuration of a pixel according to Embodiment 13.

FIG. 40 is a diagram illustrating the manufacture of a pixel according to Embodiment 13.

FIG. 41 is a diagram illustrating the manufacture of a pixel according to Embodiment 13.

FIG. 42 is a diagram illustrating an example of the configuration of a pixel according to Embodiment 13.

FIG. 43 is a diagram illustrating an example of the configuration of a pixel according to Embodiment 14.

FIG. 44 is a diagram illustrating a function of an expansion support film.

FIG. 45 is a diagram illustrating the manufacture of a pixel according to Embodiment 14.

FIG. 46 is a diagram illustrating an example of the cross-sectional configuration of a pixel according to Embodiment 15.

FIG. 47 is a diagram illustrating an example of the planar configuration of a pixel according to Embodiment 15.

FIG. 48 is a diagram illustrating a function of an expansion support film.

FIG. 49 is a diagram illustrating another example of the cross-sectional configuration of a pixel according to Embodiment 15.

FIG. 50 is a diagram illustrating another example of the cross-sectional configuration of a pixel according to Embodiment 15.

FIG. 51 is a diagram illustrating the manufacture of a pixel according to Embodiment 15.

FIG. 52 is a diagram illustrating the manufacture of a pixel according to Embodiment 15.

FIG. 53 is a diagram illustrating an example of the cross-sectional configuration of a pixel according to Embodiment 16.

FIG. 54 is a diagram illustrating an example of the planar configuration of a pixel according to Embodiment 16.

FIG. 55 is a diagram illustrating another example of the planar configuration of a pixel according to Embodiment 16.

FIG. 56 is a diagram illustrating the manufacture of a pixel according to Embodiment 16.

FIG. 57 is a diagram illustrating an orientation at an electrode bonding face.

FIG. 58 is a diagram illustrating an example of the configuration of a pixel according to Embodiment 17.

FIG. 59 is a diagram illustrating the configuration of a side wall and a bottom face of an electrode.

FIG. 60 is a diagram illustrating the manufacture of a pixel according to Embodiment 17.

FIG. 61 is a diagram illustrating another example of the manufacture of a pixel according to Embodiment 17.

FIG. 62 is a diagram illustrating an example of the configuration of a pixel according to Embodiment 18.

FIG. 63 is a diagram illustrating an orientation direction of an electrode.

FIG. 64 is a diagram illustrating the manufacture of a pixel according to Embodiment 18.

FIG. 65 is a diagram illustrating another example of the manufacture of a pixel according to Embodiment 18.

FIG. 66 is a diagram illustrating another example of the manufacture of a pixel according to Embodiment 18.

FIG. 67 is a diagram illustrating an example of the configuration of a pixel according to Embodiment 19.

FIG. 68 is a diagram illustrating the manufacture of a pixel according to Embodiment 19.

FIG. 69 is a diagram illustrating the manufacture of a pixel according to Embodiment 19.

FIG. 70 is a diagram illustrating, in detail, an example of the configuration of a pixel according to Embodiment 19.

FIG. 71 is a diagram illustrating an example of the cross-sectional configuration of a pixel according to Embodiment 20.

FIG. 72 is a diagram illustrating the manufacture of a pixel according to Embodiment 20.

FIG. 73 is a diagram illustrating an example of the cross-sectional configuration of a pixel according to Embodiment 20.

FIG. 74 is a diagram illustrating the manufacture of a pixel according to Embodiment 20.

FIG. 75 is a diagram illustrating an example of the cross-sectional configuration of a pixel according to Embodiment 20.

FIG. 76 is a diagram illustrating the manufacture of a pixel according to Embodiment 20.

FIG. 77 is a diagram illustrating an example of the cross-sectional configuration of a pixel according to Embodiment 20.

FIG. 78 is a diagram illustrating an example of the cross-sectional configuration of a pixel according to Embodiment 20.

FIG. 79 is a diagram illustrating an example of the cross-sectional configuration of a pixel according to Embodiment 21.

FIG. 80 is a diagram illustrating the bonding of a pixel according to Embodiment 21.

FIG. 81 is a diagram illustrating the manufacture of a pixel according to Embodiment 21.

FIG. 82 is a diagram illustrating the manufacture of a pixel according to Embodiment 21.

FIG. 83 is a diagram illustrating the manufacture of a pixel according to Embodiment 21.

FIG. 84 is a diagram illustrating an example of the cross-sectional configuration of a pixel according to Embodiment 21.

FIG. 85 is a diagram illustrating the manufacture of a pixel according to Embodiment 21.

FIG. 86 is a diagram illustrating the manufacture of a pixel according to Embodiment 21.

FIG. 87 is a diagram illustrating the shape of patterning.

FIG. 88 is a diagram illustrating an example of the cross-sectional configuration of a pixel according to Embodiment 22.

FIG. 89 is a diagram illustrating the bonding of a pixel according to Embodiment 22.

FIG. 90 is a diagram illustrating the manufacture of a pixel according to Embodiment 22.

FIG. 91 is a diagram illustrating the manufacture of a pixel according to Embodiment 22.

FIG. 92 is a diagram illustrating the manufacture of a pixel according to Embodiment 22.

FIG. 93 is a diagram illustrating the manufacture of a pixel according to Embodiment 22.

FIG. 94 is a diagram illustrating an example of the cross-sectional configuration of a pixel according to Embodiment 22.

FIG. 95 is a diagram illustrating the manufacture of a pixel according to Embodiment 22.

FIG. 96 is a diagram illustrating the manufacture of a pixel according to Embodiment 22.

FIG. 97 is a diagram illustrating an example of the configuration of an electronic device.

FIG. 98 is a diagram illustrating an example of the schematic configuration of an endoscopic surgery system.

FIG. 99 is a block diagram illustrating an example of the functional configuration of a camera head and a CCU.

FIG. 100 is a block diagram illustrating an example of the overall configuration of a vehicle control system.

FIG. 101 is an explanatory diagram illustrating an example of installation positions of a vehicle exterior information detecting unit and an imaging unit.

### DESCRIPTION OF EMBODIMENTS

Modes for carrying out the present technique (hereinafter referred to as embodiment) will be described below.

### Example of Overall Configuration of Imaging Device

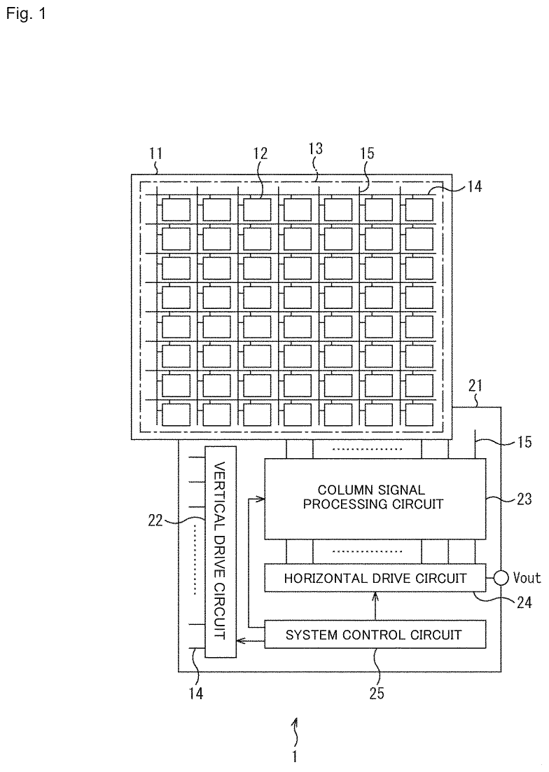

FIG. 1 is a diagram illustrating the configuration of one embodiment of an imaging device to which the present technique is applied. In FIG. 1, an imaging device 1 is a three-dimensional semiconductor device constituted by a first substrate 11 serving as a sensor substrate, and a second substrate 21, serving as a circuit substrate, which is affixed to the first substrate 11 so as to be stacked thereon. The imaging device 1 is configured as an image sensor such as a Complementary Metal Oxide Semiconductor (CMOS) image sensor, for example.

In the imaging device 1, a pixel region 13, in which a plurality of pixels 12, each including a photoelectric conversion unit, are arranged with regularity in two dimensions, is provided in the first substrate 11. In the pixel region 13, a plurality of pixel drive lines 14 are provided in a row direction, a plurality of vertical signal lines 15 are provided in a column direction, and a single pixel 12 is provided so as to be connected to a single pixel drive line 14 and a single vertical signal line 15.

Each pixel 12 is provided with a photoelectric conversion unit, a floating diffusion (FD) region, and a pixel circuit constituted by a plurality of pixel transistors and the like. Note that a plurality of pixels 12 may share a part of a pixel circuit. On the other hand, peripheral circuits such as a vertical drive circuit 22, a column signal processing circuit 23, a horizontal drive circuit 24, and a system control circuit 25 are provided in the second substrate 21.

### Example of Imaging Device

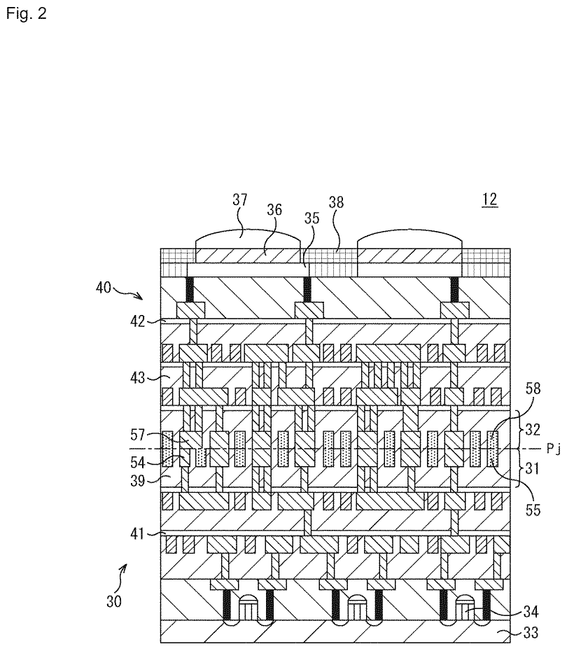

FIG. 2 is a diagram illustrating an example of the cross-sectional configuration of the pixel 12 illustrated in FIG. 1. The pixel 12 includes a first semiconductor substrate 30, and a second semiconductor substrate 40 bonded to the first semiconductor substrate 30. The first semiconductor substrate 30 includes, for example, an Si substrate 33, and a transistor 34 formed on the Si substrate 33 from a complementary metal oxide semiconductor. A plurality of interconnect layers are stacked on the transistor 34, and a first interconnect layer 31 is formed at a position furthest from the substrate 33 (the uppermost layer). A diffusion prevention film 41 constituted by, for example, SiCN, SiN, or the like is provided between each of the interconnect layers.

A first electrode pad 54 constituted by, for example, Cu, and a dummy electrode 55 constituted by, for example, Cu, are disposed in the first interconnect layer 31. The first electrode pad 54 and the dummy electrode 55 are embedded in an interlayer insulating film 39 such as, for example, a low dielectric constant material such as organic silica glass, SiO2, or the like, and are located within the same plane on the side of the first electrode pad 54, the dummy electrode 55, and the interlayer insulating film 39 opposite from the side on which the Si substrate 33 is located. The first electrode pad 54 is connected by a via to an interconnect in the interconnect layer on the Si substrate 33 side.

On the other hand, the second semiconductor substrate 40 includes a photoelectric conversion layer 35 that outputs an electrical signal (a charge) according to an amount of light received, a color filter 36 disposed on the photoelectric conversion layer 35, and a microlens 37 disposed on the color filter 36. An insulating film 38 is formed on the photoelectric conversion layer 35 in the regions aside from the color filter 36. A single pixel is formed for each set of the photoelectric conversion layer 35, the color filter 36, and the microlens 37.

An interconnect layer is stacked on the surface of the photoelectric conversion layer 35 opposite from the side where the color filter 36 is located, and a second interconnect layer 32 is formed at the position furthest from the photoelectric conversion layer 35. A diffusion prevention film 42 constituted by, for example, SiCN or SiN is formed between the respective interconnect layers. The second interconnect layer 32 is constituted by an interlayer insulating film 43 such as, for example, a low dielectric constant material such as organic silica glass, SiO2, or the like, a second electrode pad 57, and a dummy electrode 58. The second electrode pad 57 and the dummy electrode 58 are embedded in the interlayer insulating film 43, and are located within the same plane on the side of the second electrode pad 57, the dummy electrode 58, and the interlayer insulating film 43 opposite from the side where the photoelectric conversion layer 35 is located.

The photoelectric conversion layer 35 is constituted by a photodiode or the like, for example. The transistor 34 provided on the second semiconductor substrate is what is known as a transfer transistor, a reset transistor, an amplifying transistor, or the like, and is used to calculate a charge output from the photoelectric conversion layer 35.

<Bonded Parts when Pumping Phenomenon Occurs>

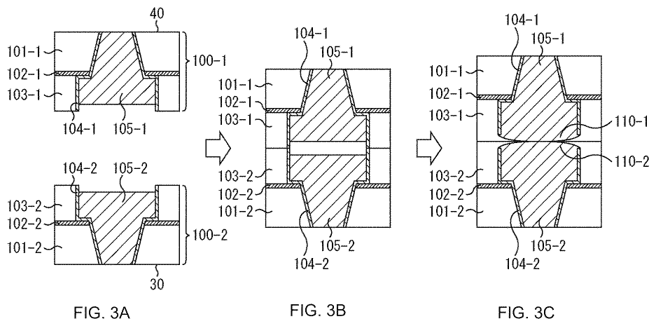

FIG. 3 is a cross-sectional view illustrating the state of the electrode bonded parts at the time of a pumping phenomenon when two substrates, e.g., the first semiconductor substrate 30 and the second semiconductor substrate 40, are affixed to each other. The bonded part between the first electrode pad 54 and the second electrode pad 57 will be described with reference to FIG. 3.

As illustrated in A in FIG. 3, of the two substrates to be affixed, a stacked film 100-1 in which an interlayer insulating film 101-1, a liner insulating film 102-1, and an interlayer insulating film 103-1 are stacked is formed on the substrate on the upper side (the second semiconductor substrate 40). An electrode 105-1 (e.g., corresponding to the first electrode pad 54) constituted by copper (Cu) is formed in the stacked film 100-1 as an electrode. A barrier metal 104-1 is formed between the stacked film 100-1 and the electrode 105-1.

As with the substrate on the upper side, copper (Cu) serving as an electrode 105-2 (e.g., corresponding to the second electrode pad 57) is formed in a stacked film 100-2 in which an interlayer insulating film 101-2 to an interlayer insulating film 103-2 are stacked on the substrate on the lower side (the first semiconductor substrate 30). A barrier metal 104-2 is formed between the stacked film 100-2 and the electrode 105-2.

Due to recessing, the electrode 105-1 is formed slightly recessed from the position of the bonding face. Likewise, due to recessing, the electrode 105-2 is formed slightly recessed from the position of the bonding face.

The structure of the bonded part between the two substrates after being affixed to each other is illustrated in B in FIG. 3. When heat treatment is performed in the state of the bonded part illustrated in B in FIG. 3, the bonded part enters the state illustrated in C in FIG. 3. In other words, a pumping phenomenon occurs due to the heat treatment, and the copper (Cu) serving as the electrodes 105-1 and 105-2 formed in the stacked films 100-1 and 100-2 of the upper and lower substrates expands (110-1 and 110-2 in the figure).

The electrode 105-1 and the electrode 105-2 are bonded using such a pumping phenomenon. Deterioration of the contact properties between the electrodes 105 can be suppressed by utilizing such thermal expansion of the electrodes 105. On the other hand, when the sizes of the electrodes 105 decreases due to the miniaturization of the pixel 12, the capacitance of the metal constituting the electrodes 105 decreases as well. When the capacitance of a metal decreases, the amount of expansion caused by the heat treatment decreases, which may cause bonding defects to occur.

When the electrodes 105 are miniaturized, the amount of the recessing also tends to increase. If the amount of recessing increases, the distance between the electrodes 105 of the two substrates when the substrates are affixed increases, and thus even if the electrodes 105 expand, the expansion will not compensate for the distance. The electrodes 105 will not be in contact with each other, which may cause bonding defects to occur.

An electrode structure that can suppress the occurrence of bonding defects will be described.

### Embodiment 1

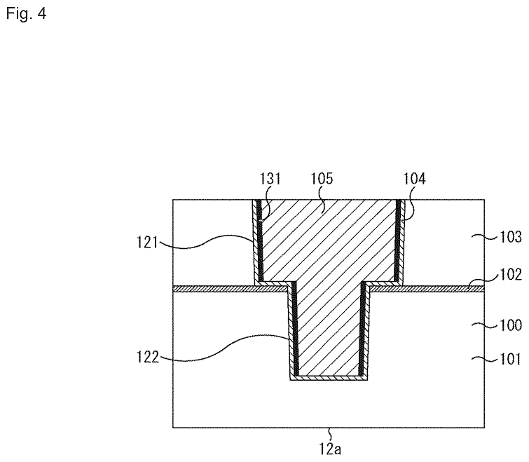

FIG. 4 is a diagram illustrating an example of the configuration of a pixel 12a according to Embodiment 1 in which the present technique is applied. FIG. 4 illustrates a single electrode constituting the pixel 12a, and illustrates an electrode (electrode pad) which is provided on a bonding face side where the first semiconductor substrate 30 and the second semiconductor substrate 40 are bonded, and which is bonded using the pumping phenomenon described above to make the first semiconductor substrate 30 and the second semiconductor substrate 40 conductive.

Although an electrode will be described here as an example, the present technique described below can be applied not only to an electrode having a function for conducting, but also to a bonding member that lacks a function for conducting but that bonds semiconductor substrates to each other.

As an example, the following will describe an electrode provided in the imaging device 1, which includes the pixel 12 having a stacked structure in which the first semiconductor substrate 30 and the second semiconductor substrate 40 are bonded, as illustrated in FIG. 2. However, the present technique described below is not only applicable when configuring such an imaging device 1, but can be widely applied in devices having a stacked structure. The present technique can also be applied to a single substrate that is to be laminated. In other words, the present technique can be applied to an electrode provided in a semiconductor substrate prior to being stacked.

As illustrated in FIG. 4, the electrode formed at the bonded part is configured by forming an electrode 105 in a stacked film 100 in which an interlayer insulating film 101, a liner insulating film 102, and an interlayer insulating film 103 are stacked.

The electrode 105 illustrated in FIG. 4 has a shape based on the dual damascene process, and is configured to have a connection hole 121 and an interconnect hole 122. As will be described later, the present technique can be applied to an electrode having a shape based on a single damascene process, and can also be applied in a configuration having only a connection hole.

A barrier metal 104 and an expansion inhibition suppression film 131 are formed between the stacked film 100 and the electrode 105. More specifically, the barrier metal 104 and the expansion inhibition suppression film 131 are formed between the stacked film 100 and the electrode 105 on side face of each of the connection hole 121 and the interconnect hole 122. The barrier metal 104 is formed between the stacked film 100 and the electrode 105 on a bottom face of each of the connection hole 121 and the interconnect hole 122.

The expansion inhibition suppression film 131 is a film formed of a material that does not inhibit thermal expansion of the material constituting the electrode 105 during heat treatment.

For example, as illustrated in FIG. 3, if only the barrier metal 104 is formed between the stacked film 100 and the electrode 105, the barrier metal 104 may inhibit the expansion of the electrode 105, and the amount of expansion of the electrode 105 may be reduced as a result. If the adhesion between the barrier metal 104 and the electrode 105 is high, the force of the expansion of the electrode 105 in the upward direction in FIG. 4 may be suppressed and weakened by the barrier metal 104, and the expansion may be insufficient.

However, the expansion inhibition suppression film 131 is provided between the barrier metal 104 and the electrode 105, and the structure is therefore such that the barrier metal 104 does not inhibit the expansion of the electrode 105. Reducing the adhesion strength between the expansion inhibition suppression film 131 and the electrode 105 suppresses situations where the force of the expansion of the electrode 105 in the upward direction in FIG. 4 is suppressed and weakened by the expansion inhibition suppression film 131, which enables sufficient expansion.

Indium Tin Oxide (ITO), SiO2 by plasma deposition, SiO formed through Atomic Layer Deposition (ALD), and the like can be used as the expansion inhibition suppression film 131, for example.

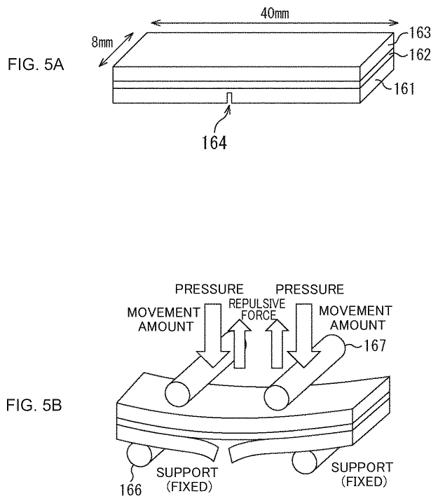

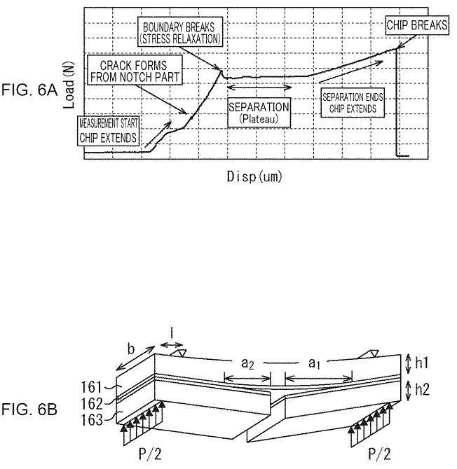

The adhesion strength between a material A and a material B can be determined as follows, for example. An example of calculating the adhesion strength through a method called 4 Point Bending (PB) will be given here as an example, which will be described with reference to FIGS. 5 and 6.

As illustrated in A in FIG. 5, a sample substrate is prepared in which a material used as the expansion inhibition suppression film 131 (an evaluation material 162) is formed on a Cu substrate 161. A silicon substrate 162 is adhered to the material 162 side of the sample substrate using an epoxy bonding agent, for example. The sample substrate is cut out to a size of 8 mm×40 mm, for example. Using a dicer, a notch 164 is formed on the sample substrate side of the sample substrate on which the silicon substrate 162 is stacked.

As illustrated in B in FIG. 5, the sample substrate in which the notch 164 has been formed is set in a measurement instrument, and measurement is started. The evaluation material 162 side of the sample substrate is oriented on the lower side, and is supported by two fixed supports 166, after which pressure is applied by two blades 167 from the top of the silicon substrate 162. The amount of movement of the blades 167 and the repulsive force of the blades 167 at this time are measured.

A in FIG. 6 illustrates an example of measurement results when such a measurement is performed. In the graph in A in FIG. 6, the vertical axis represents the repulsive force (N), and the horizontal axis represents the amount of movement (um). Although specific values are not given, first, when the measurement is started, a chip extends, and after some time, a crack begins to form from the area where the notch is located. As the blades 167 move further, the interface breaks (the stress relaxes), after which separation occurs.

In this state of separation, the repulsive force remains constant for a period of time even as the blades 167 move. When the separation ends, the repulsive force increases as the blades 167 move until the chip breaks. Using such measurement results, the adhesion strength (G value) is determined on the basis of the following Formula (1).

$$\begin{matrix}[ Math . 1 ] & \\ G = 3 {I}^{2} \frac{( 1 - {v}^{2} )}{2 E} {( \frac{P}{b} )}^{2} ( \frac{1}{{h}_{2}^{3}} - \frac{1}{{( {h}_{1} + {h}_{2} )}^{3}} ) & ( 1 )\end{matrix}$$

In Formula (1), E represents a physical property value of the epoxy resin, v represents a physical property value of the silicon substrate 163, and P represents the value of the repulsive force of the separated part obtained from the measurement results. b represents the width of the sample substrate, which is 8 mm here. h1 represents the thickness of the Cu substrate 161, h2 represents the thickness of the evaluation material 162, and 1 represents the distance from the end of the sample substrate to the supports 166, which is set to 11.4 mm, for example.

An evaluation material 162 for which the G value (N/m) obtained from Formula (1) is not greater than a predetermined value can be used as the expansion inhibition suppression film 131. For example, when the evaluation material 162 formed on the Cu substrate 161 is SiO, the G value is 1 to 6 N/m.

Although Ti (titanium), W (tungsten), or the like, for example, can be used as the barrier metal 104, it has been confirmed that when titanium or tungsten is used as the evaluation material 162, and the G value is calculated after forming the Cu substrate 161, the G value will be at least 25 N/m. It has also been confirmed that when the G value is calculated using a sample substrate in which titanium, tungsten, or the like is used instead of the Cu substrate 161 and SiO is formed on the titanium, the tungsten, or the like, the G value will be at least 25 N/m.

On the basis of this, for example, with the electrode constituted by the barrier metal 104 and the electrode 105 illustrated in FIG. 3, the adhesion strength between the barrier metal 104 and the electrode 105 is 25 N/m, which is a high adhesion strength. As such, when the copper (Cu) constituting the electrode 105 expands, the expansion force may be suppressed by the barrier metal 104.

On the other hand, when the expansion inhibition suppression film 131 is provided between the barrier metal 104 and the electrode 105 as illustrated in FIG. 4, the adhesion strength between the expansion inhibition suppression film 131 and the electrode 105 can be reduced. For example, when using SiO as the expansion inhibition suppression film 131, the adhesion strength between the expansion inhibition suppression film 131 and the electrode 105, which in this case is the adhesion strength between SiO and copper (Cu), is reduced, i.e., is about 1 to 6 N/m. Accordingly, when the copper (Cu) constituting the electrode 105 expands, the force of the expansion can be prevented from being suppressed by the expansion inhibition suppression film 131.

Forming the expansion inhibition suppression film 131 from a material having a low adhesion strength with the material of the electrode 105 between the barrier metal 104 and the electrode 105 in this manner makes it possible to allow the electrode 105 to expand without the expansion of the electrode 105 being inhibited during thermal expansion. This in turn makes it possible to suppress the occurrence of bonding defects.

Because a material having a lower adhesion strength in relation to the material of the electrode 105 is used as the expansion inhibition suppression film 131, an expansion inhibition suppression film 131 appropriate in the combination is suitably selected according to the material of the electrode 105. Metals such as Cu, Ag, Au, Be, Al, Zn, Sn, Ni, Pb, Co, Ru, Mo, W, Ta, Ti, and the like, as well as metals such as duralumin and bronze, which are alloys taking Cu or Al as their principal components, can be used as the material of the electrode 105. The material of the expansion inhibition suppression film 131 suitable for the material used may be set according to which of these materials is used as the electrode 105.

An example in which a material that reduces the adhesion strength with the electrode 105 is used as the expansion inhibition suppression film 131 has been described here. However, a material having a low coefficient of friction can also be used as the expansion inhibition suppression film 131.

Consider again a case where only the barrier metal 104 is formed between the stacked film 100 and the electrode 105 as illustrated in FIG. 3. With the configuration of the electrode 105 illustrated in FIG. 3, the barrier metal 104 may inhibit the expansion of the electrode 105, and the amount of expansion of the electrode 105 may decrease as a result. If the friction of the barrier metal 104 with respect to the electrode 105 is high, the force of the expansion of the electrode 105 in the upward direction in FIG. 4 may be suppressed and weakened by the barrier metal 104, and the expansion may be insufficient.

The expansion inhibition suppression film 131 is provided between the barrier metal 104 and the electrode 105, making it difficult for friction to arise between the expansion inhibition suppression film 131 and the electrode 105 to provide a structure in which the barrier metal 104 does not inhibit the expansion of the electrode 105. This in turn suppresses a situation where the force of the expansion of the electrode 105 in the upward direction in FIG. 4 is suppressed and weakened by the expansion inhibition suppression film 131, which enables sufficient expansion to be achieved.

Carbon (C), molybdenum disulfide (MoS2), or the like can be used as the expansion inhibition suppression film 131, for example.

For example, tantalum (Ta) can be used as the barrier metal 104, but the coefficient of friction of tantalum is about 0.58. In such a case, a material having a coefficient of friction of no greater than 0.58 can be used as the expansion inhibition suppression film 131. For example, the coefficient of friction of carbon (C) is about 0.10 to 0.15, which is less than 0.58, and carbon (C) is therefore suitable for use as the expansion inhibition suppression film 131. For example, the coefficient of friction of molybdenum disulfide (MoS2) is about 0.04, which is less than 0.58, and molybdenum disulfide (MoS2) is therefore suitable for use as the expansion inhibition suppression film 131.

In addition to carbon (C) and molybdenum disulfide (MoS2), tungsten disulfide (WS2), tungsten selenide (WSe2), hafnium sulfide (HfS2), boron nitride (BN), or materials such as graphite, graphene, fullerene, carbon nanotubes, diamond-like carbon, and diamond, which are compositions having carbon as the principal component, can be used as the material of the expansion inhibition suppression film 131. A material having a coefficient of static friction of no greater than 0.2 (u) can be used as the material of the expansion inhibition suppression film 131, for example.

Referring to FIG. 4, providing the expansion inhibition suppression film 131 between the barrier metal 104 and the electrode 105 can, when the force of what is upward expansion in the figure is occurring in the electrode 105, prevent the expansion inhibition suppression film 131 from suppressing that upward force. Accordingly, the expansion of the electrode 105 is not inhibited, and the bonding with the electrode provided on the substrate to be affixed can be performed without problems.

Because the expansion inhibition suppression film 131 is not formed on the bottom face of the interconnect hole 122 in the configuration illustrated in FIG. 4, a non-conductive material can be used as the material of the expansion inhibition suppression film 131, in addition to a conductive material.

### Manufacture According to Embodiment 1

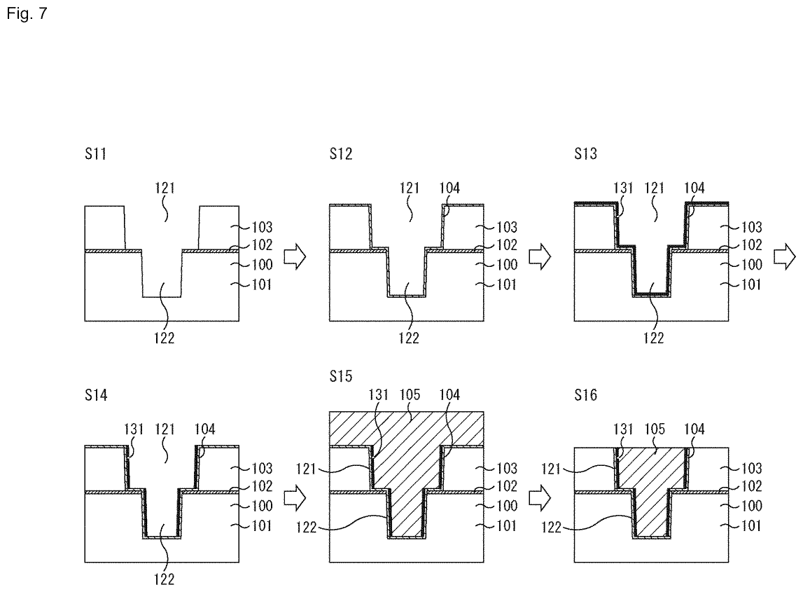

The manufacture of the pixel 12a having the configuration of the electrode 105 illustrated in FIG. 4 will be described with reference to FIG. 7. The manufacture of the part of the electrode 105 will be described with reference to FIG. 7.

In step S11, a substrate is prepared in which the stacked film 100 is formed, with the interlayer insulating film 101, the liner insulating film 102, and the interlayer insulating film 103 stacked therein. The connection hole 121 and the interconnect hole 122 are formed by etching the stacked film 100.

For example, in a photolithography step, a photoresist is applied to generate a resist pattern for forming the interconnect hole 122 (patterning). An etching step is performed, and dry etching is performed using the resist pattern generated in the photolithography step as a mask, which forms the interconnect hole 122. The connection hole 121 can be formed by repeating the same processing.

In step S12, the barrier metal 104 is formed by sputtering, for example. The barrier metal 104 is formed on the side faces and the bottom faces of the connection hole 121 and the interconnect hole 122, and is also formed on a top face of the interlayer insulating film 103.

In step S13, the expansion inhibition suppression film 131 is formed on the barrier metal 104. The expansion inhibition suppression film 131 can also be formed by sputtering. If a material having a low adhesion strength, such as an oxide film, is used as the expansion inhibition suppression film 131, the oxide film is formed in step S13. If a material having a low coefficient of friction, such as carbon, is used as the expansion inhibition suppression film 131, a carbon film is formed in step S13.

In step S14, the expansion inhibition suppression film 131 is removed by an etch-back process. Because the expansion inhibition suppression film 131 is removed by the etch-back process, the expansion inhibition suppression film 131 on the interlayer insulating film 103, the expansion inhibition suppression film 131 on the bottom face of the connection hole 121, and the expansion inhibition suppression film 131 on the bottom face of the interconnect hole 122 are removed. In other words, the expansion inhibition suppression film 131 formed in regions other than the expansion inhibition suppression film 131 on the side face of the connection hole 121 and the side face of the interconnect hole 122 is removed.

In step S15, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S16, the Cu is polished and flattened. This step removes excess Cu and the barrier metal 104 on the top face of the interlayer insulating film 103 through Chemical Mechanical Planarization (CMP).

An electrode including the expansion inhibition suppression film 131 illustrated in FIG. 4 can be formed through the foregoing steps.

Although an example in which sputtering is used to form the barrier metal 104 and the expansion inhibition suppression film 131 has been described here, the method for forming the films is not limited to sputtering. For example, plasma CVD (Plasma Enhanced CVD; PECVD), thermal CVD (Thermal CVD; TCVD) using heat, optical CVD (Photo CVD) using light, metal CVD (Metal CVD; MCVD), organic metal CVD (Metal Organic CVD; MOCVD), and the like, which are examples of chemical vapor deposition (CVD); molecular beam epitaxy (MBE); pulsed laser deposition (PLD); atomic layer deposition (ALD); or the like can also be used to form the film. These methods can be applied as appropriate in the following descriptions as well.

### Embodiment 2

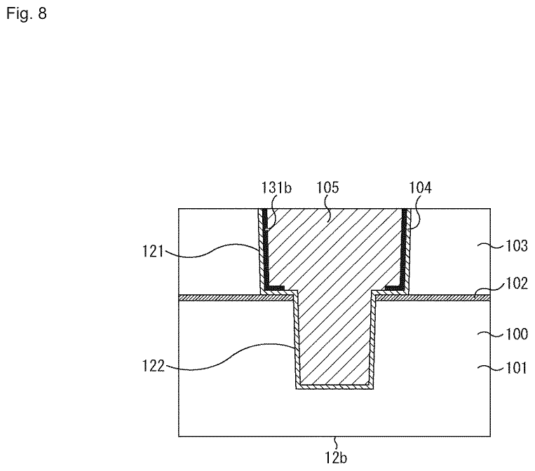

FIG. 8 is a diagram illustrating an example of the configuration of a pixel 12b according to Embodiment 2 in which the present technique is applied. Parts that are the same between the pixel 12b according to Embodiment 2, illustrated in FIG. 8, and the pixel 12a according to Embodiment 1, illustrated in FIG. 4, will be given the same reference signs, and descriptions thereof will be omitted as appropriate.

When comparing the pixel 12b according to Embodiment 2, illustrated in FIG. 8, and the pixel 12a according to Embodiment 1, illustrated in FIG. 4, the region in which an expansion inhibition suppression film 131b of the pixel 12b is formed is different from the region in which the expansion inhibition suppression film 131 of the pixel 12a is formed. The other points are the same.

The expansion inhibition suppression film 131b of the pixel 12b illustrated in FIG. 8 is provided on the side face of the connection hole 121, but is not provided on the side face of the interconnect hole 122. The expansion inhibition suppression film 131b of the pixel 12b illustrated in FIG. 8 is also provided on part of the bottom face of the connection hole 121. Note that the configuration may be such that the expansion inhibition suppression film 131b is not provided on the bottom face of the connection hole 121.

When the copper (Cu) mainly within the connection hole 121 expands during heat treatment and is bonded to another electrode 105, the configuration can be such that the expansion of the copper within the connection hole 121 is not inhibited. A configuration including the electrode 105 illustrated in FIG. 8 can be applied as such a configuration.

In the configuration illustrated in FIG. 8, the copper of the electrode 105 in the connection hole 121 is in contact with the expansion inhibition suppression film 131b. The expansion inhibition suppression film 131b is constituted by a material having a low adhesion strength or a material having a low coefficient of friction, as in Embodiment 1. Accordingly, the expansion inhibition suppression film 131b does not inhibit the expansion of the copper of the electrode 105 within the connection hole 121 during the heat treatment. The expansion of the electrode 105 is therefore not inhibited, and the bonding with the electrode provided on the substrate to be affixed can be performed without problems.

### Manufacture According to Embodiment 2

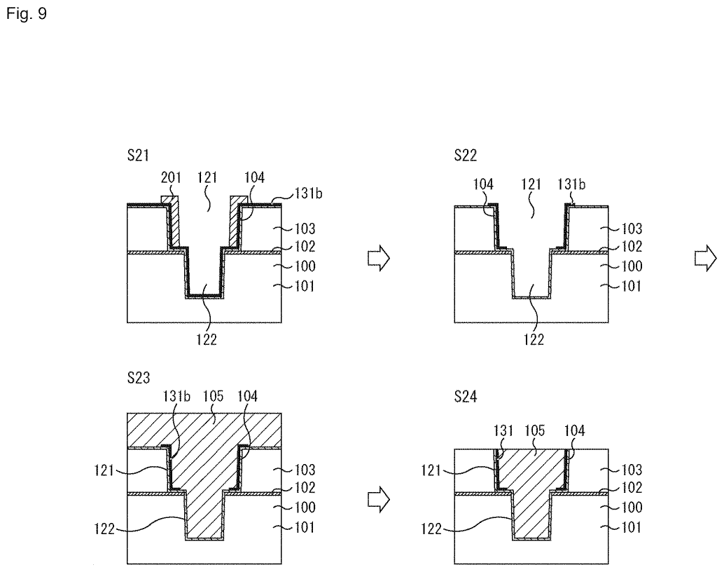

The manufacture of the pixel 12a having the configuration of the electrode 105 illustrated in FIG. 8 will be described with reference to FIG. 9. The manufacture of the part of the electrode 105 will be described with reference to FIG. 9.

In step S21, a substrate is prepared in which the stacked film 100 is formed, with barrier metal 104 and the expansion inhibition suppression film 131b formed therein. By executing steps S11, S12, and S13 described with reference to FIG. 7, the barrier metal 104 and the expansion inhibition suppression film 131b are formed in the connection hole 121 and the interconnect hole 122 in the steps before step S21.

In step S21, for example, in a photolithography step, a photoresist is applied to generate a resist pattern 201 that masks the region to be left as the expansion inhibition suppression film 131b (patterning).

In step S22, an etching step is performed, and dry etching is performed using the resist pattern 201 as a mask, which removes the expansion inhibition suppression film 131b other than that located on the side walls in the connection hole 121, and forms the expansion inhibition suppression film 131b on the side walls in the connection hole 121.

As indicated in the depiction of step S21, the resist 201 is applied to the side face and part of the bottom face of the connection hole 121, and to part of the top face of the stacked film 100. Accordingly, as indicated in the depiction of step S22, the expansion inhibition suppression film 131b is formed on the side face and part of the bottom face of the connection hole 121, and on part of the top face of the stacked film 100.

In step S23, the material of the electrode 105, e.g., copper (Cu), is embedded in the connection hole 121 and the interconnect hole 122. In step S24, the Cu is polished and flattened. Steps S23 and S24 are basically the same steps as steps S15 and S16 (FIG. 7).

An electrode including the expansion inhibition suppression film 131b illustrated in FIG. 8 can be formed through the foregoing steps.

### Embodiment 3

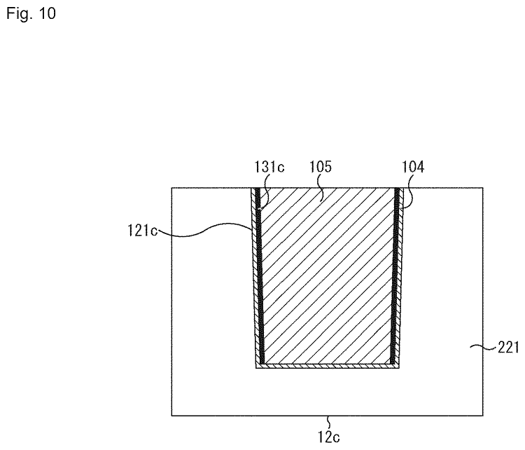

FIG. 10 is a diagram illustrating an example of the configuration of a pixel 12c according to Embodiment 3 in which the present technique is applied. Parts that are the same between the pixel 12c according to Embodiment 3, illustrated in FIG. 10, and the pixel 12a according to Embodiment 1, illustrated in FIG. 4, will be given the same reference signs, and descriptions thereof will be omitted as appropriate.

Although the pixel 12a according to Embodiment 1, illustrated in FIG. 4, has a dual damascene structure, the pixel 12c according to Embodiment 3, illustrated in FIG. 10, has a single damascene structure.

As illustrated in FIG. 10, in the electrode formed at the bonded part, a connection hole 121c is provided in an insulating film 221, and the barrier metal 104 is formed on the side face and the bottom face of the connection hole 121c. The expansion inhibition suppression film 131 is formed on the barrier metal 104 formed on the side face of the connection hole 121c.

The expansion inhibition suppression film 131c is a film formed of a material that does not inhibit thermal expansion of the material constituting the electrode 105 during heat treatment, and is constituted by a material having a low adhesion strength or a material having a low coefficient of friction, as in Embodiment 1. Accordingly, the expansion inhibition suppression film 131c does not inhibit the expansion of the copper of the electrode 105 within the connection hole 121c during the heat treatment. The expansion of the electrode 105 is therefore not inhibited, and the bonding with the electrode provided on the substrate to be affixed can be performed without problems.

### Manufacture According to Embodiment 3

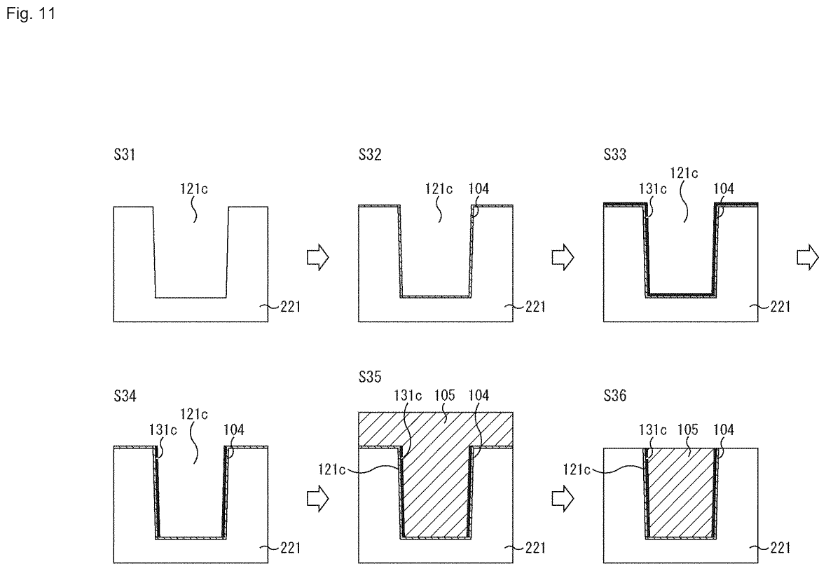

The manufacture of the pixel 12c having the configuration of the electrode 105 illustrated in FIG. 10 will be described with reference to FIG. 11. The manufacture of the part of the electrode 105 will be described with reference to FIG. 11.

In step S31, a semiconductor substrate in which the connection hole 121c is formed in the insulating film 221 is prepared. The connection hole 121c is formed by etching the semiconductor substrate. For example, in a photolithography step, a photoresist is applied to generate a resist pattern for forming the connection hole 121c. Dry etching is performed using the generated resist pattern as a mask, which forms the connection hole 121c.

In step S32, the barrier metal 104 is formed by sputtering, for example. The barrier metal 104 is formed on the side face and the bottom face of the connection hole 121c, and is also formed on a top face of the insulating film 221.

In step S33, the expansion inhibition suppression film 131c is formed on the barrier metal 104. The expansion inhibition suppression film 131c can also be formed by sputtering. If a material having a low adhesion strength, such as an oxide film, is used as the expansion inhibition suppression film 131c, the oxide film is formed in step S33. If a material having a low coefficient of friction, such as carbon, is used as the expansion inhibition suppression film 131c, a carbon film is formed in step S33.

In step S34, the extra expansion inhibition suppression film 131c is removed by an etch-back process. Because the expansion inhibition suppression film 131c is removed by the etch-back process, the expansion inhibition suppression film 131c on the interlayer insulating film 103 and the expansion inhibition suppression film 131c on the bottom face of the connection hole 121c are removed. In other words, the expansion inhibition suppression film 131c formed in regions other than the expansion inhibition suppression film 131c on the side face of the connection hole 121 is removed.

In step S35, the material of the electrode 105, e.g., copper (Cu), is embedded in the connection hole 121c. The electrode 105, constituted by copper (Cu), is embedded in the connection hole 121c by Cu sputtering followed by Cu plating.

In step S36, the Cu is polished and flattened. This step removes the excess part of the Cu and the barrier metal 104 on the top face of the insulating film 221 through Chemical Mechanical Planarization (CMP).

An electrode including the expansion inhibition suppression film 131c illustrated in FIG. 10 can be formed through the foregoing steps.

### Embodiment 4-1

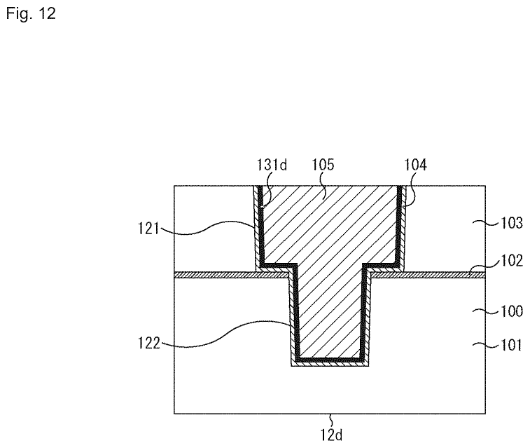

FIG. 12 is a diagram illustrating an example of the configuration of a pixel 12d according to Embodiment 4-1 in which the present technique is applied. Parts that are the same between the pixel 12d according to Embodiment 4-1, illustrated in FIG. 12, and the pixel 12a according to Embodiment 1, illustrated in FIG. 4, will be given the same reference signs, and descriptions thereof will be omitted as appropriate.

When comparing the pixel 12d according to Embodiment 4-1, illustrated in FIG. 12, and the pixel 12a according to Embodiment 1, illustrated in FIG. 4, the region in which an expansion inhibition suppression film 131d of the pixel 12d is formed is different from the region in which the expansion inhibition suppression film 131 of the pixel 12a is formed. The other points are the same.

Unlike the pixel 12a according to Embodiment 1 illustrated in FIG. 4, the expansion inhibition suppression film 131d of the pixel 12d illustrated in FIG. 12 is provided on the bottom face of the connection hole 121 and the bottom face of the interconnect hole 122, but the other points are the same. The expansion inhibition suppression film 131d of the pixel 12d illustrated in FIG. 12 is provided on the side face and the bottom face of the connection hole 121, and the side face and the bottom face of the interconnect hole 122.

In the configuration illustrated in FIG. 12, the expansion inhibition suppression film 131d is formed in the connection hole 121 and the interconnect hole 122. The copper of the electrode 105 is in contact with the expansion inhibition suppression film 131d, but is not in contact with the barrier metal 104. The expansion inhibition suppression film 131d is constituted by a material having a low adhesion strength or a material having a low coefficient of friction, as in Embodiment 1. However, when the expansion inhibition suppression film 131d is also formed on the bottom face of the interconnect hole 122, as with the pixel 12d illustrated in FIG. 12, a conductive material is used as the material of the expansion inhibition suppression film 131d.

In the configuration illustrated in FIG. 12 too, the expansion inhibition suppression film 131d does not inhibit the expansion of the copper of the electrode 105 during the heat treatment. The expansion of the electrode 105 is therefore not inhibited, and the bonding with the electrode provided on the substrate to be affixed can be performed without problems.

### Manufacture According to Embodiment 4-1

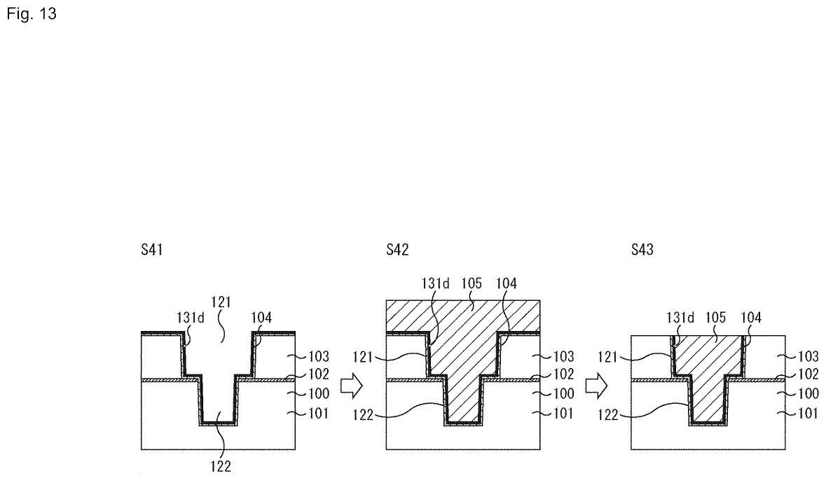

The manufacture of the pixel 12d having the configuration of the electrode 105 illustrated in FIG. 12 will be described with reference to FIG. 13. The manufacture of the part of the electrode 105 will be described with reference to FIG. 13.

In step S41, a substrate is prepared in which the stacked film 100 is formed, with barrier metal 104 and the expansion inhibition suppression film 131d formed therein. By executing steps S11, S12, and S13 described with reference to FIG. 7, the barrier metal 104 and the expansion inhibition suppression film 131d are formed in the connection hole 121 and the interconnect hole 122 in the steps before step S41.

As indicated in the depiction of step S41, the expansion inhibition suppression film 131d is formed on the side face and the bottom face of the connection hole 121, the side face and the bottom face of the interconnect hole 122, and the top face of the stacked film 100.

In step S42, the material of the electrode 105, e.g., copper (Cu), is embedded in the connection hole 121 and the interconnect hole 122. In step S43, the Cu is polished and flattened. Steps S43 and S44 are basically the same steps as steps S15 and S16 (FIG. 7). By omitting the etch-back process performed in step S14 of FIG. 7 and polishing the Cu, an electrode in which the expansion inhibition suppression film 131d is also present on the bottom face is formed, as illustrated in FIG. 12.

An electrode including the expansion inhibition suppression film 131d illustrated in FIG. 12 can be formed through the foregoing steps.

### Embodiment 4-2

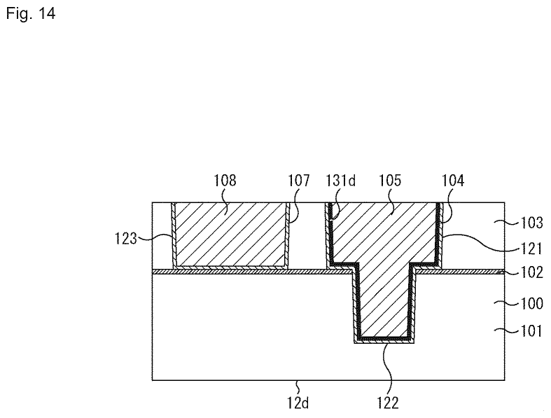

FIG. 14 is a diagram illustrating an example of the configuration of a pixel 12d according to Embodiment 4-2 in which the present technique is applied. Parts that are the same between the pixel 12d according to Embodiment 4-2, illustrated in FIG. 14, and the pixel 12d according to Embodiment 4-1, illustrated in FIG. 12, will be given the same reference signs, and descriptions thereof will be omitted as appropriate.

The pixel 12d according to Embodiment 4-2, illustrated in FIG. 14, is different from the pixel 12d according to Embodiment 4-1, illustrated in FIG. 12, in that a dummy electrode 108 is added to the pixel 12d. The other points are the same.

The pixel 12d illustrated in FIG. 14 includes the electrode 105 for conducting with another semiconductor substrate, and the dummy electrode 108 that does not need to conduct with the other semiconductor substrate. The electrode 105 disposed on the right side of the pixel 12d illustrated in FIG. 14 has the same configuration as the electrode 105 illustrated in FIG. 12, descriptions thereof will be omitted.

When a region where the electrode 105 is disposed and a region where the electrode 105 is not disposed are present due to the layout or the like, for example, the dummy electrode 108 is disposed in the region where the electrode 105 is not disposed. The dummy electrode 108 is disposed, for example, in a region where the bonding with other semiconductor substrate is weak, such that the bonding strength between the semiconductor substrates does not decrease. As such, the dummy electrode 108 can be formed relatively larger than the electrode 105 for which conductivity is required.

As illustrated in FIG. 14, the dummy electrode 108 illustrated on the left side of the figure is larger than the electrode 105 illustrated on the right side of the figure. Forming the dummy electrode 108 larger also increases the amount of copper embedded in a connection hole 123, and thus the amount of expansion during the heat treatment also increases. In such a case, a reduction in the amount of expansion, which is of concern with the miniaturized electrode 105, does not easily arise in the dummy electrode 108, which makes it possible to omit the expansion inhibition suppression film 131.

In the dummy electrode 108 illustrated in FIG. 14, only a barrier metal 107 is formed between the interlayer insulating film 103 and the dummy electrode 108, and the expansion inhibition suppression film 131 is not formed. In this manner, the configurations of the electrode including the dummy electrode 108 and the electrode including the electrode 105 can also be different.

Although FIG. 14 illustrates an example of combining Embodiment 4-2, in which the dummy electrode 108 is provided, with Embodiment 4-1, Embodiment 4-2 can also be carried out in combination with Embodiments 1 to 3. In other words, the configurations of the electrode 105 described in Embodiments 1 to 3 can be applied as appropriate to the configuration on the electrode 105 side. Embodiment 4-2 can also be combined with the embodiments described below.

### Manufacture According to Embodiment 4-2

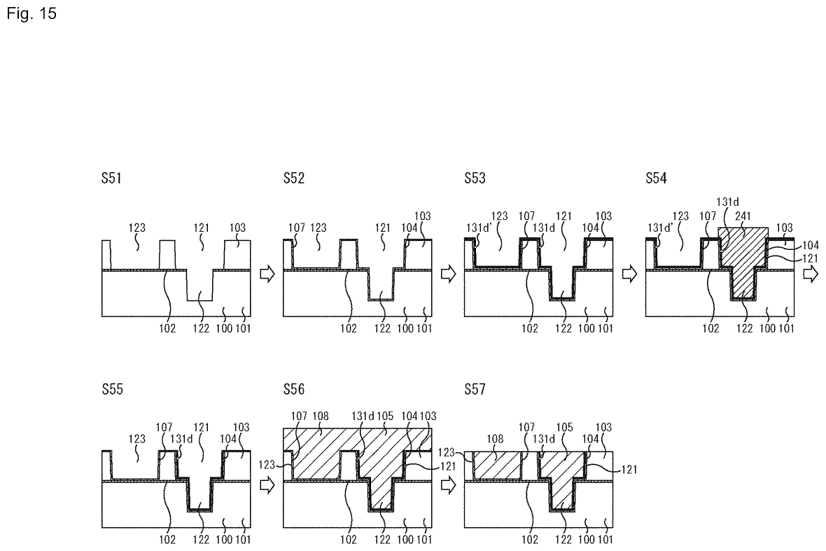

The manufacture of the pixel 12d having the configuration of the electrode 105 illustrated in FIG. 4 will be described with reference to FIG. 15. The manufacture of the part of the electrode 105 and the dummy electrode 108 will be described with reference to FIG. 15.

In step S51, a substrate is prepared in which the stacked film 100 is formed, with the interlayer insulating film 101, the liner insulating film 102, and the interlayer insulating film 103 stacked therein. The connection hole 121, the interconnect hole 122, and the connection hole 123 are formed by etching the stacked film 100. For example, in a photolithography step, a photoresist is applied to generate a resist pattern for forming the connection hole 121, the interconnect hole 122, and the connection hole 123, and dry etching is performed using the resist pattern as a mask to form the connection hole 121, the interconnect hole 122, and the connection hole 123.

In step S52, the barrier metal 104 is formed by sputtering, for example. The barrier metal 104 is formed on the side face and the bottom face of the connection hole 121, the side face and the bottom face of the interconnect hole 122, and the side face and the bottom face of the connection hole 123, and is also formed on the top face of the stacked film 100.

In step S53, the expansion inhibition suppression film 131d is formed on the barrier metal 104. The expansion inhibition suppression film 131d can also be formed by sputtering. If a material having a low adhesion strength, such as an oxide film, is used as the expansion inhibition suppression film 131, the oxide film is formed in step S53. If a material having a low coefficient of friction, such as carbon, is used as the expansion inhibition suppression film 131, a carbon film is formed in step S53.

In step S53, the expansion inhibition suppression film 131d is formed on the side face and the bottom face of the connection hole 121, the side face and the bottom face of the interconnect hole 122, the side face and the bottom face of the connection hole 123, and the top face of the stacked film 100. The expansion inhibition suppression film 131d formed on the side face and the bottom face of the connection hole 123 will be denoted as an expansion inhibition suppression film 131d′.

In step S54, the parts to serve as the electrode 105, which in this case are the connection hole 121 and the interconnect hole 122, are filled (applied) with a resist 241. An etching step is performed, and dry etching is performed using the resist pattern generated in the photolithography step as a mask, which removes the expansion inhibition suppression film 131d′ formed in the connection hole 123 that is to serve as the dummy electrode 108.

In step S55, an ashing and washing process is performed, the resist 241 is removed, and wet washing is performed.

In step S56, the material of the electrode 105, e.g., copper (Cu), is embedded in the connection hole 121 and the interconnect hole 122. The material of the dummy electrode 108, e.g., copper (Cu), is also embedded in the connection hole 123. The copper (Cu) is embedded in the connection hole 121, the interconnect hole 122, and the connection hole 123 by Cu sputtering followed by Cu plating.

In step S57, the Cu is polished and flattened. In this step, the excess part of the Cu and the barrier metal 104 on the top face of the stacked film 100 are removed by CMP.

The electrode 105 including the expansion inhibition suppression film 131 illustrated in FIG. 14, and the pixel 12d having the dummy electrode 108 that does not include the expansion inhibition suppression film 131, can be formed through the foregoing steps.

### Embodiment 5

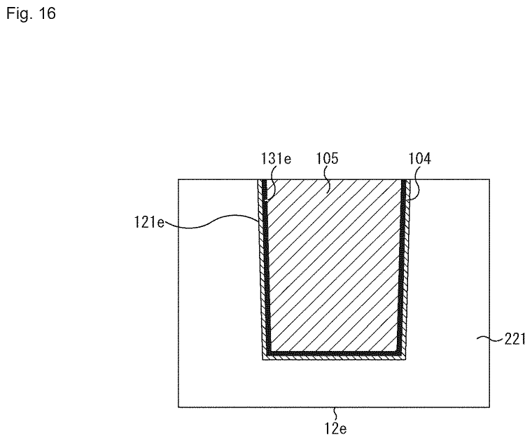

FIG. 16 is a diagram illustrating an example of the configuration of a pixel 12e according to Embodiment 5 in which the present technique is applied. Parts that are the same between (i) the pixel 12e according to Embodiment 5, illustrated in FIG. 16, and (ii) the pixel 12c according to Embodiment 3, illustrated in FIG. 10, and the pixel 12d according to Embodiment 4, illustrated in FIG. 12, will be given the same reference signs, and descriptions thereof will be omitted as appropriate.

When comparing the pixel 12e according to Embodiment 5, illustrated in FIG. 16, and the pixel 12c according to Embodiment 3, illustrated in FIG. 10, the single damascene configuration is the same, and the difference is that an expansion inhibition suppression film 131e is also formed on the bottom face of a connection hole 121e.

When comparing the pixel 12e according to Embodiment 5, illustrated in FIG. 16, with the pixel 12d according to Embodiment 4, illustrated in FIG. 12, the pixel 12d according to Embodiment 4, illustrated in FIG. 12, has a dual damascene structure, whereas the pixel 12e according to Embodiment 5, illustrated in FIG. 16, has a single damascene structure.

As illustrated in FIG. 16, in the electrode formed at the bonded part where the substrates are affixed to each other, the connection hole 121e is provided in the insulating film 221, and the barrier metal 104 is formed on the side face and the bottom face of the connection hole 121e. The expansion inhibition suppression film 131e is formed on the barrier metal 104 formed on the side face and the bottom face of the connection hole 121e.

The expansion inhibition suppression film 131e is a film formed of a material that does not inhibit thermal expansion of the material constituting the electrode 105 during heat treatment, and is constituted by a material having a low adhesion strength or a material having a low coefficient of friction, as in Embodiment 1. However, when the expansion inhibition suppression film 131e is also formed on the bottom face of the connection hole 121e, as with the pixel 12e illustrated in FIG. 16, a conductive material is used as the material of the expansion inhibition suppression film 131e.

In the configuration illustrated in FIG. 16 too, the expansion inhibition suppression film 131e does not inhibit the expansion of the copper of the electrode 105 within the connection hole 121e during the heat treatment. The expansion of the electrode 105 is therefore not inhibited, and the bonding with the electrode provided on the substrate to be affixed can be performed without problems.

### Manufacture According to Embodiment 5

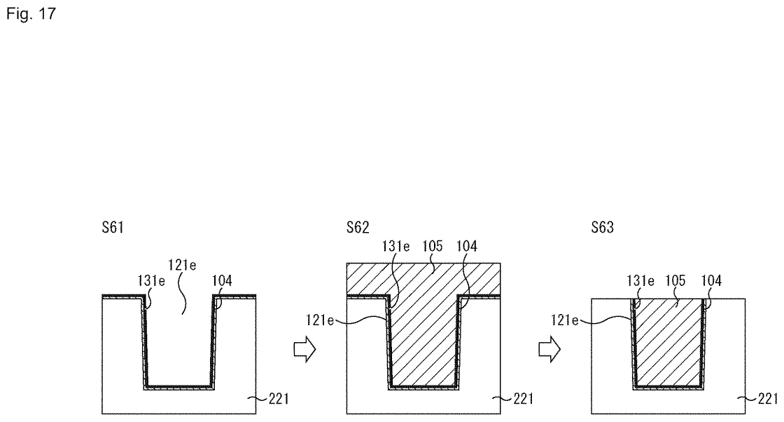

The manufacture of the pixel 12e having the configuration of the electrode 105 illustrated in FIG. 16 will be described with reference to FIG. 17. The manufacture of the part of the electrode 105 will be described with reference to FIG. 17.

In step S61, a semiconductor substrate is prepared in which the connection hole 121e is formed in the insulating film 221 and the barrier metal 104 and the expansion inhibition suppression film 131e are formed within the connection hole 121e. By executing steps S31, S32, and S33 described with reference to FIG. 11, the barrier metal 104 and the expansion inhibition suppression film 131e are formed in the connection hole 121e in the steps before step S61.

As indicated in the depiction of step S51, the expansion inhibition suppression film 131e is formed on the side face and the bottom face of the connection hole 121e and the top face of the insulating film 221.

In step S52, the material of the electrode 105, e.g., copper (Cu), is embedded in the connection hole 121e. In step S53, the Cu is polished and flattened. Steps S53 and S54 are basically the same steps as steps S35 and S36 (FIG. 11). By omitting the etch-back process performed in step S34 of FIG. 11 and polishing the Cu, the electrode 105 in which the expansion inhibition suppression film 131e is also present on the bottom face of the connection hole 121e is formed, as illustrated in FIG. 16.

An electrode including the expansion inhibition suppression film 131e illustrated in FIG. 16 can be formed through the foregoing steps.

### Embodiment 6

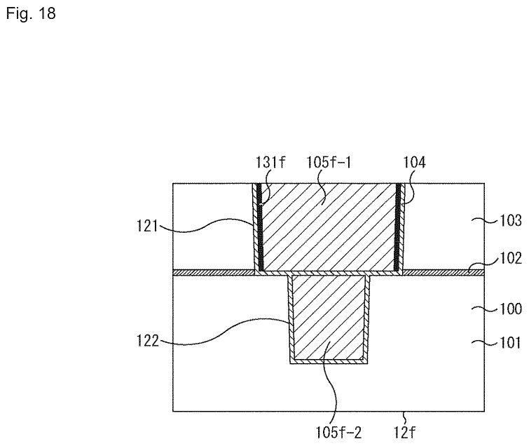

FIG. 18 is a diagram illustrating an example of the configuration of a pixel 12f according to Embodiment 6 in which the present technique is applied. Parts that are the same between the pixel 12f according to Embodiment 6, illustrated in FIG. 16, and the pixel 12a according to Embodiment 1, illustrated in FIG. 4, will be given the same reference signs, and descriptions thereof will be omitted as appropriate.

When comparing the pixel 12f according to Embodiment 6, illustrated in FIG. 18, and the pixel 12a according to Embodiment 1, illustrated in FIG. 4, the pixel 12f differs in that the electrode 105 is constituted by an electrode 105f-1 and an electrode 105f-2 formed of different materials. The other points are the same.

The electrode 105 of the pixel 12f illustrated in FIG. 18 is constituted by the electrode 105f-1, which is formed of a first material, and the electrode 105f-2, which is formed of a second material different from the first material. In the example illustrated in FIG. 18, the electrode 105f-1 is an electrode formed in the connection hole 121, and the electrode 105f-2 is an electrode formed in the interconnect hole 122.

The first material with which the connection hole 121 is filled, and which constitutes the electrode 105f-1, is a material susceptible to thermal expansion. A material having a large linear expansion coefficient can be used for the first material. The second material with which the interconnect hole 122 is filled, and which constitutes the electrode 105f-2, is a conductive material.

Zinc (Zn), aluminum (Al), tin (Sn), duralumin, bronze, or the like, or a combination thereof can be used as the first material. Copper (Cu) can be used as the second material. The linear expansion coefficient of copper (Cu) is 16.5. The linear expansion coefficient of zinc (Zn) is 30.2, the linear expansion coefficient of aluminum (Al) is 23.1, the linear expansion coefficient of tin (Sn) is 22.0, the linear expansion coefficient of duralumin is 21.6, and the linear expansion coefficient of bronze is 17.3. All of these values are greater than the linear expansion coefficient of copper, and can be used as the first material.

The barrier metal 104 and an expansion inhibition suppression film 131f are formed on the side wall of the connection hole 121. The barrier metal 104 is formed on the bottom face of the connection hole 121. The barrier metal 104 is formed on the side wall and the bottom face of the interconnect hole 122.

The electrode 105f-1 formed in the connection hole 121 is formed of the first material that is susceptible to expansion, and the expansion inhibition suppression film 131f is also formed to prevent the expansion thereof from being inhibited. Accordingly, the amount of expansion of the electrode 105f-1 formed in the connection hole 121 can be increased, and the electrode 105f-1 can expand sufficiently.

When the necessary amount of expansion can be ensured by using the first material, which is susceptible to expansion, for the electrode 105f-1 in the connection hole 121, the expansion inhibition suppression film 131f may be omitted.

In the configuration illustrated in FIG. 18, the expansion inhibition suppression film 131f is formed in the connection hole 121, the first material having a large linear expansion coefficient is used for the electrode 105f-1 in the connection hole 121, and the electrode 105f-1 is in contact with the expansion inhibition suppression film 131f, but is not in contact with the barrier metal 104. The expansion inhibition suppression film 131f is constituted by a material having a low adhesion strength or a material having a low coefficient of friction, as in Embodiment 1.

In the configuration illustrated in FIG. 18 too, the expansion inhibition suppression film 131f does not inhibit the expansion of the electrode 105 during the heat treatment. The expansion of the electrode 105 is therefore not inhibited, and the bonding with the electrode provided on the substrate to be affixed can be performed without problems.

### Manufacture According to Embodiment 6

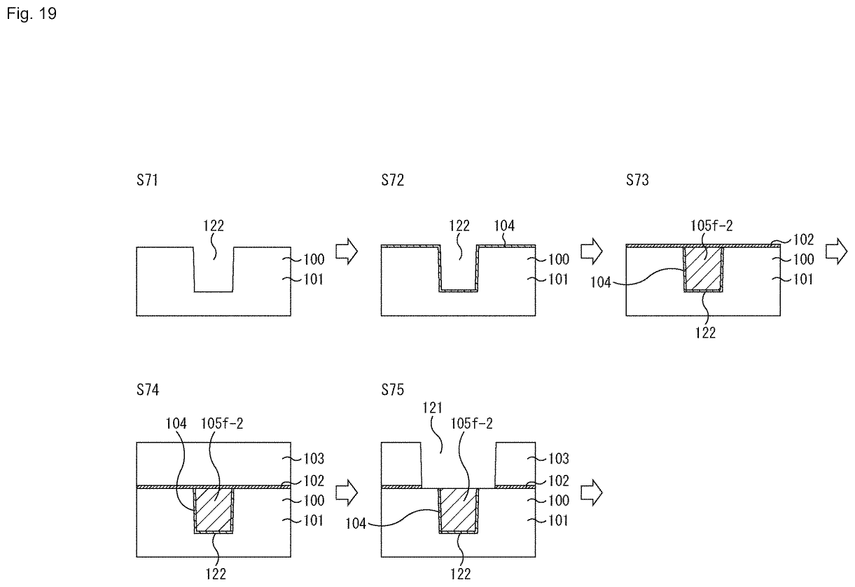

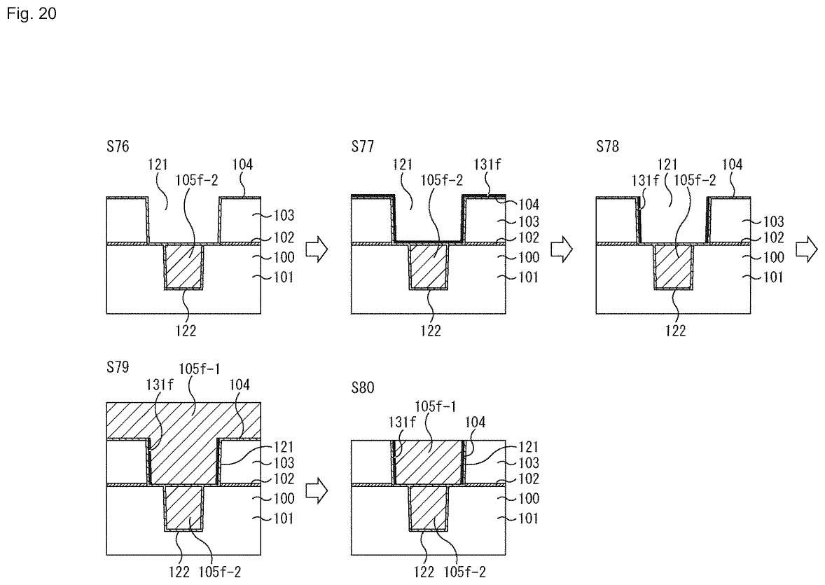

The manufacture of the pixel 12f having the configuration of the electrode 105 illustrated in FIG. 18 will be described with reference to FIGS. 19 and 20. The manufacture of the part of the electrode 105 will be described with reference to FIGS. 19 and 20.

In step S71, a semiconductor substrate is prepared in which the interlayer insulating film 101 is formed. The interconnect hole 122 is formed by etching the interlayer insulating film 101. For example, in a photolithography step, a photoresist is applied to generate a resist pattern in which a region where the interconnect hole 122 is to be formed is open, and dry etching is performed using the resist pattern as a mask to form the interconnect hole 122.

In step S72, the barrier metal 104 is formed by sputtering, for example. The barrier metal 104 is formed on the side face and the bottom face of the interconnect hole 122, and is also formed on the top face of the interlayer insulating film 101.

In step S73, the second material, e.g., copper (Cu), is embedded in the interconnect hole 122. The electrode 105f-2, constituted by copper (Cu), is embedded in the interconnect hole 122 by Cu sputtering followed by Cu plating. The barrier metal 104 formed on the interlayer insulating film 101 is removed, and the liner insulating film 102 is formed.

In step S74, the interlayer insulating film 103 is formed on the liner insulating film 102 formed on the interlayer insulating film 101.

In step S75, the connection hole 121 is formed by etching the interlayer insulating film 103. For example, in a photolithography step, a photoresist is applied to generate a resist pattern in which a region where the connection hole 121 is to be formed is open, and dry etching is performed using the resist pattern as a mask to form the connection hole 121.

In step S76 (FIG. 20), the barrier metal 104 is formed by sputtering, for example. The barrier metal 104 is formed on the side face and the bottom face of the connection hole 121, and is also formed on the top face of the interlayer insulating film 103.

In step S77, the expansion inhibition suppression film 131f is formed on the barrier metal 104. The expansion inhibition suppression film 131f can also be formed by sputtering. If a material having a low adhesion strength, such as an oxide film, is used as the expansion inhibition suppression film 131f, the oxide film is formed in step S77. If a material having a low coefficient of friction, such as carbon, is used as the expansion inhibition suppression film 131f, a carbon film is formed in step S77.

In step S78, the extra expansion inhibition suppression film 131f is removed by an etch-back process. Because the expansion inhibition suppression film 131f is removed by the etch-back process, the expansion inhibition suppression film 131f on the interlayer insulating film 103 and the expansion inhibition suppression film 131f on the bottom face of the connection hole 121 are removed. In other words, the expansion inhibition suppression film 131f formed in regions other than the expansion inhibition suppression film 131f on the side face of the connection hole 121 is removed.

In step S79, the material of the electrode 105f-1, e.g., an alloy of copper (Cu) and tin (Sn), is embedded in the connection hole 121. The electrode 105f-1, constituted by the alloy (Cu—Sn), is embedded in the connection hole 121 by alloy sputtering followed by alloy plating.

In step S80, the alloy is polished and flattened. In this step, the excess part of the alloy and the barrier metal 104 on the top face of the interlayer insulating film 103 are removed by CMP.

An electrode constituted by the different material illustrated in FIG. 18, and including the expansion inhibition suppression film 131f, can be formed through the foregoing steps.

### Embodiment 7

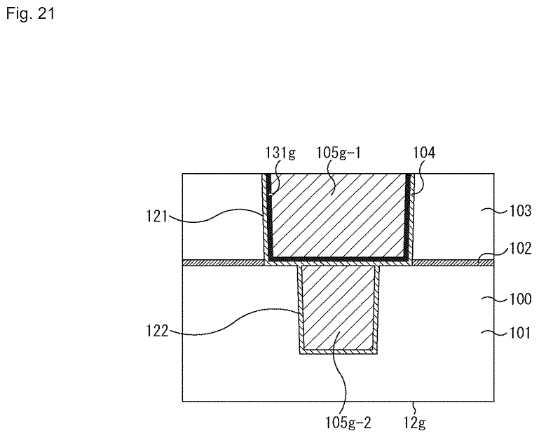

FIG. 21 is a diagram illustrating an example of the configuration of a pixel 12g according to Embodiment 7 in which the present technique is applied. Parts that are the same between the pixel 12g according to Embodiment 7, illustrated in FIG. 21, and the pixel 12f according to Embodiment 6, illustrated in FIG. 18, will be given the same reference signs, and descriptions thereof will be omitted as appropriate.

When comparing the pixel 12g according to Embodiment 7, illustrated in FIG. 21, and the pixel 12f according to Embodiment 6, illustrated in FIG. 18, the region in which an expansion inhibition suppression film 131g of the pixel 12g is formed is different from the region in which the expansion inhibition suppression film 131f of the pixel 12f is formed. The other points are the same.

Unlike the pixel 12f according to Embodiment 6 illustrated in FIG. 18, the expansion inhibition suppression film 131g of the pixel 12g illustrated in FIG. 21 is provided on the bottom face of the connection hole 121 too, but the other points are the same. The expansion inhibition suppression film 131g of the pixel 12g illustrated in FIG. 21 is provided on the side face and the bottom face of the connection hole 121.

In the configuration illustrated in FIG. 21, the expansion inhibition suppression film 131g is formed in the connection hole 121, a first material having a large linear expansion coefficient is used for an electrode 105g-1 in the connection hole 121, and the electrode 105g-1 is in contact with the expansion inhibition suppression film 131g, but is not in contact with the barrier metal 104. The expansion inhibition suppression film 131g is constituted by a material having a low adhesion strength or a material having a low coefficient of friction, as in Embodiment 1.

In the configuration illustrated in FIG. 21 too, the expansion inhibition suppression film 131g does not inhibit the expansion of the electrode 105 during the heat treatment. The expansion of the electrode 105 is therefore not inhibited, and the bonding with the electrode provided on the substrate to be affixed can be performed without problems.

### Manufacture According to Embodiment 7

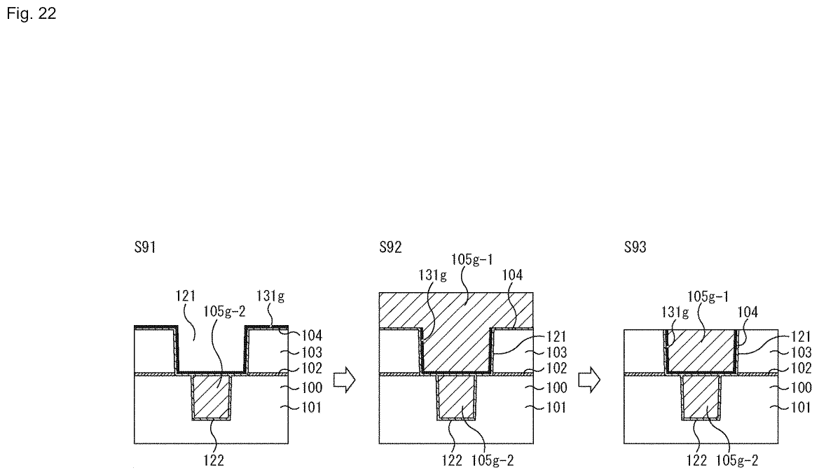

The manufacture of the pixel 12g having the configuration of an electrode 105g illustrated in FIG. 21 will be described with reference to FIG. 22. The manufacture of the part of the electrode 105g will be described with reference to FIG. 22.

In step S91, a substrate is prepared in which the stacked film 100 is formed, with barrier metal 104 and the expansion inhibition suppression film 131g formed therein. By executing steps S71 to S77 described with reference to FIGS. 19 and 20 in the steps before step S91, the connection hole 121 and the interconnect hole 122 are formed in the stacked film 100, the barrier metal 104 is formed on the side faces thereof, and the electrode 105-2 is formed in the interconnect hole 122. Furthermore, the expansion inhibition suppression film 131g is formed on the side face and the bottom face of the connection hole 121 and the surface of the interlayer insulating film 101.

In step S92, the material of the electrode 105g-1, e.g., an alloy of copper (Cu) and tin (Sn), is embedded in the connection hole 121. The electrode 105g-1, constituted by the alloy (Cu—Sn), is embedded in the connection hole 121 by alloy sputtering followed by alloy plating.

In step S93, the alloy is polished and flattened. In this step, the excess part of the alloy and the barrier metal 104 on the top face of the interlayer insulating film 103 are removed by CMP.

When manufacturing the pixel 12g illustrated in FIG. 21, the etch-back process performed in step S78 of FIG. 20 is omitted, and the Cu is polished. Through such a process, an electrode in which the expansion inhibition suppression film 131g is also present on the bottom face of the connection hole 121 is formed, as illustrated in FIG. 21.

An electrode 105 constituted by the different material illustrated in FIG. 21, and including the expansion inhibition suppression film 131g, can be formed through the foregoing steps.

### Embodiment 8

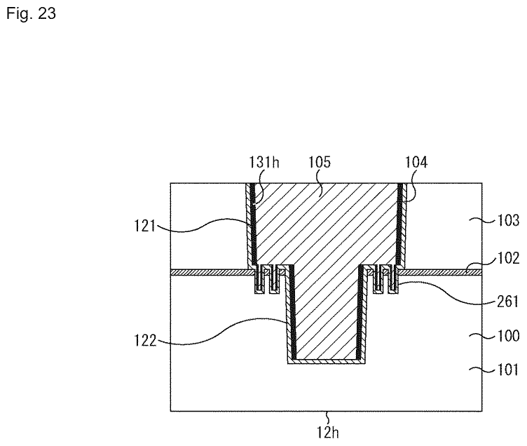

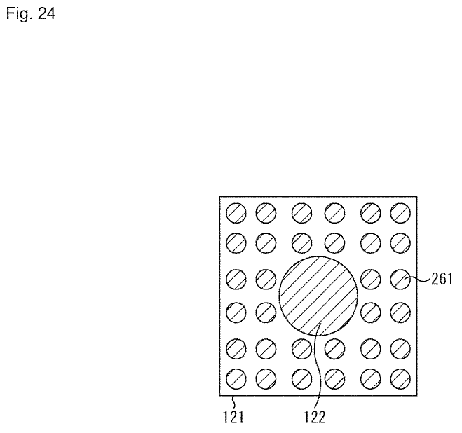

FIG. 23 is a diagram illustrating an example of the cross-sectional configuration of a pixel 12h according to Embodiment 8 in which the present technique is applied, and FIG. 24 is a diagram illustrating an example of the planar configuration of the pixel 12h. Parts that are the same between the pixel 12h according to Embodiment 8, illustrated in FIG. 23, and the pixel 12a according to Embodiment 1, illustrated in FIG. 4, will be given the same reference signs, and descriptions thereof will be omitted as appropriate.

When comparing the pixel 12h according to Embodiment 8, illustrated in FIG. 23, and the pixel 12a according to Embodiment 1, illustrated in FIG. 4, the pixel 12h differs in that the pixel 12h has a configuration in which vias 261 are added to the pixel 12a. The other points are the same.

The vias 261 are formed in the bottom face of the connection hole 121 of the pixel 12h illustrated in FIG. 23. The vias 261 are formed in a region corresponding to the difference between the bottom face of the connection hole 121 and the face of the interconnect hole 122 on the connection hole 121 side thereof.

Referring to the example of the planar configuration illustrated in FIG. 24, the connection hole 121 is formed in a square shape, and the interconnect hole 122 is formed as a circle in the center of the connection hole 121. The vias 261 are formed within the connection hole 121, in the region outside of the interconnect hole 122. The vias 261 are formed as small circles, and a plurality of the vias 261 are provided. Because the vias 261 are circular in plan view and square in cross-sectional view (FIG. 23), a single one of the vias 261 is formed in a cylindrical shape. Although the vias 261 will continue to be described as having cylindrical shapes as an example, other shapes, such as square columns, may be used instead.

Referring to the example of the cross-sectional configuration illustrated in FIG. 23, the barrier metal 104 is formed on the side faces and the bottom faces of the vias 261. Furthermore, an expansion inhibition suppression film 131h is formed on the side faces of the vias 261.

In the pixel 12h, providing the plurality of vias 261 increases the amount of copper (Cu), for example, constituting the electrode 105, and thus the amount of expansion can be increased.

In the configuration illustrated in FIG. 23 too, the electrode 105 is configured to be in contact with the expansion inhibition suppression film 131h. The expansion inhibition suppression film 131h is constituted by a material having a low adhesion strength or a material having a low coefficient of friction, as in Embodiment 1. Accordingly, the expansion inhibition suppression film 131h does not inhibit the expansion of the copper of the electrode 105 within the connection hole 121 during the heat treatment. The expansion of the electrode 105 is therefore not inhibited, and the bonding with the electrode provided on the substrate to be affixed can be performed without problems.

### Manufacture According to Embodiment 8

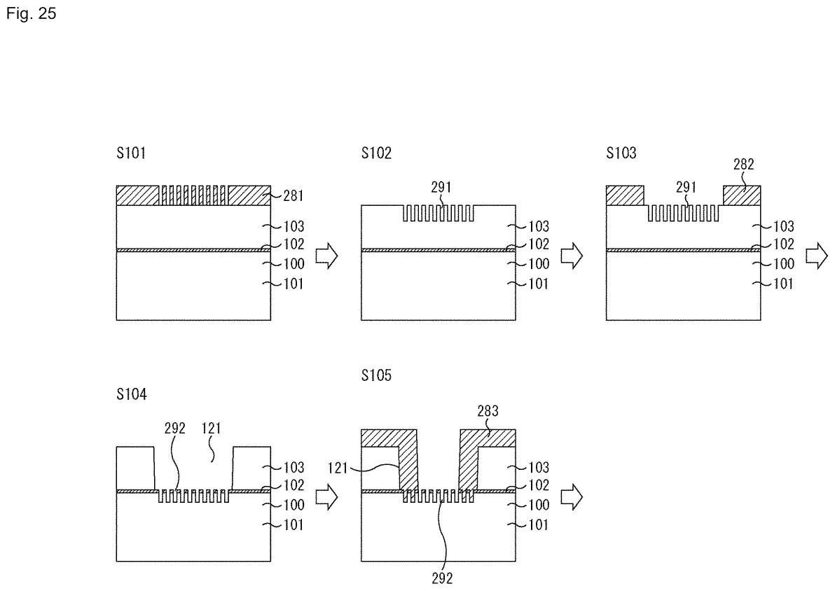

The manufacture of the pixel 12h having the configuration of the electrode 105 illustrated in FIG. 24 will be described with reference to FIG. 25. The manufacture of the part of the electrode 105 will be described with reference to FIG. 25.

In step S101, a substrate is prepared in which the stacked film 100 is formed, with the interlayer insulating film 101, the liner insulating film 102, and the interlayer insulating film 103 stacked therein. A resist is applied to the stacked film 100 to generate a resist pattern 281 in which the parts in which the vias 261 are to be formed are open.

Although the resist pattern 281 illustrated in FIG. 25 is illustrated as a pattern in which the openings are arranged at equal intervals, only the openings provided at both ends of the resist pattern 281 are needed to form the vias 261, and thus a resist pattern 281 without openings in the central part of the resist pattern 281 may be generated.

In step S102, dry etching is performed using the generated resist pattern 281 as a mask, and grooves 291 are formed in the interlayer insulating film 103.

In step S103, a resist pattern 282 in which the region to serve as the connection hole 121 is open is generated.

In step S104, dry etching is performed using the generated resist pattern 282 as a mask, and the connection hole 121 is formed in the interlayer insulating film 103. Recess-shaped grooves 292 are formed in the bottom face of the hole that is to serve as the connection hole 121, in the parts where the grooves 291 were located.

In step S105, a resist is applied to cover the grooves 292 which, of the grooves 292, are at positions where the vias 261 are to remain. A resist 283 is also applied to the side face of the connection hole 121 and the top face of the stacked film 100. In step S105, a resist pattern 283 is generated in which the region where the interconnect hole 122 is to be formed is open.

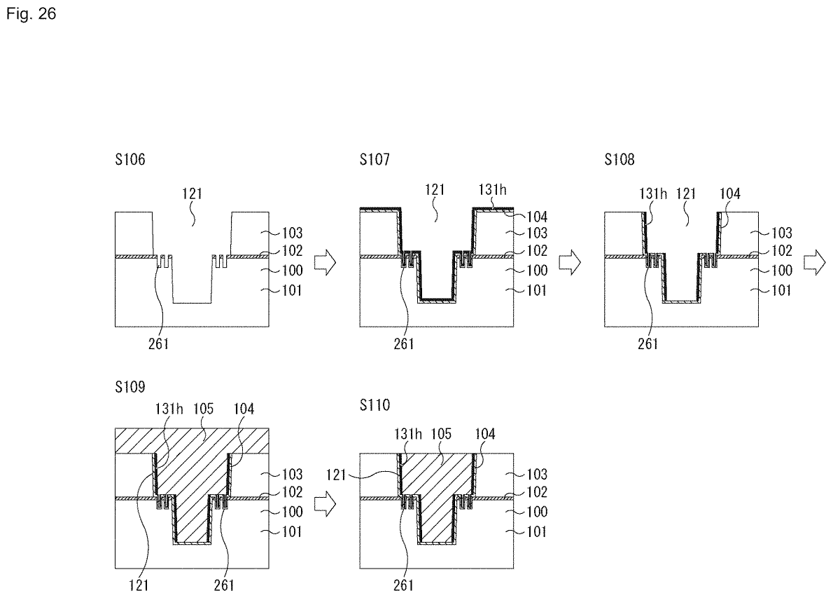

In step S106 (FIG. 26), dry etching is performed using the generated resist pattern 283 as a mask to form the interconnect hole 122 in the interlayer insulating film 101 of the stacked film 100.

In step S107, the barrier metal 104 is formed by sputtering, for example. The barrier metal 104 is formed on the side faces and the bottom faces of the connection hole 121 and the interconnect hole 122, and is also formed on a top face of the interlayer insulating film 103. After the barrier metal 104 is formed, the expansion inhibition suppression film 131h is formed on the barrier metal 104. The expansion inhibition suppression film 131 can also be formed by sputtering. In step S107, the barrier metal 104 and the expansion inhibition suppression film 131h are formed on the side faces and the bottom faces of the vias 261.

If a material having a low adhesion strength, such as an oxide film, is used as the expansion inhibition suppression film 131h, the oxide film is formed in step S107. If a material having a low coefficient of friction, such as carbon, is used as the expansion inhibition suppression film 131h, a carbon film is formed in step S107.

In step S108, the expansion inhibition suppression film 131h is removed by an etch-back process. Because the expansion inhibition suppression film 131h is removed by the etch-back process, the expansion inhibition suppression film 131h on the interlayer insulating film 103, the expansion inhibition suppression film 131h on the bottom face of the connection hole 121, the expansion inhibition suppression film 131h on the bottom face of the interconnect hole 122, and the expansion inhibition suppression film 131h on the bottom faces of the vias 261 are removed. In other words, the expansion inhibition suppression film 131h formed in regions other than the expansion inhibition suppression film 131h on the side face of the connection hole 121, the side face of the interconnect hole 122, and the side faces of the vias 261 is removed.

In step S109, the material of the electrode 105, e.g., copper (Cu), is embedded in the connection hole 121, the interconnect hole 122, and the vias 261. The electrode 105, constituted by copper (Cu), is embedded in the connection hole 121, the interconnect hole 122, and the vias 261 by Cu sputtering followed by Cu plating.

In step S110, the Cu is polished and flattened. In this step, the excess part of the Cu and the barrier metal 104 on the top face of the interlayer insulating film 103 are removed by CMP.

An electrode including the vias 261 illustrated in FIG. 24, and the expansion inhibition suppression film 131h as well, can be formed through the foregoing steps.

### Embodiment 9

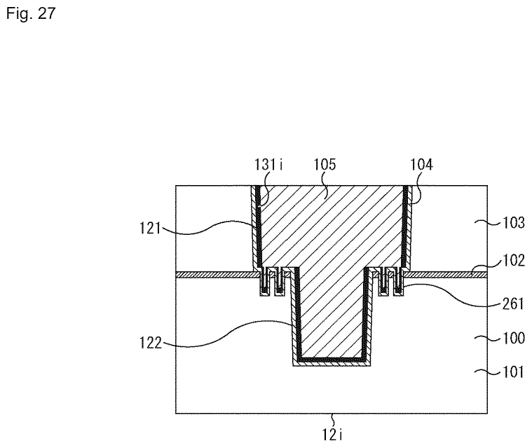

FIG. 27 is a diagram illustrating an example of the configuration of a pixel 12i according to Embodiment 9 in which the present technique is applied. Parts that are the same between the pixel 12i according to Embodiment 9, illustrated in FIG. 27, and the pixel 12h according to Embodiment 8, illustrated in FIG. 24, will be given the same reference signs, and descriptions thereof will be omitted as appropriate.

When comparing the pixel 12i according to Embodiment 9, illustrated in FIG. 27, and the pixel 12h according to Embodiment 8, illustrated in FIG. 24, the region in which an expansion inhibition suppression film 131i of the pixel 12i is formed is different from the region in which the expansion inhibition suppression film 131h of the pixel 12h is formed. The other points are the same.

Unlike the pixel 12h according to Embodiment 8 illustrated in FIG. 24, the expansion inhibition suppression film 131i of the pixel 12i illustrated in FIG. 27 is provided on the bottom face of the connection hole 121, the bottom face of the interconnect hole 122, and the bottom faces of the vias 261, but the other points are the same. The expansion inhibition suppression film 131i of the pixel 12i illustrated in FIG. 27 is provided on the side face and the bottom face of the connection hole 121, the side face and the bottom face of the interconnect hole 122, and the side faces and the bottom faces of the vias 261.

In the configuration illustrated in FIG. 27, the expansion inhibition suppression film 131i is formed in the connection hole 121, the interconnect hole 122, and the vias 261. The copper of the electrode 105 is in contact with the expansion inhibition suppression film 131i, but is not in contact with the barrier metal 104. The expansion inhibition suppression film 131i is constituted by a material having a low adhesion strength or a material having a low coefficient of friction, as in Embodiment 1 and the like. However, when the expansion inhibition suppression film 131i is also formed on the bottom face of the interconnect hole 122, as with the pixel 12i illustrated in FIG. 27, a conductive material is used as the material of the expansion inhibition suppression film 131i.

In the configuration illustrated in FIG. 27 too, the expansion inhibition suppression film 131i does not inhibit the expansion of the copper of the electrode 105 during the heat treatment. The expansion of the electrode 105 is therefore not inhibited, and the bonding with the electrode provided on the substrate to be affixed can be performed without problems.

### Manufacture According to Embodiment 9

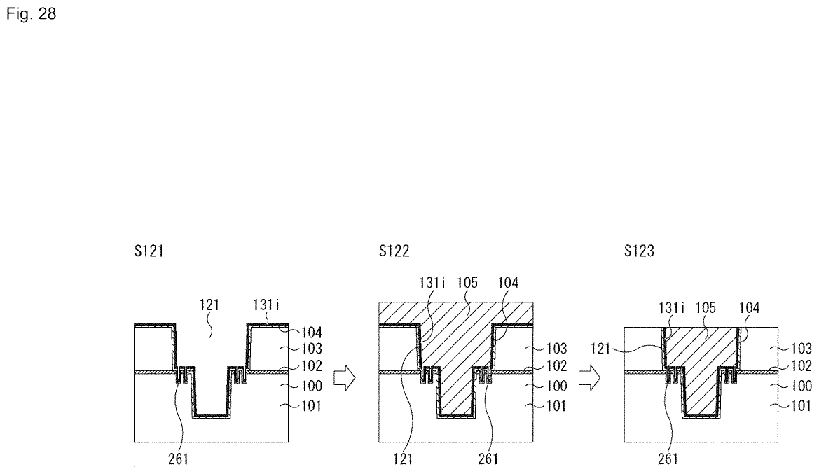

The manufacture of the pixel 12i having the configuration of the electrode 105 illustrated in FIG. 27 will be described with reference to FIG. 28. The manufacture of the part of the electrode 105 will be described with reference to FIG. 28.

In step S121, a substrate is prepared in which the stacked film 100 is formed, with barrier metal 104 and the expansion inhibition suppression film 131i formed therein. By executing steps S101 to S107 described with reference to FIGS. 25 and 26 in the steps before step S121, the barrier metal 104 and the expansion inhibition suppression film 131i are formed in the connection hole 121, the interconnect hole 122, and the vias 261.

In step S122, the material of the electrode 105, e.g., copper (Cu), is embedded in the connection hole 121, the interconnect hole 122, and the vias 261. In step S123, the Cu is polished and flattened. Steps S122 and S123 are basically the same steps as steps S109 and S110 (FIG. 26). By omitting the etch-back process performed in step S108 of FIG. 26 and polishing the Cu, an electrode in which the expansion inhibition suppression film 131i is also present on the bottom faces of the connection hole 121, the interconnect hole 122, and the vias 261 is formed, as illustrated in FIG. 27.

An electrode including the vias 261 illustrated in FIG. 27, and the expansion inhibition suppression film 131i as well, can be formed through the foregoing steps.

### Embodiment 10

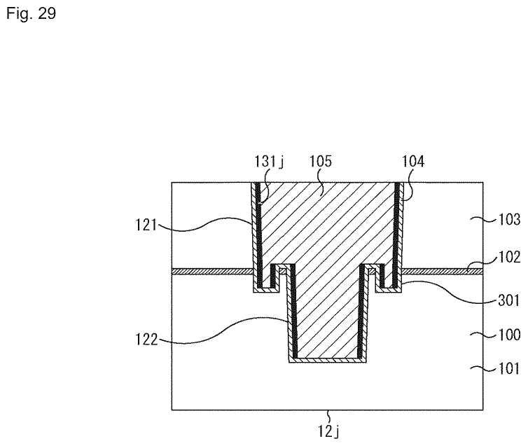

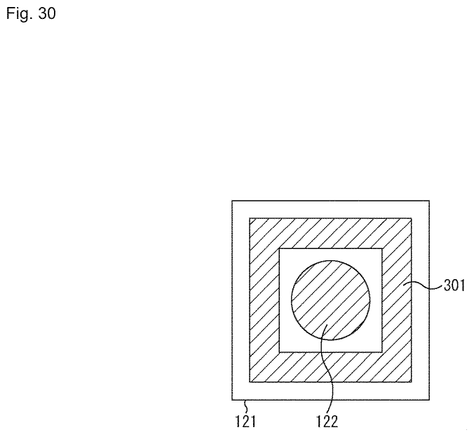

FIG. 29 is a diagram illustrating an example of the cross-sectional configuration of a pixel 12j according to Embodiment 10 in which the present technique is applied, and FIG. 30 is a diagram illustrating the planar configuration of the pixel 12j. Parts that are the same between the pixel 12j according to Embodiment 10, illustrated in FIG. 29, and the pixel 12a according to Embodiment 1, illustrated in FIG. 4, will be given the same reference signs, and descriptions thereof will be omitted as appropriate.

When comparing the pixel 12j according to Embodiment 10, illustrated in FIG. 29, and the pixel 12a according to Embodiment 1, illustrated in FIG. 4, the pixel 12j differs in that the pixel 12j has a configuration in which a trench 301 is added to the pixel 12a. The other points are the same.

The trench 301 is formed in the bottom face of the connection hole 121 of the pixel 12j illustrated in FIG. 29. The trench 301 is formed in a region corresponding to the difference between the bottom face of the connection hole 121 and the face of the interconnect hole 122 on the connection hole 121 side thereof.

Referring to the example of the planar configuration illustrated in FIG. 30, the connection hole 121 is formed in a square shape, and the interconnect hole 122 is formed as a circle in the center of the connection hole 121. The trench 301 is formed in a square shape within the connection hole 121, in the region outside of the interconnect hole 122, so as to surround the interconnect hole 122. The trench 301 can be formed deeper than the vias 261 (FIG. 23) and in a quadrangle having a predetermined width, as illustrated in FIG. 30.

Referring to the example of the cross-sectional configuration illustrated in FIG. 29, the barrier metal 104 is formed on the side face and the bottom faces of the trench 301. Furthermore, an expansion inhibition suppression film 131j is also formed on the side faces of the trench 301.

In the pixel 12j, providing the trench 301 increases the amount of copper (Cu), for example, constituting the electrode 105, and thus the amount of expansion can be increased.

In the configuration illustrated in FIG. 29 too, the electrode 105 is configured to be in contact with the expansion inhibition suppression film 131j. The expansion inhibition suppression film 131j is constituted by a material having a low adhesion strength or a material having a low coefficient of friction, as in Embodiment 1 and the like. Accordingly, the expansion inhibition suppression film 131j does not inhibit the expansion of the copper of the electrode 105 within the connection hole 121 during the heat treatment. The expansion of the electrode 105 is therefore not inhibited, and the bonding with the electrode provided on the substrate to be affixed can be performed without problems.

### Manufacture According to Embodiment 10

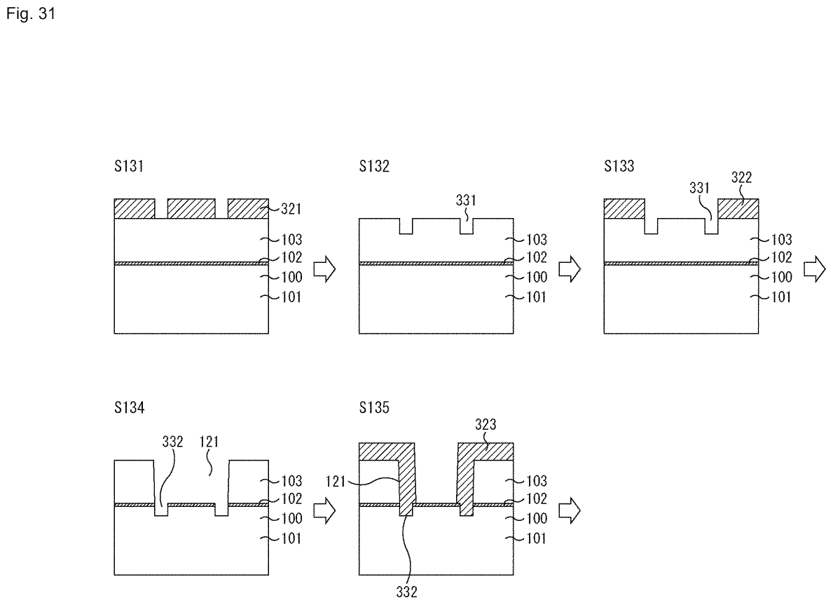

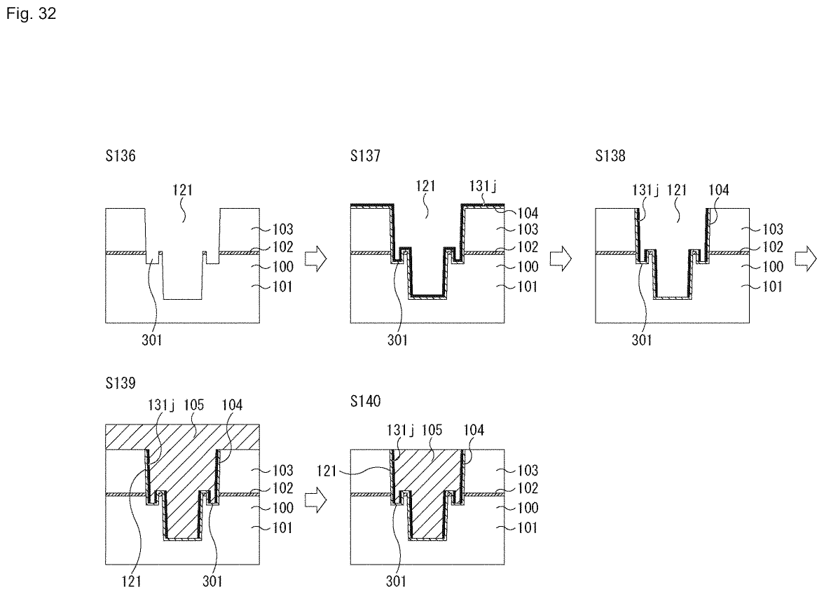

The manufacture of the pixel 12j having the configuration of the electrode 105 illustrated in FIG. 30 will be described with reference to FIGS. 31 and 32. The manufacture of the part of the electrode 105 will be described with reference to FIGS. 31 and 32.

In step S131, a substrate is prepared in which the stacked film 100 is formed, with the interlayer insulating film 101, the liner insulating film 102, and the interlayer insulating film 103 stacked therein. A resist is applied to the stacked film 100 to generate a resist pattern 321 in which the part in which the trench 301 is to be formed is open.

In step S132, dry etching is performed using the generated resist pattern 321 as a mask, and a groove 331 is formed in the stacked film 100.

In step S133, a resist pattern 322 in which the region to serve as the connection hole 121 is open is generated.

In step S134, dry etching is performed using the generated resist pattern 322 as a mask, and the connection hole 121 is formed in the stacked film 100. A recess-shaped groove 332 is formed in the bottom face of the hole that is to serve as the connection hole 121, in the part where the groove 331 was located.

In step S135, a resist pattern 323 is generated in which the region where the interconnect hole 122 is to be formed is open.

In step S136 (FIG. 32), dry etching is performed using the generated resist pattern 322 as a mask to form the interconnect hole 122 in the interlayer insulating film 101 of the stacked film 100.

In step S137, the barrier metal 104 is formed by sputtering, for example. The barrier metal 104 is formed on the side faces and the bottom faces of the connection hole 121 and the interconnect hole 122, and is also formed on a top face of the interlayer insulating film 103. The expansion inhibition suppression film 131j is also formed on the barrier metal 104 that has been formed. The expansion inhibition suppression film 131 can also be formed by sputtering. In step S137, the barrier metal 104 and the expansion inhibition suppression film 131j are formed on the side face and the bottom face of the trench 301.

If a material having a low adhesion strength, such as an oxide film, is used as the expansion inhibition suppression film 131j, the oxide film is formed in step S137. If a material having a low coefficient of friction, such as carbon, is used as the expansion inhibition suppression film 131j, a carbon film is formed in step S137.

In step S138, the extra expansion inhibition suppression film 131j is removed by an etch-back process. Because the expansion inhibition suppression film 131j is removed by the etch-back process, the expansion inhibition suppression film 131j on the surface of the interlayer insulating film 103, the expansion inhibition suppression film 131j on the bottom face of the connection hole 121, the expansion inhibition suppression film 131j on the bottom face of the interconnect hole 122, and the expansion inhibition suppression film 131j on the bottom face of the trench 301 are removed. In other words, the expansion inhibition suppression film 131j formed in regions other than the expansion inhibition suppression film 131j formed on the side face of the connection hole 121, the side face of the interconnect hole 122, and the side face of the trench 301 is removed.

In step S139, the material of the electrode 105, e.g., copper (Cu), is embedded in the connection hole 121, the interconnect hole 122, and the trench 301. The electrode 105, constituted by copper (Cu), is embedded in the connection hole 121, the interconnect hole 122, and the trench 301 by Cu sputtering followed by Cu plating.

In step S140, the Cu is polished and flattened. In this step, the excess part of the Cu and the barrier metal 104 on the top face of the interlayer insulating film 103 are removed by CMP.

An electrode including the trench 301 illustrated in FIG. 30, and the expansion inhibition suppression film 131j as well, can be formed through the foregoing steps.

### Embodiment 11

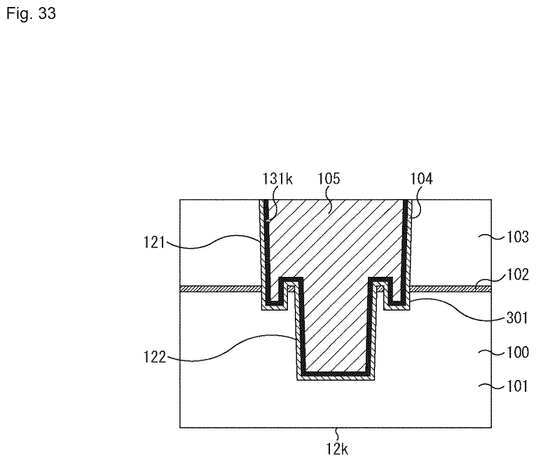

FIG. 33 is a diagram illustrating an example of the configuration of a pixel 12k according to Embodiment 11 in which the present technique is applied. Parts that are the same between the pixel 12k according to Embodiment 11, illustrated in FIG. 33, and the pixel 12j according to Embodiment 10, illustrated in FIG. 30, will be given the same reference signs, and descriptions thereof will be omitted as appropriate.

When comparing the pixel 12k according to Embodiment 11, illustrated in FIG. 33, and the pixel 12j according to Embodiment 10, illustrated in FIG. 30, the region in which an expansion inhibition suppression film 131k of the pixel 12k is formed is different from the region in which the expansion inhibition suppression film 131j of the pixel 12j is formed. The other points are the same.

Unlike the pixel 12j according to Embodiment 10 illustrated in FIG. 30, the expansion inhibition suppression film 131k of the pixel 12k illustrated in FIG. 33 is provided on the bottom face of the connection hole 121, the bottom face of the interconnect hole 122, and the bottom face of the trench 301, but the other points are the same. The expansion inhibition suppression film 131k of the pixel 12k illustrated in FIG. 33 is provided on the side face and the bottom face of the connection hole 121, the side face and the bottom face of the interconnect hole 122, and the side face and the bottom face of the trench 301.

In the configuration illustrated in FIG. 33, the expansion inhibition suppression film 131k is formed in the connection hole 121, the interconnect hole 122, and the trench 301. The copper of the electrode 105 is in contact with the expansion inhibition suppression film 131k, but is not in contact with the barrier metal 104. The expansion inhibition suppression film 131k is constituted by a material having a low adhesion strength or a material having a low coefficient of friction, as in Embodiment 1 and the like. However, when the expansion inhibition suppression film 131k is also formed on the bottom face of the interconnect hole 122, as with the pixel 12k illustrated in FIG. 33, a conductive material is used as the material of the expansion inhibition suppression film 131k.

In the configuration illustrated in FIG. 33 too, the expansion inhibition suppression film 131k does not inhibit the expansion of the copper of the electrode 105 during the heat treatment. The expansion of the electrode 105 is therefore not inhibited, and the bonding with the electrode provided on the substrate to be affixed can be performed without problems.

### Manufacture According to Embodiment 11

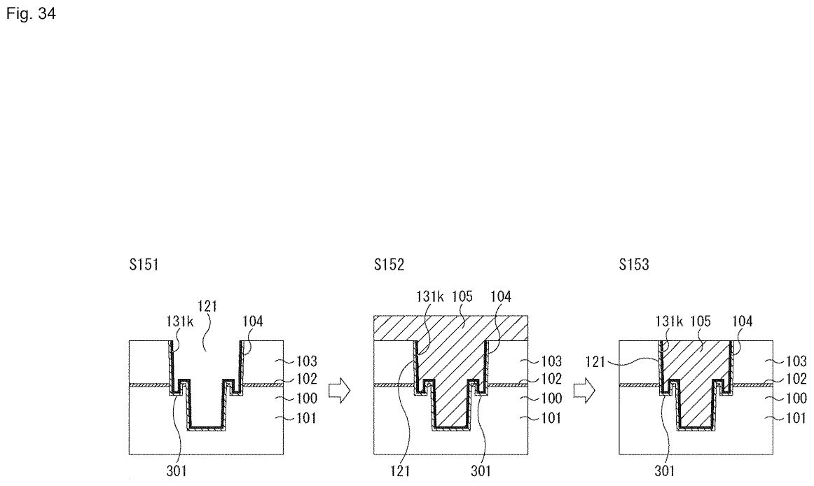

The manufacture of the pixel 12j having the configuration of the electrode 105 illustrated in FIG. 33 will be described with reference to FIG. 34. The manufacture of the part of the electrode 105 will be described with reference to FIG. 34.

In step S151, a semiconductor substrate is prepared in which the stacked film 100 is formed, with barrier metal 104 and the expansion inhibition suppression film 131j formed therein. By executing steps S131 to S136 described with reference to FIGS. 31 and 32 in the steps before step S151, the barrier metal 104 and the expansion inhibition suppression film 131k are formed in the connection hole 121, the interconnect hole 122, and the trench 301.

In step S152, the material of the electrode 105, e.g., copper (Cu), is embedded in the connection hole 121, the interconnect hole 122, and the trench 301. In step S153, the Cu is polished and flattened. Steps S152 and S153 are basically the same steps as steps S139 and S140 (FIG. 32). By omitting the etch-back process performed in step S138 of FIG. 32 and polishing the Cu, an electrode in which the expansion inhibition suppression film 131k is also present on the bottom faces of the connection hole 121, the interconnect hole 122, and the trench 301 is formed, as illustrated in FIG. 33.

An electrode including the trench 301 illustrated in FIG. 33, and the expansion inhibition suppression film 131k as well, can be formed through the foregoing steps.

### Embodiment 12

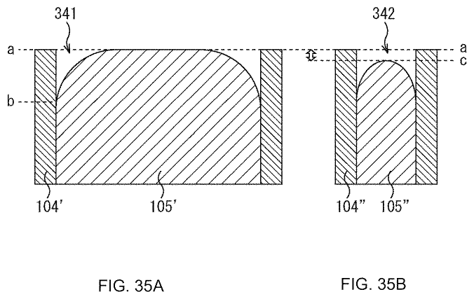

The tendency for the amount of recessing to increase as the electrode 105 is miniaturized will be described with reference to FIG. 35.

A in FIG. 35 represents an electrode 105′ formed at a relatively large size (parts to which the present technique are not applied will be indicated by dashes or double dashes), and B in FIG. 35 represents a miniaturized electrode 105″.

Referring to A in FIG. 35, the central part of the electrode 105′ is formed up to a position a, and both ends are formed up to a position b deeper than the position a. The region in which the electrode 105′ is not formed, from the position a to the position b, is taken as a recess region 341.

Referring to B in FIG. 35, the central part of the electrode 105″ is formed up to a position c deeper than the position a. The region in which the electrode 105″ is not formed, from the position a to the position c, is taken as a recess region 342.

As indicated in A in FIG. 35, with the electrode 105′ formed at a relatively large size, the recessing only has influence at the end of the open side of the electrode 105′, but as indicated in B in FIG. 35, with the miniaturized electrode 105″, the influence of the recessing may extend to the entire open side of the electrode 105″. As the recess region 342 of the electrode 105″ increases, i.e., as the distance from the position a to the position c increases, when the semiconductor substrate is affixed to another semiconductor substrate and the electrodes 105″ are connected to each other, the electrode 105″ will not expand sufficiently, the electrodes 105″ will not contact each other, and contact defects may occur.

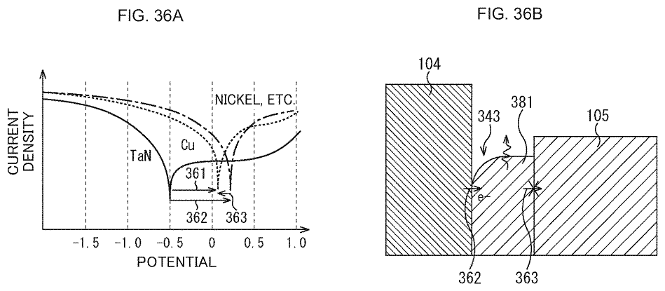

One factor that causes the recess region 341 and the recess region 342 to occur is corrosion of the electrode 105′ (hereinafter, when there is no need to distinguish between the electrode 105′ and the electrode 105″, the electrode 105′ will be used as an example). Corrosion of the electrode 105′ will be described with reference to FIG. 36.

The descriptions will continue using an example in which a barrier metal 104′ is formed of tantalum nitride (TaN) and the electrode 105′ is formed of copper (Cu). As illustrated in FIG. 35, when the barrier metal 104′ and the electrode 105′ are formed in contact, i.e., when different metals are formed in contact, a current density difference between the adjacent metals may cause corrosion called galvanic corrosion, which causes charge transfer, to occur.

A in FIG. 36 is a graph in which the vertical axis represents current density and the horizontal axis represents potential, and the graph expresses the relationship between the current density and the potential of a predetermined metal. A in FIG. 36 is a graph for metals such as TaN, Cu, nickel, and the like.

TaN has a lower potential than Cu, and thus a current path 361 in which a charge is transferred from TaN to Cu is generated. As illustrated in FIG. 35, the current path 361 in which a charge is transferred from the barrier metal 104′ to the electrode 105′ is formed between the barrier metal 104′, which is formed of TaN, and the electrode 105′, which is formed of Cu, and the electrode 105′ is charged as a result. Slurry retention occurs when the electrode 105′ is charged, and the recess region 341 is formed as a result.

Such corrosion may occur in the entirety of the Cu at the open side in the miniaturized electrode 105″ illustrated in B in FIG. 35, and a large recess region 342 may form as a result. A structure that suppresses the effects of corrosion at least in the electrode 105, and in which such a recess region 342 does not arise, will be described below.

Referring to B in FIG. 36, a reaction film 381 is provided between the barrier metal 104 and the electrode 105 to reduce the effects of corrosion on the electrode 105. The reaction film 381 is a film formed of a metal having a higher potential than the electrode 105.

Referring to A in FIG. 36, a current path 362 in which a charge is transferred from TaN to nickel is generated by providing a reaction film 81 having a higher potential than Cu, e.g., a reaction film 81 formed of nickel. Referring to B in FIG. 36, the current path 362 from the barrier metal 104 to the reaction film 381 is generated. As a result, a recess region 343 is generated in a part of the region where the reaction film 381 and the barrier metal 104 are in contact.

Referring to A in FIG. 36, when nickel and Cu are compared, nickel has a higher potential than Cu, and thus a current path 363 in which a charge is transferred from nickel to Cu is not generated. Referring to B in FIG. 36, the current path 363 from the reaction film 381 to the electrode 105 is not generated.

Providing the reaction film 381 between the barrier metal 104 and the electrode 105 makes it possible to suppress the occurrence of recessing caused by corrosion of the electrode 105.

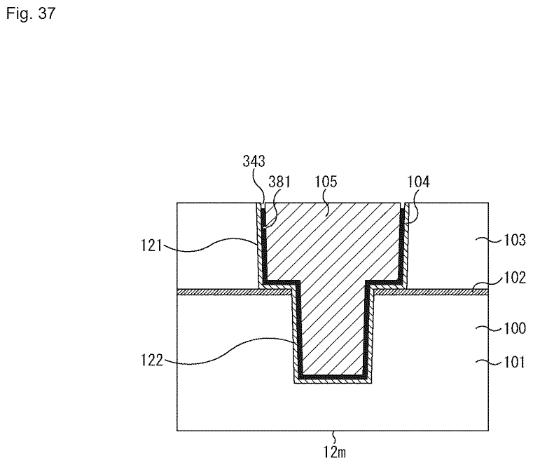

FIG. 37 is a diagram illustrating an example of the configuration of a pixel 12m according to Embodiment 12 in which the present technique is applied. Parts that are the same between the pixel 12m according to Embodiment 12, illustrated in FIG. 37, and the pixel 12d according to Embodiment 4-1, illustrated in FIG. 12, will be given the same reference signs, and descriptions thereof will be omitted as appropriate.

As illustrated in FIG. 37, the electrode formed at the bonded part is configured by forming an electrode 105 in a stacked film 100 in which an interlayer insulating film 101, a liner insulating film 102, and an interlayer insulating film 103 are stacked. The barrier metal 104 and the reaction film 381 are formed between the stacked film 100 and the electrode 105. More specifically, the barrier metal 104 and the reaction film 381 are formed on the side faces and the bottom faces of the connection hole 121 and the interconnect hole 122.

The reaction film 381 is a film formed of a material having a higher potential than the material constituting the electrode 105. Metals such as graphite, platinum, zirconium, titanium, silver, nickel, or alloys having these as the principal components can be used as the material of the reaction film 381, for example.

FIG. 37 illustrates a state in which the part of the reaction film 381 located on the open side (the upper side in the figure) experiences the corrosion described with reference to FIG. 36, and the recess region 343 is produced. Viewing the top face of the interlayer insulating film 103, the recess region 343 is present at the location of the reaction film 381, and a recessed shape is formed therein. Depending on the extent of the recessing, the recess region 343 may be large, or may be small (or nonexistent).

A structure in which the reaction film 381 is provided between the barrier metal 104 and the electrode 105, such that the barrier metal 104 does not corrode the electrode 105, can be used, which makes it possible to reduce the amount of recessing. Reducing the amount of recessing makes it possible to prevent a situation where, when the semiconductor substrate is affixed to another semiconductor substrate and the electrodes 105 contact each other, the expansion of the electrodes 105 is insufficient, the electrodes 105 do not make contact with each other, and contact defects occur.

### Manufacture According to Embodiment 12

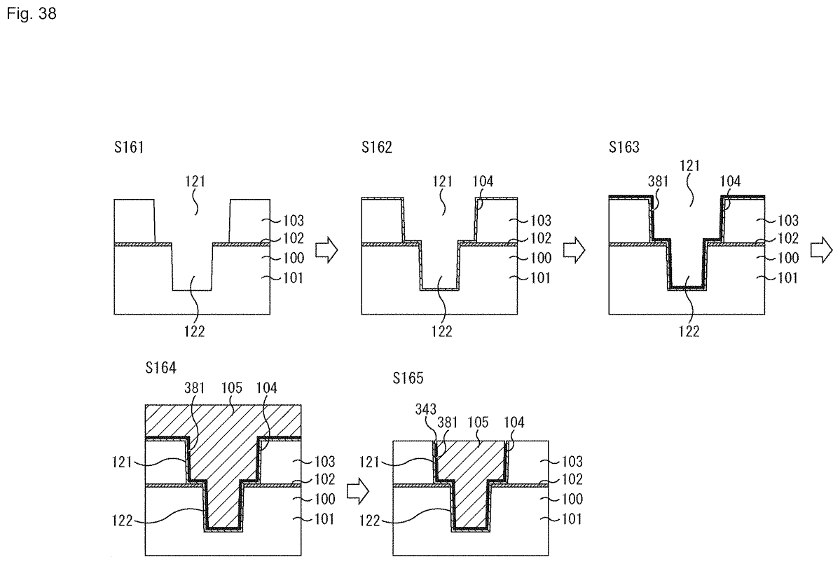

The manufacture of the pixel 12m having the configuration of the electrode 105 illustrated in FIG. 37 will be described with reference to FIG. 38. The manufacture of the part of the electrode 105 will be described with reference to FIG. 38.

In step S161, a semiconductor substrate is prepared in which the stacked film 100 is formed, with the interlayer insulating film 101, the liner insulating film 102, and the interlayer insulating film 103 stacked therein. The connection hole 121 and the interconnect hole 122 are formed by etching the stacked film 100. For example, in a photolithography step, a photoresist is applied to generate a resist pattern to form the connection hole 121, and dry etching is performed using the resist pattern as a mask to form the connection hole 121. The interconnect hole 122 is formed through a similar step.

In step S162, the barrier metal 104 is formed by sputtering, for example. The barrier metal 104 is formed on the side faces and the bottom faces of the connection hole 121 and the interconnect hole 122, and is also formed on a top face of the interlayer insulating film 103.

In step S163, the reaction film 381 is formed on the barrier metal 104. The reaction film 381 can also be formed by sputtering. A material having a higher potential than the material used for the barrier metal 104 and the electrode 105 is used for the reaction film 381.

In step S164, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S165, the Cu is polished and flattened. In this step, the excess part of the Cu, and the barrier metal 104 and the reaction film 381 on the top face of the interlayer insulating film 103, are removed by CMP.

An electrode including the reaction film 381 illustrated in FIG. 37 can be formed through the foregoing steps.

### Embodiment 13

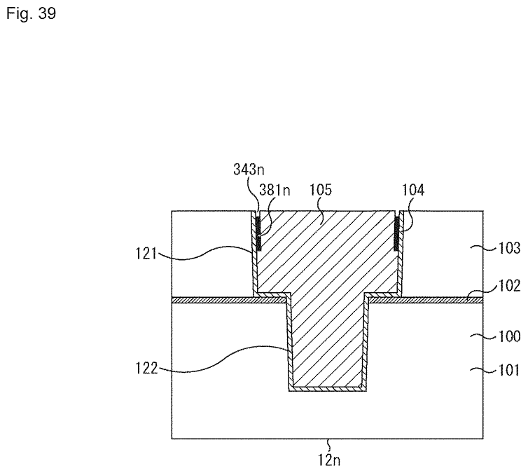

FIG. 39 is a diagram illustrating an example of the configuration of a pixel 12n according to Embodiment 13 in which the present technique is applied. Parts that are the same between the pixel 12n according to Embodiment 13, illustrated in FIG. 39, and the pixel 12m according to Embodiment 12, illustrated in FIG. 37, will be given the same reference signs, and descriptions thereof will be omitted as appropriate.

When comparing the pixel 12n according to Embodiment 13, illustrated in FIG. 39, and the pixel 12m according to Embodiment 12, illustrated in FIG. 37, the region in which a reaction film 381n of the pixel 12n is formed is different from the region in which the reaction film 381 of the pixel 12m is formed. The other points are the same.

The reaction film 381n of the pixel 12n illustrated in FIG. 39 is provided on a part of the side face of the connection hole 121. The reaction film 381n is formed on the side face of the connection hole 121, to a predetermined depth from the side on which the bonding face is located.

The reaction film 381n is formed at a depth of, for example, at least 10 nm from the surface of the stacked film 100. The reaction film 381n is formed to be at least 5 nm thick, for example. The reaction film 381n is formed at a film thickness and depth at which a slurry can enter and produce a volume that reacts sufficiently even if the reaction film 381n melts and a gap is formed.

As described with reference to FIGS. 35 and 36, the recessing occurs on the side where the bonding face of the electrode 105 is located, and thus the configuration of the pixel 12n illustrated in FIG. 39 is a configuration in which the reaction film 381n is provided on the side on which the bonding face, where recessing is likely to occur, is located. Even with such a configuration, the reaction film 381n can prevent the recessing from reaching the electrode 105, and the bonding with the electrode provided on the other substrate to be affixed can be performed without problems.

### Manufacture According to Embodiment 13

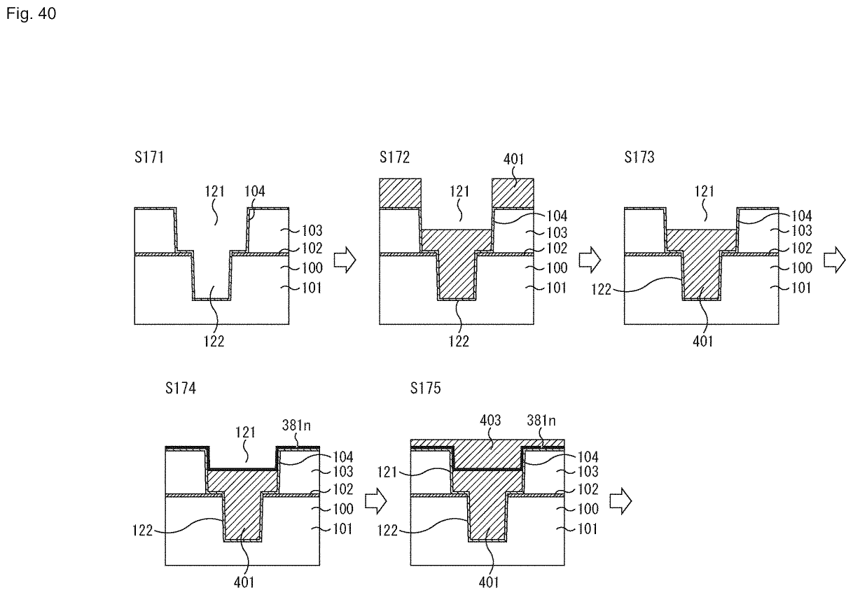

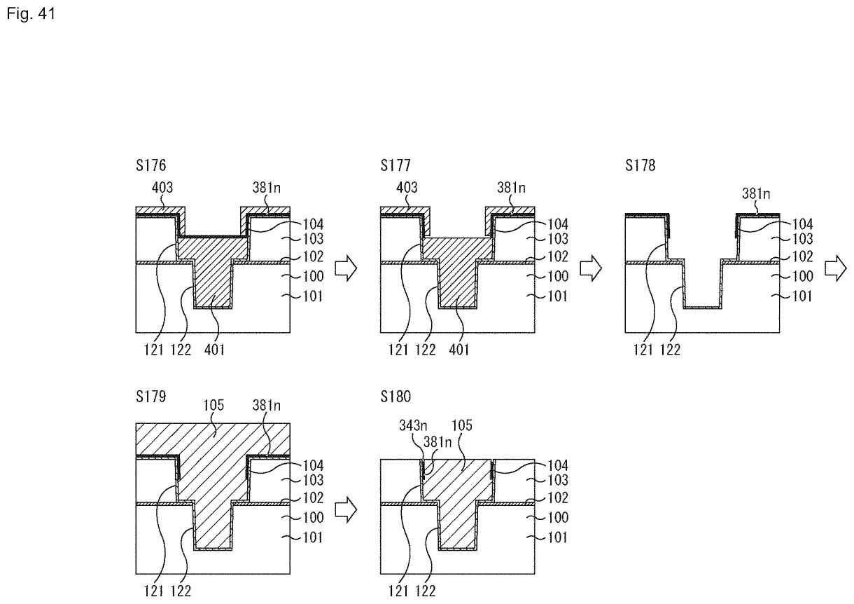

The manufacture of the pixel 12n having the configuration of the electrode 105 illustrated in FIG. 39 will be described with reference to FIGS. 40 and 41. The manufacture of the part of the electrode 105 will be described with reference to FIGS. 40 and 41.

In step S171, a substrate is prepared in which the barrier metal 104 is formed on the stacked film 100, with the interlayer insulating film 101, the liner insulating film 102, and the interlayer insulating film 103 stacked therein. In step S172, the resist pattern 401 is formed. The resist pattern 401 is formed such that the side face in the connection hole 121 where the reaction film 381n is to be formed is open.

In step S173, the resist pattern 401 is partially removed. The resist pattern 401 to be removed is the resist pattern 401 formed on the stacked film 100. In other words, the resist pattern is removed so as to leave the resist pattern 401 formed in the connection hole 121 and the interconnect hole 122.

In step S174, the reaction film 381n is formed by sputtering, for example. The reaction film 381n is formed on the open side face of the connection hole 121, the top face of the resist pattern 401, and the top face of the interlayer insulating film 103.

In step S175, a resist pattern 403 is generated. The resist pattern 403 is generated on the reaction film 381n formed in the process of step S174.

In step S176 (FIG. 41), to remove the reaction film 381n formed on the resist pattern 401 where the resist pattern 403 is to be partially removed, the resist pattern 403 in the region where the reaction film 381n formed on the resist pattern 401 is present is removed.

In step S177, the reaction film 381n in the open region of the resist pattern 403 is removed by an etch-back process. In step S178, the resist pattern 403 is removed.

In step S179, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S175, the Cu is polished and flattened. In this step, the excess part of the Cu, and the barrier metal 104 and the reaction film 381n on the top face of the interlayer insulating film 103, are removed by CNP.

An electrode including the reaction film 381n illustrated in FIG. 39 can be formed through the foregoing steps.

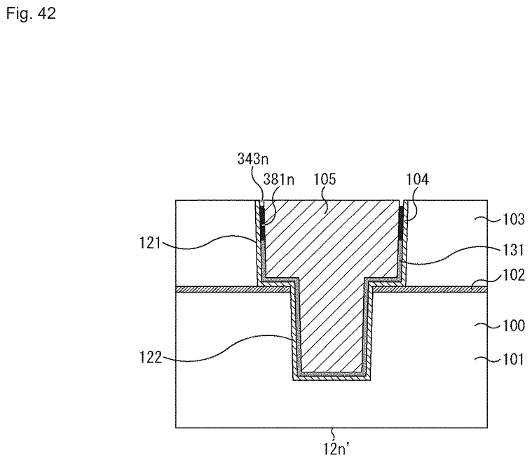

When the reaction film 381n is provided in the part of the connection hole 121, as in the pixel 12n illustrated in FIG. 39, the expansion inhibition suppression film 131 may be provided in the part where the reaction film 381n is not provided. FIG. 42 illustrates an example of a pixel 12n′ having such a configuration.

The reaction film 381n is formed at a predetermined size on the side face of the connection hole 121 of the pixel 12n′ illustrated in FIG. 42, on the side where the bonding face is located. The expansion inhibition suppression film 131 is formed on the region of the side face of the connection hole 121 of the pixel 12n′ where the reaction film 381n is not formed, the bottom face of the connection hole 121, and the side face and the bottom face of the interconnect hole 122. Such a configuration enables a configuration in which the amount of recessing is suppressed and the expansion of the electrode 105 is not inhibited during the heat treatment.

Embodiment 13 can be carried out in combination with any one or more of Embodiments 1 to 11.

### Embodiment 14

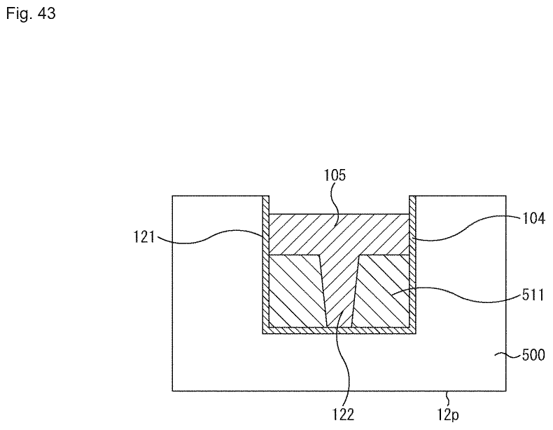

FIG. 43 is a diagram illustrating an example of the configuration of a pixel 12p according to Embodiment 14 in which the present technique is applied.

In the pixel 12p illustrated in FIG. 43, the connection hole 121 and the interconnect hole 122 are formed in an insulating film 500. Copper (Cu), for example, which is to serve as the electrode 105, is embedded in the connection hole 121 and the interconnect hole 122.

An expansion support film 511 is formed around the interconnect hole 122. The expansion support film 511 is configured to have substantially the same thickness as the depth of the interconnect hole 122. Although not illustrated, the electrode 105 in the interconnect hole 122 is connected to an electrode in the interconnect layer. The interconnect hole 122 and the electrode 105 are formed in a central part of the expansion support film 511 in order to connect to the interconnect.

The barrier metal 104 is formed so as to surround the electrode 105 and the expansion support film 511. The barrier metal 104 is formed in a continuous manner between the electrode 105 and the insulating film 500 in the connection hole 121, between the expansion support film 511 and the insulating film 500, and on the bottom face of the interconnect hole 122.

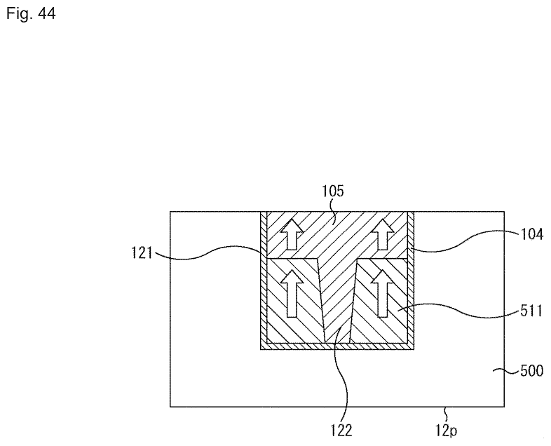

As illustrated in FIG. 44, the expansion support film 511 functions as a film that pushes the electrode 105 up toward the bonding face side during the heat treatment to support expansion.

As illustrated in FIG. 44, during the heat treatment, the expansion support film 511 expands, and the electrode 105 on the expansion support film 511 receives a force moving toward the bonding face side (the upper side in the figure) from the expansion of the expansion support film 511. The electrode 105 itself has a force from expansion toward the bonding face side, and the force from the expansion support film 511 is added to that force. Accordingly, the expansion force of the electrode 105 is strengthened, and the bonding with the electrode provided on the other substrate to be affixed can be performed without problems.

The expansion support film 511 is constituted by a material that is more susceptible to thermal expansion than the electrode 105 in order to achieve the function of assisting the expansion when the electrode 105 thermally expands. A material having a high thermal expansion coefficient is used for the expansion support film 511. When copper (Cu) is used for the electrode 105, a material having a higher thermal expansion coefficient than the thermal expansion coefficient of copper is used for the expansion support film 511. Because the thermal expansion coefficient of copper is 16.8 ppm/K, when copper is used for the electrode 105, a material having a thermal expansion coefficient of at least 16.8 ppm/K is used as the material of the expansion support film 511, for example.

A resin, a metal, or an insulating material is used as the material of the expansion support film 511, for example. When a resin is used as the material of the expansion support film 511, polyimide, epoxy resin, fluorine resin, or the like can be used, for example.

When a metal is used as the material of the expansion support film 511, aluminum, tin, zinc, lead, magnesium, solder, or the like can be used, for example. When an insulating material is used as the material of the expansion support film 511, lithium titanium oxide/lithium titanate (LTO), Low-k (a material having a low dielectric constant k), or the like can be used, for example.

FIG. 43 illustrates an example in which the surface on the side of the electrode 105 of the pixel 12p where the bonding face is located is recessed from the surface of the insulating film 500 due to recessing. As described with reference to FIG. 44, even when the electrode 105 is recessed due to recessing, the expansion of the electrode 105 is supported by the expansion force of the expansion support film 511 during the heat treatment. Accordingly, the bonding with the electrode provided on the other substrate to be affixed can be performed without problems during the affixing to the other substrate.

### Manufacture According to Embodiment 14

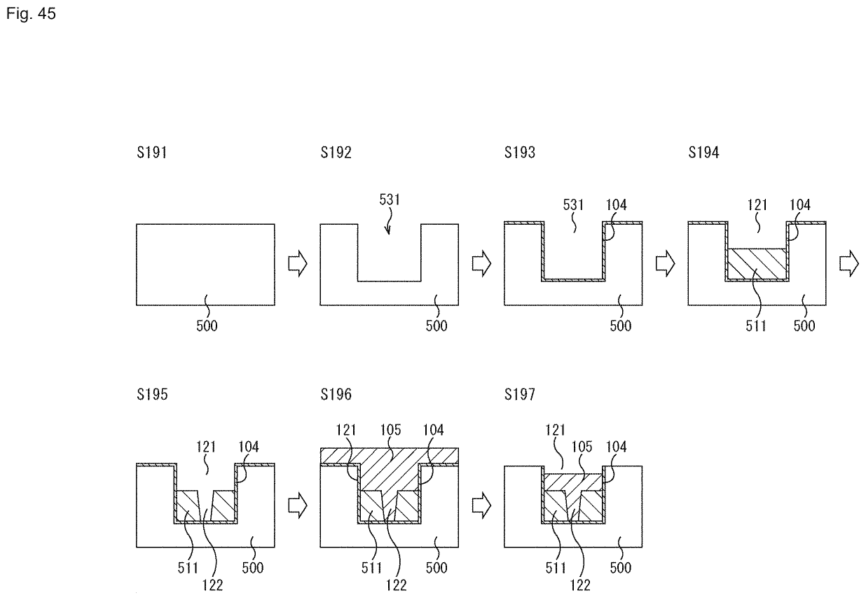

The manufacture of the pixel 12p having the configuration of the electrode 105 illustrated in FIG. 43 will be described with reference to FIG. 45. The manufacture of the part of the electrode 105 will be described with reference to FIG. 45.

In step S191, a substrate is prepared in which the insulating film 500 is formed. In step S192, a groove 531 is formed in the insulating film 500 by etching. The groove 531 is a region where the electrode 105 and the expansion support film 511 are to be formed. For example, in a photolithography step, a photoresist is applied to generate a resist pattern to form the groove 531, and dry etching is performed using the resist pattern as a mask to form the groove 531.

In step S193, the barrier metal 104 is formed by sputtering, for example. The barrier metal 104 is formed on the side face and the bottom face of the groove 531, and the surface of the insulating film 500.

In step S194, the expansion support film 511 is formed on the barrier metal 104 in the groove 531. Forming the expansion support film 511 in step S194 also forms a space corresponding to the connection hole 121.

In step S195, the expansion support film 511 is partially removed, which forms a region corresponding to the interconnect hole 122. Similar to the process of step S191, for example, a resist pattern is generated in which a part to serve as the interconnect hole 122 is open, and dry etching is performed using the resist pattern as a mask to form the interconnect hole 122.

In step S196, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S197, the Cu is polished and flattened. In this step, the excess part of the Cu and the barrier metal 104 on the top face of the insulating film 500 are removed by CMP.

An electrode including the expansion support film 511 illustrated in FIG. 43 can be formed through the foregoing steps.

### Embodiment 15

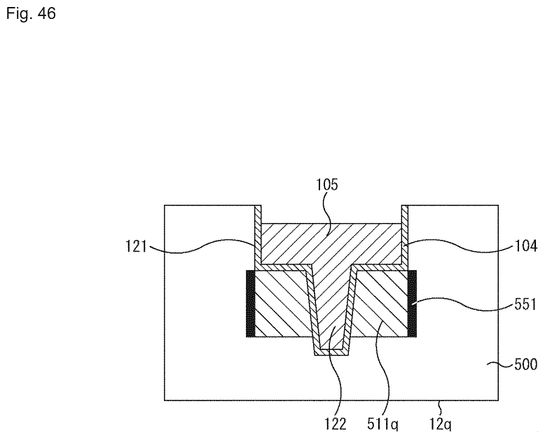

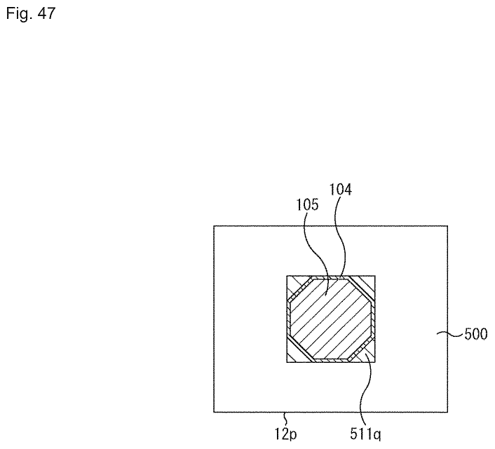

FIG. 46 is a diagram illustrating an example of the cross-sectional configuration of a pixel 12q according to Embodiment 14 in which the present technique is applied, and FIG. 47 is a diagram illustrating the planar configuration of the pixel 12q. Parts that are the same between the pixel 12q according to Embodiment 15, illustrated in FIG. 46, and the pixel 12p according to Embodiment 14, illustrated in FIG. 43, will be given the same reference signs, and descriptions thereof will be omitted as appropriate.

In the pixel 12q illustrated in FIG. 46, the connection hole 121 and the interconnect hole 122 are formed in the insulating film 500. Copper (Cu), for example, which is to serve as the electrode 105, is embedded in the connection hole 121 and the interconnect hole 122. The barrier metal 104 is formed so as to surround the electrode 105. The barrier metal 104 is formed in a continuous manner on the side face and the bottom face of the connection hole 121, and the side face and the bottom face of the interconnect hole 122.

An expansion support film 511p is formed around the interconnect hole 122. The barrier metal 104 is formed between the electrode 105 in the interconnect hole 122 and the expansion support film 511. The periphery of the expansion support film 511p is surrounded by an oxide film 551. The oxide film 551 is formed between the expansion support film 511p and the insulating film 500.

In the configuration of the pixel 12q illustrated in FIG. 46, an expansion support film 511q is formed in a lower layer of the electrode 105 in the connection hole 121.

Referring to the example of the planar configuration of the pixel 12q illustrated in FIG. 47, the electrode 105 is formed in a central part, and the expansion support film 511q is formed around the electrode 105. In the example illustrated in FIG. 47, the electrode 105 is octagonal, i.e., the connection hole 121 is formed in an octagonal shape. The expansion support film 511q is formed in a quadrangular shape. Although an example in which the electrode 105 is octagonal and the expansion support film 511q is quadrangular is described here, other shapes may be used instead.

The expansion support film 511q is formed using the same resin, metal, or insulating material as the expansion support film 511 of the pixel 12p according to Embodiment 14.

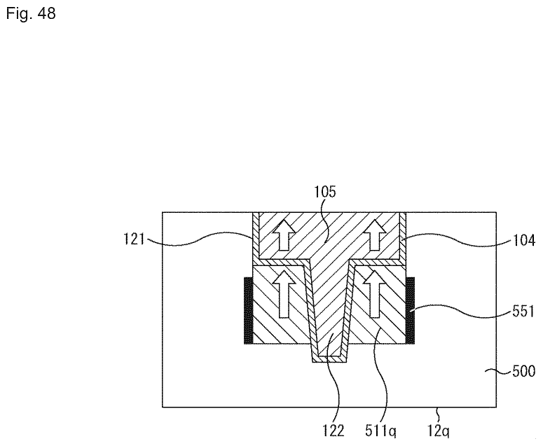

As illustrated in FIG. 48, the expansion support film 511q functions as a film that pushes the electrode 105 up toward the bonding face side during the heat treatment to support expansion. As illustrated in FIG. 48, during the heat treatment, the expansion support film 511q expands, and the barrier metal 104 and the electrode 105 on the expansion support film 511q receives a force moving toward the bonding face side (the upper side in the figure) from the expansion of the expansion support film 511q. The electrode 105 itself has a force from expansion toward the bonding face side, and the force from the expansion support film 511q is added to that force. Accordingly, the expansion force of the electrode 105 is strengthened, and when affixing to another substrate, the bonding with the electrode provided on the other substrate to be affixed can be performed without problems.

FIG. 46 illustrates an example in which the surface on the side of the electrode 105 of the pixel 12q where the bonding face is located is recessed from the surface of the insulating film 500 due to recessing. As described with reference to FIG. 44, even when the electrode 105 is recessed due to recessing, the expansion of the electrode 105 is supported by the expansion force of the expansion support film 511q. Accordingly, the bonding with the electrode provided on the other substrate to be affixed can be performed without problems during the affixing to the other substrate.

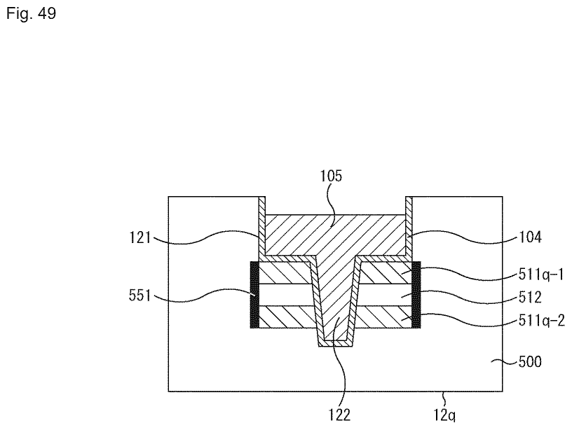

FIG. 49 illustrates another example of the cross-sectional configuration of the pixel 12q according to Embodiment 14. In the pixel 12q illustrated in FIG. 49, the expansion support film 511 is constituted by three layers. The expansion support film 511q of the pixel 12q is constituted by an expansion support film 511q-1, an interlayer film 512, and an expansion support film 511q-2. The expansion support film 511q-1 and the expansion support film 511q-2 may be constituted by the same material, or may be constituted by different materials. The interlayer film 512 may be constituted by the same material as the insulating film 500.

Although a case where the expansion support film 511 is constituted by three layers is described here as an example, the number of layers is not limited to three, and the expansion support film 511 can be constituted by multiple layers.

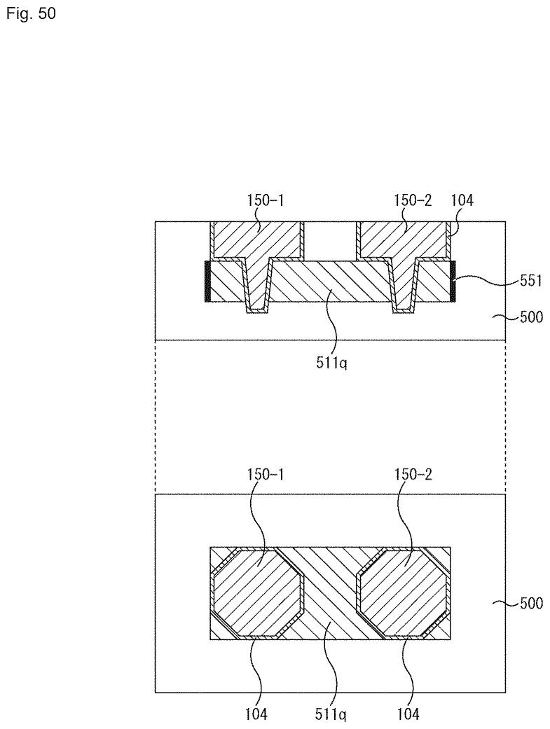

When the electrode 105 is provided in close proximity, a configuration in which the expansion support film 511q is provided can be used, as illustrated in FIG. 50. The upper part of FIG. 50 illustrates an example of the cross-sectional configuration of the parts of two adjacent electrode 105 in the pixel 12q, and the lower part of FIG. 50 illustrates an example of the planar configuration.

In the example of the expansion support film 511q illustrated in FIG. 50, the expansion support film 511q is formed spanning the adjacent electrodes 105-1 and 105-2. The expansion support film 511q is formed in a region which is in layer below the electrode 105-1 and the electrode 105-2, and is between the electrodes. In the example illustrated in the upper part of FIG. 50, the oxide film 551 surrounding the expansion support film 511 is formed on the left side of the lower layer of the electrode 105-1 and on the right side of the lower layer of the electrode 105-2.

The expansion support film 511q may be formed for each electrode 105, or may be formed spanning a plurality of electrodes 105.

### Manufacture According to Embodiment 15

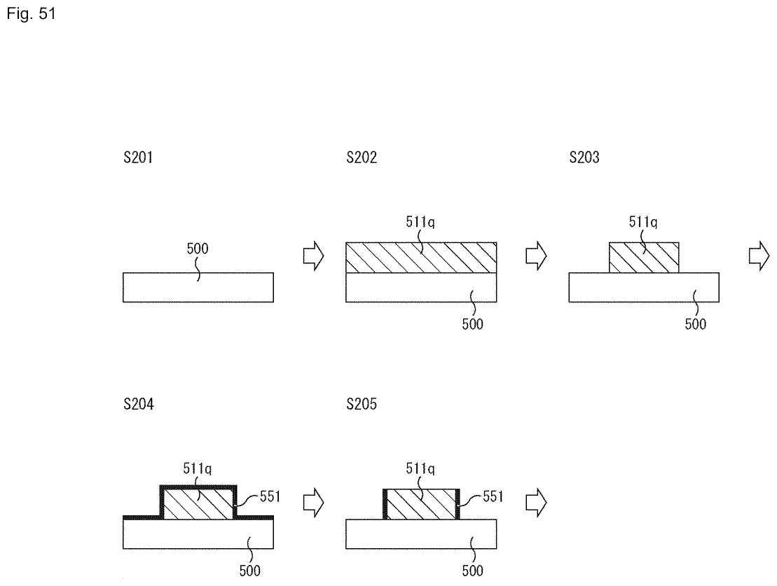

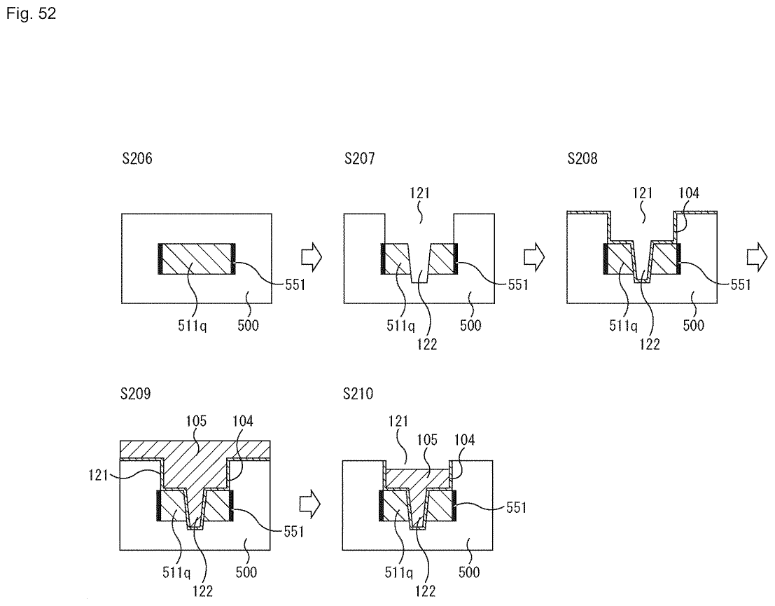

The manufacture of the pixel 12q having the configuration of the electrode 105 illustrated in FIG. 46 will be described with reference to FIGS. 51 and 52. The manufacture of the part of the electrode 105 will be described with reference to FIGS. 51 and 52.

In step S201, a substrate is prepared in which the insulating film 500 is formed. In step S202, a film that is to serve as the expansion support film 511q is formed on the insulating film 500.

In step S203, the expansion support film 511q is removed from the regions other than those which are to serve as the expansion support film 511q. For example, a resist pattern in which the region to serve as the expansion support film 511q is masked is generated, and dry etching is performed using the resist pattern as a mask to form the expansion support film 511q.

In step S204, the oxide film 551 is formed. For example, SiN (silicon nitride) can be used as the oxide film 551. The oxide film 551 is formed on the top face and a side face of the expansion support film 511q, and on the top face of the insulating film 500.

In step S205, the extra oxide film 551 is removed. For example, the oxide film 551 formed on the top face of the expansion support film 511q and on the top face of the insulating film 500 is removed through an etch-back process.

In step S206 (FIG. 52), the insulating film 500 is further formed. In step S206, the insulating film 500 is formed in the layer of the part where the connection hole 121 is to be formed.

In step S207, the connection hole 121 and the interconnect hole 122 are formed by dry etching, for example. The interconnect hole 122 is formed by etching the expansion support film 511q, and the connection hole 121 is formed by etching the insulating film 500.

In step S208, the barrier metal 104 is formed by sputtering, for example. The barrier metal 104 is formed on the side face and the bottom face of the connection hole 121, the side face and the bottom face of the interconnect hole 122, and the top face of the insulating film 500.

In step S209, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S210, the Cu is polished and flattened. In this step, the excess part of the Cu and the barrier metal 104 on the top face of the insulating film 500 are removed by CMP. When recessing occurs, the top face of the electrode 105 is located at a position lower than the top face of the insulating film 500, as indicated in the depiction of step S210.

An electrode including the expansion support film 511q illustrated in FIG. 46 can be formed through the foregoing steps.

### Embodiment 16

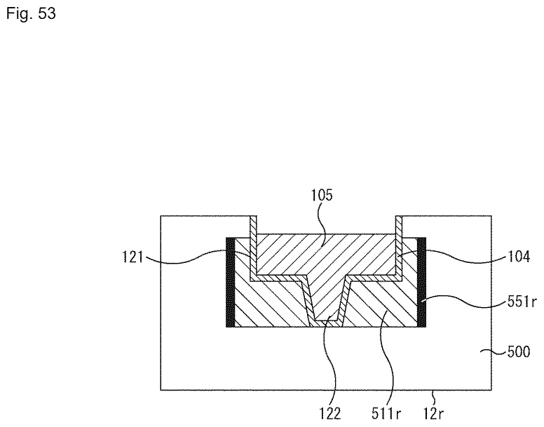

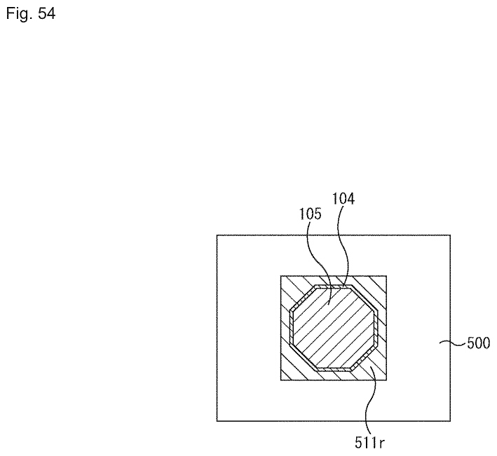

FIG. 53 is a diagram illustrating an example of the cross-sectional configuration of a pixel 12r according to Embodiment 14 in which the present technique is applied, and FIG. 54 is a diagram illustrating the planar configuration of the pixel 12r. Parts that are the same between the pixel 12r according to Embodiment 16, illustrated in FIGS. 53 and 54, and the pixel 12q according to Embodiment 14, illustrated in FIGS. 46 and 47, will be given the same reference signs, and descriptions thereof will be omitted as appropriate.

Compared to the pixel 12q illustrated in FIG. 46, the region where an expansion support film 511r is formed is different in the pixel 12r illustrated in FIG. 53. The other points are the same. The expansion support film 511r of the pixel 12r illustrated in FIG. 53 is provided around the interconnect hole 122, and is also provided in a part around the connection hole 121.

The barrier metal 104 is formed between the electrode 105 in the interconnect hole 122 and the expansion support film 511. The barrier metal 104 is formed between the electrode 105 in the connection hole 121 and the expansion support film 511.

The periphery of the expansion support film 511r is surrounded by an oxide film 551. An oxide film 551r is formed between the expansion support film 511r and the insulating film 500.

In the pixel 12r illustrated in FIG. 53, the expansion support film 511r, which is constituted by a material having a high thermal expansion coefficient, is provided in the lower layer and in the periphery of the electrode 105 of the connection hole 121.

Referring to the example of the planar configuration of the pixel 12r illustrated in FIG. 54, the electrode 105 is formed in a central part, and the expansion support film 511r is formed surrounding the electrode 105. In the example illustrated in FIG. 54, the electrode 105 is octagonal, i.e., the connection hole 121 is formed in an octagonal shape. The expansion support film 511r is formed in a quadrangular shape. Although an example in which the electrode 105 is octagonal and the expansion support film 511r is quadrangular is described here, other shapes may be used instead.

The expansion support film 511r is formed using the same resin, metal, or insulating material as the expansion support film 511 of the pixel 12q according to Embodiment 14.

As in the case of the pixel 12q described with reference to FIG. 48, the expansion support film 511r functions as a film that pushes the electrode 105 up toward the bonding face side during the heat treatment to the support expansion. During the heat treatment, a force from the expansion support film 511r disposed in the lower layer of the connection hole 121, and a force from the expansion support film 511r disposed in the periphery of the connection hole 121, act on the electrode 105 of the pixel 12r illustrated in FIG. 54. Accordingly, the expansion force of the electrode 105 is strengthened, and when affixing to another substrate, the bonding with the electrode provided on the other substrate to be affixed can be performed without problems.

FIG. 53 illustrates an example in which the surface on the side of the electrode 105 of the pixel 12r where the bonding face is located is recessed from the surface of the insulating film 500 due to recessing. Even if the electrode 105 is recessed due to recessing, the expansion of the electrode 105 is supported by the expansion force of the expansion support film 511r. Accordingly, the bonding with the electrode provided on the other substrate to be affixed can be performed without problems during the affixing to the other substrate.

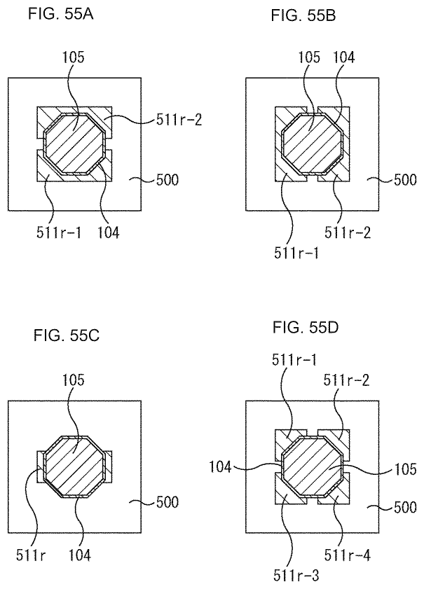

FIG. 55 illustrates another example of the planar configuration of the pixel 12r according to Embodiment 14. The example of the planar configuration of the pixel 12r illustrated in FIG. 55 is an example in which the expansion support film 511r disposed in the lower layer of the electrode 105 of the connection hole 121 is only partially provided. The configuration of the pixel 12r illustrated in FIG. 55 can also be applied to the pixel 12q according to Embodiment 15 illustrated in FIG. 46.

The example illustrated in A in FIG. 55 is an example in which the expansion support film 511r provided in the lower layer of the electrode 105 is divided into two regions, namely an expansion support film 511r-1 and an expansion support film 511r-2. The expansion support film 511r-1 and the expansion support film 511r-2 are disposed above and below, respectively, in the figure. The expansion support film 511r-1 and the expansion support film 511r-2 are separated by the insulating film 500.

The example illustrated in B in FIG. 55 is the same as that illustrated in A in FIG. 55, in that the expansion support film 511r provided in the lower layer of the electrode 105 is divided into two regions, namely the expansion support film 511r-1 and the expansion support film 511r-2. In the example illustrated in B in FIG. 55, the expansion support film 511r-1 and the expansion support film 511r-2 are disposed on the left and right, respectively, in the figure. The expansion support film 511r-1 and the expansion support film 511r-2 are separated by the insulating film 500.

In the example illustrated in C in FIG. 55, the expansion support film 511r provided in the lower layer of the electrode 105 is provided in a rectangular shape near the center of the electrode 105. Alternatively, the expansion support film 511r is not provided in the region directly below the electrode 105, but the expansion support film 511r is provided at the ends of the electrode 105. In this manner, a configuration in which the expansion support film 511r having a predetermined shape and size is provided only in the central region or at the ends of the electrode 105 can also be used.

In the example illustrated in D in FIG. 55, the expansion support film 511r provided in the lower layer of the electrode 105 is divided into four regions, namely expansion support films 511r-1 to 511r-4. The expansion support films 511r-1 to 511r-4 are disposed at the four corners of the electrode 105, respectively. The expansion support films 511r-1 to 511r-4 are separated by the insulating film 500.

When the expansion support film 511r is also disposed around the electrode 105, as in the pixel 12r illustrated in FIG. 53, the expansion support film 511r around the electrode 105 is also formed according to the shapes indicated in A in FIG. 55 to D in FIG. 55.

The regions, sizes, shapes, and the like in which the expansion support film 511 is provided are not limited to those described above, and the expansion support film 511 may be formed and disposed in regions, sizes, shapes, and the like other than those described above.

### Manufacture According to Embodiment 16

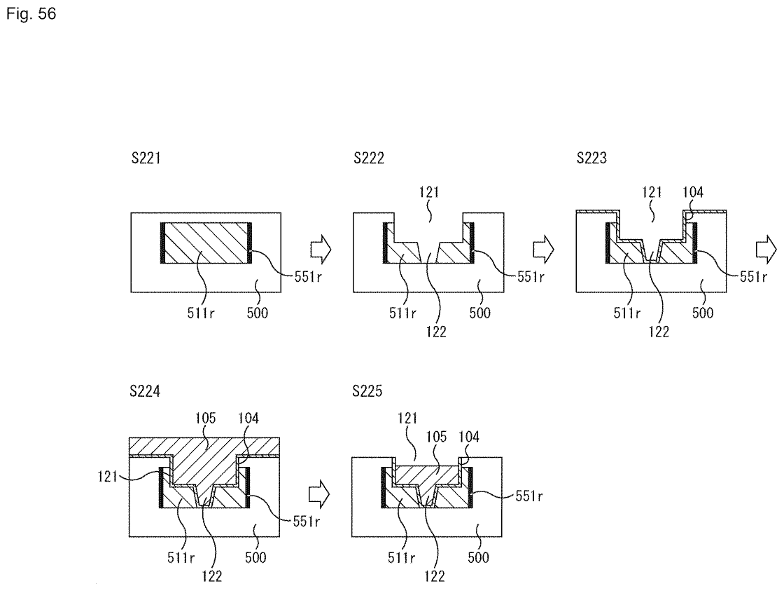

The manufacture of the pixel 12q having the configuration of the electrode 105 illustrated in FIG. 53 will be described with reference to FIG. 56. The manufacture of the part of the electrode 105 will be described with reference to FIG. 56.

In step S221, a substrate is prepared in which the insulating film 500 containing the expansion support film 511r and the oxide film 551r is formed. Steps S201 to S205 illustrated in FIG. 51 are executed before step S221, and the substrate is prepared after these steps are completed.

In step S222, the connection hole 121 and the interconnect hole 122 are formed by dry etching, for example. In step S222, etching is performed using the mask in which the part corresponding to the connection hole 121 is open, such that the expansion support film 511r remains on the side face of the connection hole 121.

In step S223, the barrier metal 104 is formed by sputtering, for example. The barrier metal 104 is formed on the side face and the bottom face of the connection hole 121, the side face and the bottom face of the interconnect hole 122, and the top face of the insulating film 500.

In step S224, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S225, the Cu is polished and flattened. In this step, the excess part of the Cu and the barrier metal 104 on the top face of the insulating film 500 are removed by CMP. When recessing occurs, the top face of the electrode 105 is at a position lower than the top face of the insulating film 500, as indicated in the depiction of step S210.

An electrode including the expansion support film 511r illustrated in FIG. 53 can be formed through the foregoing steps.

### Embodiment 17

Embodiment 17 will be described hereinafter. Embodiment 17 will describe a pixel 12 in which the electrode 105 is formed of copper (Cu) and a Cu (111) face is formed on a connection face side.

As described in the foregoing embodiments, if, when a substrate is affixed to another substrate, the electrodes 105 are bonded to each other using thermal expansion, the occurrence of contact defects and the like can be reduced by forming the electrode 105 in the Cu (111) orientation.

Cu (111) has a high surface diffusion rate and can be directly bonded at low temperatures. Forming the electrode 105 in the Cu (111) orientation makes it possible to provide a high surface diffusion rate, which facilitates expansion during bonding and suppresses the occurrence of defects during bonding.

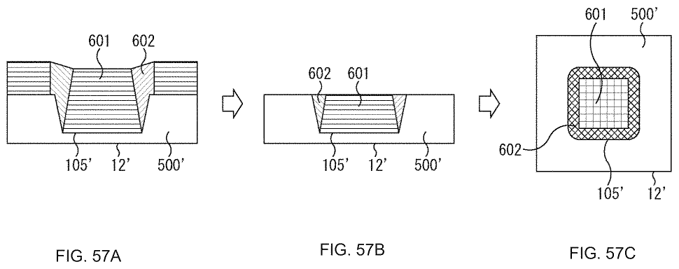

The orientation of the copper in the electrode 105 when the electrode 105 is formed of copper (Cu) will be described with reference to FIG. 57. A in FIG. 57 is a diagram illustrating an example of the cross-sectional configuration of a pre-CMP pixel 12′ (a dash is added to the pixel 12 to which the present technique is not applied), and illustrating the orientation of the copper. The electrode 105 is formed through an embedded wiring method using electric field-assisted Cu electroplating, as described in the foregoing embodiments.

When the electrode 105 is formed through an embedded wiring method using electric field-assisted Cu electroplating, the Cu is formed in a random orientation. Therefore, even if a Cu (111) face has been formed successfully, as illustrated in A in FIG. 57, even if (111)-oriented Cu is formed in a central region of the electrode 105′ (called a (111) region 601 hereinafter), randomly-oriented Cu is formed around the (111) region 601 (called a random region 602 hereinafter).

Upon being subjected to CMP, the pixel 12′ illustrated in A in FIG. 57 becomes as illustrated in B in FIG. 57, and when viewed in a plan view, is as illustrated in C in FIG. 56. The (111) region 601 is provided in the center of the electrode 105′ on the bonding face side of the pixel 12′, and the random region 602 is provided in the periphery thereof.

When the electrode 105′ is miniaturized, the (111) region 601 shrinks, and the proportion of the (111) region 601 occupying the bonding face decreases. In other words, the influence of the random region 602 on the bonding face may increase, and bonding using the high surface diffusion rate described above may become difficult. As illustrated in A in FIG. 57, it is difficult to control the orientation for plating on a shape where steps (inclinations) are present. In addition, (111)-oriented twin crystals (denoted as (111) nt-Cu hereinafter as appropriate) grow by forming planes perpendicular to the electroplating deposition surface, and thus in an embedded wiring formation method where steps are present in the side faces, aligning the (111) surfaces parallel to the bonding face is difficult.

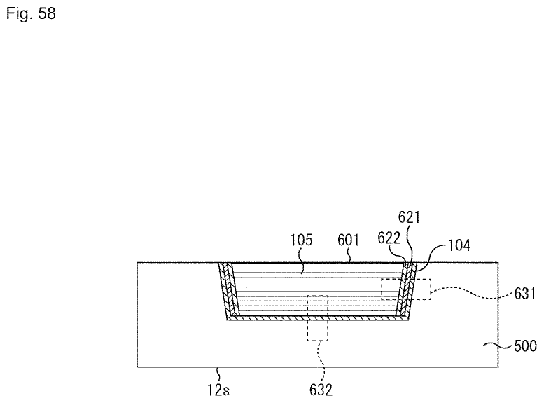

FIG. 58 is a diagram illustrating an example of the cross-sectional configuration of a pixel 12s according to Embodiment 17 in which the present technique is applied.

In the pixel 12s illustrated in FIG. 58, the electrode 105 is formed in the insulating film 500. The electrode 105 is formed of Cu, and the entire bonding face is the (111) region 601, in which the Cu (111) orientations are aligned.

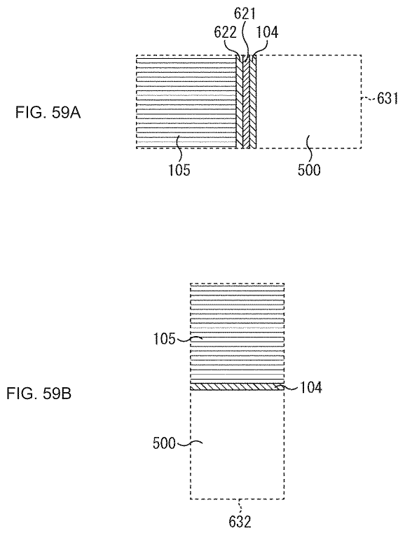

The side wall and bottom of the electrode 105 are configured as illustrated in FIG. 59. A in FIG. 59 is a diagram illustrating a region 631 of the side wall of the electrode 105 in FIG. 58 in an enlarged manner. In the side wall region 631, the barrier metal 104, a Cu seed 621, and a plating inhibition film 622 are formed between the insulating film 500 and the electrode 105.

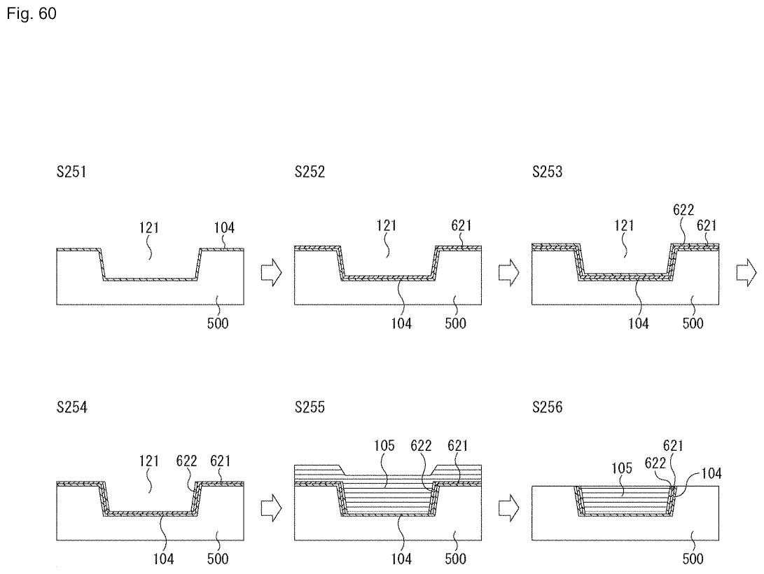

The Cu seed 621 is a film provided when forming the electrode 105, when Cu is formed by sputtering and Cu plating. The Cu seed 621 is a film that integrates with the formed electrode 105 (Cu) when the electrode 105 is formed, and is therefore not originally present in the formed electrode 105. When the pixel 12s (the electrode 105) is manufactured as will be described later with reference to FIG. 60, the Cu seed 621 remains formed on the side wall of the electrode 105.

The plating inhibition film 622 is formed between the Cu seed 621 and the electrode 105 in the side wall region 631 of the electrode 105. The plating inhibition film 622 is a film that inhibits the growth of Cu. Because the plating inhibition film 622 is formed on the side wall, the growth of Cu is inhibited, and the Cu seed 621 remains without being integrated with the electrode 105.

Because the plating inhibition film 622 is formed on the side wall and the growth of Cu is inhibited, the random regions 602 illustrated in A and B in FIG. 57 can be prevented from being formed. In other words, the (111) region 601 can be formed without inhibiting the growth of Cu from the bottom face.

B in FIG. 59 is a diagram illustrating a region 632 of the bottom face of the electrode 105 in FIG. 58 in an enlarged manner. In the bottom face region 632, the barrier metal 104 is formed between the insulating film 500 and the electrode 105. Because the plating inhibition film 622 is not formed on the bottom face, the Cu seed 621 formed on the bottom face is integrated with the electrode 105 and does not remain.

The electrode 105 of the pixel 12s illustrated in FIG. 58 is configured with the plating inhibition film 622 provided on the side wall, such that the (111)nt-Cu film does not grow from the side wall. On the other hand, the configuration is also such that the (111)nt-Cu film grows from the bottom face toward the bonding face side. Accordingly, the (111)nt-Cu film can be formed in a direction perpendicular to the substrate (silicon substrate) on which the insulating film 500 is formed.

The plating inhibition film 622 is formed using a material that has a function for inhibiting the growth of Cu. For example, an insulating film such as SiO₂, SiN, or the like, or a metal such as Ta (tantalum), can be used as the plating inhibition film 622. SiO2, Ta2O5, TiO2, SiN, SiCN, SiOF, or the like can be used as the plating inhibition film 622.

According to the electrode 105 illustrated in FIG. 58, when the semiconductor substrate is affixed to another semiconductor substrate and the electrodes 105 are connected to each other, the electrodes 105 can be connected to each other even at a low temperature, e.g., 300 degrees or lower. Connecting the electrodes 105 at a low temperature makes it possible, for example, to implement a stacked device, such as the imaging device 1 (FIGS. 1 and 2), which uses an organic material limited to a temperature of 400 degrees or lower.

Even when the electrodes 105 are miniaturized, a situation where the electrodes 105 do not contact each other and contact defects occur can be prevented, which makes it easier to improve the stability of the connection, ensure a certain yield, and the like.

### Manufacture According to Embodiment 17

The manufacture of the pixel 12s having the configuration of the electrode 105 illustrated in FIG. 58 will be described with reference to FIG. 60. The manufacture of the part of the electrode 105 will be described with reference to FIG. 60.

In step S251, a substrate is prepared in which the connection hole 121 is formed in the insulating film 500 and the barrier metal 104 is further formed. For example, a resist pattern is for forming the connection hole 121 is generated, and dry etching is performed using the resist pattern as a mask to form the connection hole 121. The barrier metal 104 is then formed by sputtering, for example. The barrier metal 104 is formed on the side face and the bottom face of the connection hole 121, and on the top face of the insulating film 500.

In step S252, the Cu seed 621 is formed. For example, a barrier layer constituted by Ti (titanium), Ta (tantalum), or nitrides thereof is formed. The barrier layer is formed in an Ar/N2 atmosphere using a method such as Radio Frequency (RF) sputtering, to a thickness of about 5 to 50 nm. The Cu seed 621 is then formed on the barrier layer using a method such as RF sputtering, for example, at a thickness of about 1 to 50 nm.

In step S253, the plating inhibition film 622 is formed. The plating inhibition film 622 is formed on the Cu seed 621, on the side face and the bottom face of the connection hole 121 and on the top face of the insulating film 500. For example, the plating inhibition film 622 is formed by forming an SiO2 or SiN film, or a natural oxide film such as Ti, Ta, or the like, using ALD or the like, and then making the surface thereof non-conductive.

In step S254, an etch-back process is performed on the entire surface using dry etching, which removes the plating inhibition film 622 formed on the surface of the insulating film 500 and the bottom face of the connection hole 121.

Performing step S254 ensures that the plating inhibition film 622 remains only in the region that is to serve as the side wall of the electrode 105, i.e., on the side face of the connection hole 121.

In step S255, the Cu to serve as the electrode 105 is formed in the connection hole 121. For example, (111)nt-Cu is formed by electroplating. The electroplating is performed using the following plating solution, for example:
Copper sulfate-based bath, Cu 60 g/L, H2SO4 60 g/L, HCL 50 ppm

Additives include an accelerator (a sulfur-based organic compound) and an inhibitor (a non-ionic surfactant), and the like

The plating current conditions of the electroplating are 10 mA/cm2 to 50 mA/cm2 of electrolytic direct current, and when plating is performed under these conditions, (111)nt-Cu can be formed on the Cu seed 621.

As indicated in the depiction of step S255, (111)nt-Cu grows from the bottom face of the connection hole 121 in which the Cu seed 621 was exposed, and is formed in the connection hole 121. In addition, because the Cu seed 621 is also exposed at the surface of the insulating film 500, (111)nt-Cu grows and is formed from the surface of the insulating film 500. However, because (111)nt-Cu does not grow from the side wall where the plating inhibition film 622 is located, the generation of the random region 602 where (111)nt-Cu having unaligned orientations is present on the bonding face side can be suppressed.

In step S256, the extra Cu is removed. For example, the Cu formed on the surface of the insulating film 500, and the barrier metal 104, are removed through CMP.

An electrode having the Cu (111) orientation surface illustrated in FIG. 58 can be formed through the foregoing steps.

### Other Example of Manufacture According to Embodiment 17

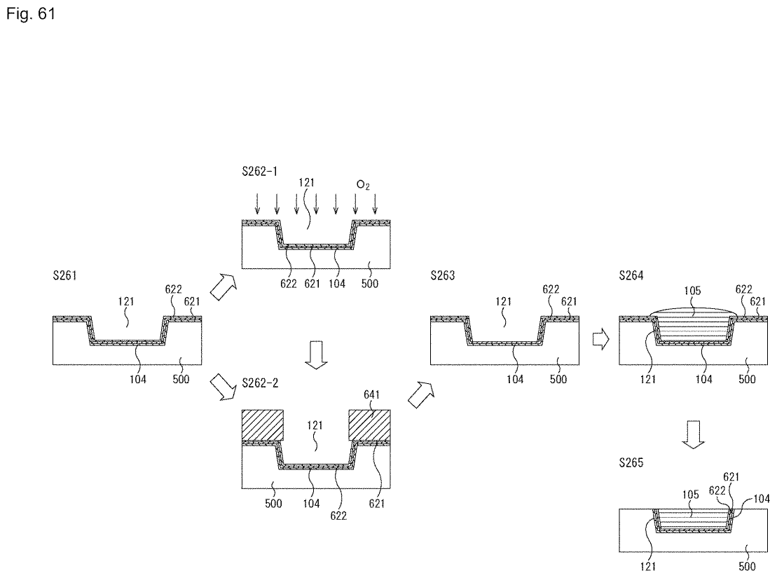

Another example of the manufacture of the pixel 12s having the configuration of the electrode 105 illustrated in FIG. 58 will be described with reference to FIG. 61.

In step S261, a substrate is prepared in which the connection hole 121 is formed in the insulating film 500, and furthermore, the barrier metal 104, the Cu seed 621, and the plating inhibition film 622 are formed. By executing steps S251 to S253 (FIG. 60) in the steps before step S261, the barrier metal 104, the Cu seed 621, and the plating inhibition film 622 are formed.

If the plating inhibition film 622 is formed of a metal such as Ti or Ta, after the processing in step S262-1 is performed, step S262-2 is performed. Step S262-2 is performed out to make the surface of the plating inhibition film 622 (in this case, the surface of the metal) non-conductive through an oxygen (O₂) plasma treatment or the like. Performing the processing for making the surface non-conductive improves the stability in later steps.

After step S262-1 is performed, the process moves to step S262-2. If the plating inhibition film 622 is formed of a material aside from metal, e.g., an insulating film, the process moves to step S262-2 after step S261 is performed.

In step S262-2, a resist pattern 641 in which the region to serve as the connection hole 121 is open is generated. In step S263, dry etching is performed using the resist pattern 641 as a mask to remove the plating inhibition film 622 formed on the bottom face of the connection hole 121.

Performing step S263 ensures that the plating inhibition film 622 remains in the region that is to serve as the side wall of the electrode 105, i.e., on the side face of the connection hole 121. The plating inhibition film 622 formed on the surface of the insulating film 500 still remains at the point in time when step S263 is performed.

In step S264, the Cu to serve as the electrode 105 is formed in the connection hole 121. The process in step S264 is the same as the process performed in step S255 (FIG. 60), e.g., a process in which (111)nt-Cu is formed by electroplating. In step S264, because the plating inhibition film 622 remains on the surface of the insulating film 500, (111)nt-Cu does not grow from the surface of the insulating film 500, and (111)nt-Cu is therefore not formed on the surface of the insulating film 500.

In step S264, the conditions used when (111)nt-Cu is formed by applying field-assisted electroplating can be used as described with reference to step S255 (FIG. 60). However, in this case, the plating inhibition film 622 is also formed on the insulating film 500, and it is therefore necessary to lower the plating current value according to the numerical aperture and adjust the value to an appropriate level.

As described with reference to step S264, (111)nt-Cu grows from the bottom face of the connection hole 121 in which the Cu seed 621 was exposed, and is formed in the connection hole 121, but, because the plating inhibition film 622 is formed on the surface of the insulating film 500, (111)nt-Cu does not grow from the surface of the insulating film 500. However, because (111)nt-Cu also does not grow from the side wall where the plating inhibition film 622 is located, the generation of the random region 602 where (111)nt-Cu having unaligned orientations is present on the bonding face side can be suppressed.

In step S265, the barrier metal 104 formed on the surface of the insulating film 500 is removed through CMP, for example. At this time, if Cu remains on the surface of the insulating film 500, the Cu is also removed.

An electrode having the Cu (111) orientation surface illustrated in FIG. 58 can be formed through the foregoing steps.

### Embodiment 18

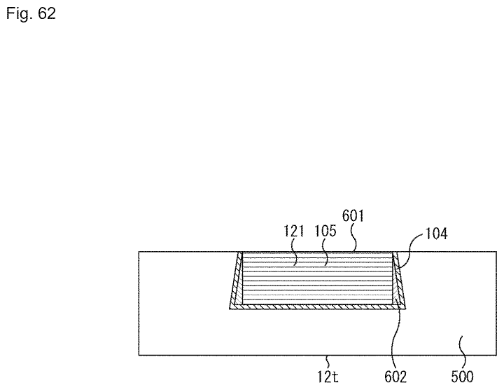

FIG. 62 is a diagram illustrating an example of the cross-sectional configuration of a pixel 12t according to Embodiment 18 in which the present technique is applied. Parts that are the same between the pixel 12t according to Embodiment 18, illustrated in FIG. 62, and the pixel 12s according to Embodiment 17, illustrated in FIG. 58, will be given the same reference signs, and descriptions thereof will be omitted as appropriate.

Compared to the pixel 12s illustrated in FIG. 58, the pixel 12t illustrated in FIG. 61 differs in that the shape of the side wall of the connection hole 121 is different, and in that the plating inhibition film 622 is not formed. The other points are the same.

In the pixel 12t illustrated in FIG. 62, the connection hole 121 is formed in the insulating film 500, and the electrode 105 is formed in the connection hole 121. The connection hole 121 is formed in a reverse-tapered shape. The connection hole 121 is formed such that a width thereof on the connection face side (the face on the upper side in the figure) is smaller than the width of the connection hole 121 on the bottom face side thereof (the lower side in the figure). The barrier metal 104 is formed on the side wall and the bottom face of the connection hole 121.

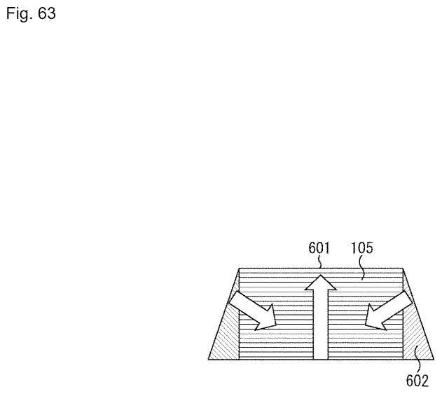

FIG. 63 is a diagram illustrating an orientation direction of the Cu formed in the connection hole 121. The (111)nt-Cu formed from the side wall grows in a downward-diagonal direction because the side wall of the connection hole 121 is formed at a downward-diagonal tilt in the figure. On the other hand, the (111)nt-Cu that grows from the bottom face of the connection hole 121 grows in the upward direction, i.e., toward the connection face side.

Because the (111)nt-Cu grown from the side wall grows in the downward direction and the (111)nt-Cu grown from the bottom face grows in the upward direction, the effect of the (111)nt-Cu grown from the side wall on the (111)nt-Cu growth from the bottom face can be reduced. By having the (111)nt-Cu grow in this manner, the electrode 105 in the connection hole 121 can be configured such that the (111) region 601 occupies the majority of the connection face side, even if the random region 602 is formed near the side wall of the connection hole 121, as illustrated in FIG. 62.

According to the electrode 105 illustrated in FIG. 62, when the semiconductor substrate is affixed to another semiconductor substrate and the electrodes 105 are connected to each other, the electrodes 105 can be connected to each other even at a low temperature, e.g., 300 degrees or lower. Connecting the electrodes 105 at a low temperature makes it possible, for example, to implement a stacked device which uses an organic material limited to a temperature of 400 degrees or lower.

Even when the electrodes 105 are miniaturized, a situation where the electrodes 105 do not contact each other and contact defects occur can be prevented, which makes it easier to improve the stability of the connection, ensure a certain yield, and the like.

The Cu on the side wall of the pad having poor seed coverage (the connection hole 121) can be protected, and defects arising during plating can be reduced. Aligning the crystal orientations in the electrode 105 reduces the crystalline interface, and makes it possible to increase electromigration resistance.

### Manufacture According to Embodiment 18

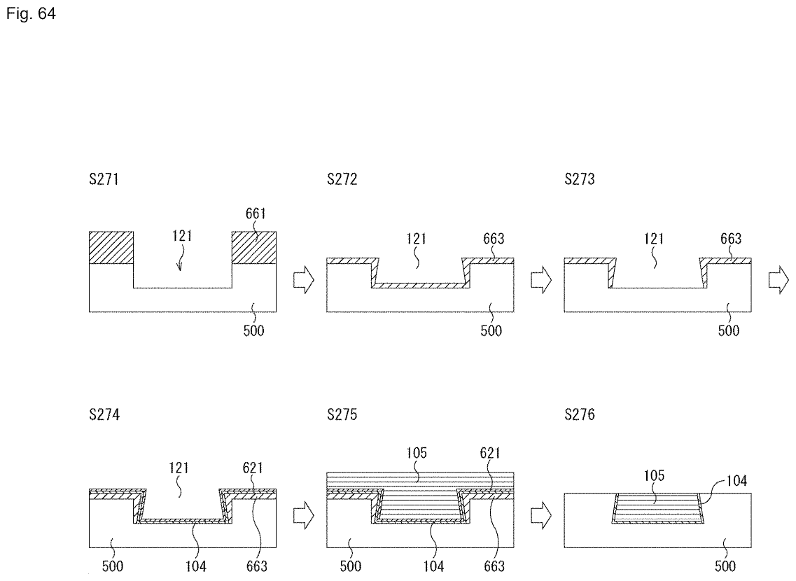

The manufacture of the pixel 12t having the configuration of the electrode 105 illustrated in FIG. 62 will be described with reference to FIG. 64. The manufacture of the part of the electrode 105 will be described with reference to FIG. 64.

In step S271, a substrate is prepared in which the insulating film 500 is formed, and etching is performed to form the connection hole 121. For example, a resist pattern 661 is generated in which the region to serve as the connection hole 121 is open, and dry etching is performed using the resist pattern 661 as a mask to form the connection hole 121.

In step S271, a plasma film 663 formed of SiO2 or SiN is formed by plasma chemical vapor deposition (CVD). The plasma film 663 is formed on the side wall and the bottom face of the connection hole 121, and on the surface of the insulating film 500. The plasma film 663 formed on the side wall of the connection hole 121 has a reverse-tapered shape, as indicated in the depiction of step S271.

The plasma film 663 and the insulating film 500 can be configured integrally by forming the plasma film 663 from the same material as the insulating film 500. However, even if the plasma film 663 is formed from a material different from the insulating film 500, the plasma film 663 can be used to form the reverse-tapered shape side wall of the insulating film 500.

In step S273, etching is performed to remove the plasma film 663 formed on the bottom face of the connection hole 121. The plasma film 663 formed on the surface of the insulating film 500 is processed to be made thinner or removed.

The plasma film 663 formed on the bottom face of the connection hole 121 may be left, and the etch-back process in step S273 can be omitted.

In step S274, the barrier metal 104 and the Cu seed 621 are formed. The barrier metal 104 is formed by sputtering, for example, and is formed on the side face (on the plasma film 663) and the bottom face of the connection hole 121, and on the top face of the insulating film 500 (on the top face of the plasma film 663).

The Cu seed 621 can be formed by the same process as that described with reference to step S252 (FIG. 60). The Cu seed 621 is formed on the barrier metal 104, which in this case is the side face and the bottom face of the connection hole 121, and the top face of the insulating film 500.

In step S275, the Cu to serve as the electrode 105 is formed in the connection hole 121. The process in step S275 is the same as the process in step S255 (FIG. 60), e.g., the (111)nt-Cu is formed by electroplating. In step S275, (111)nt-Cu is also formed on the surface of the insulating film 500.

In step S276, the (111)nt-Cu and the barrier metal 104 formed on the surface of the insulating film 500 are removed through CMP, for example.

An electrode having the Cu (111) orientation surface illustrated in FIG. 62 can be formed through the foregoing steps.

### Other Example of Manufacture According to Embodiment 18

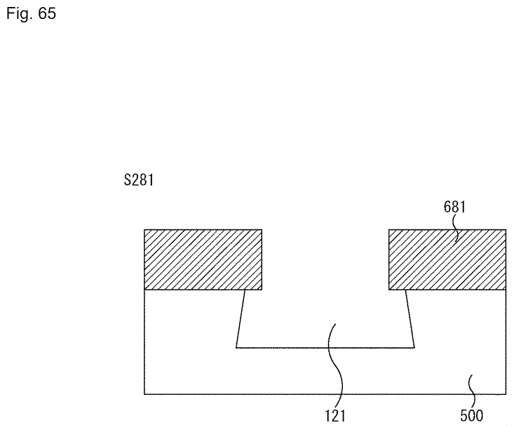

Another example of a manufacturing processes to form the side wall of the connection hole 121 in a reverse-tapered shape will be described with reference to FIG. 65.

In step S281, a substrate is prepared in which the insulating film 500 is formed, and etching is performed to form the connection hole 121, and to form the side wall of the connection hole 121 in a reverse-tapered shape. For example, a resist pattern 681 is generated in which a region smaller than the region to serve as the connection hole 121 is open, and etching is performed using the resist pattern 681 as a mask.

This etching process is performed by incorporating isotropic etching conditions. Isotropic etching can also form the side wall of the connection hole 121 in a reverse-tapered shape because the film directly under the resist can be removed.

In the process in step S281, the connection hole 121 is formed having a reverse-tapered side wall. After the processing of step S281 is completed, steps S272 to S276 (the same steps as in FIG. 64 are executed. The electrode 105 of the pixel 12t illustrated in FIG. 62 is formed by performing processes such as forming and removing the barrier metal 104 and the Cu seed 621, forming and removing the (111)nt-Cu film, and the like.

### Other Example of Manufacture According to Embodiment 18

The plasma film 663 is formed as a film having the same function as the plating inhibition film 622, i.e., the plasma film 663 may be formed using the same material as that of the plating inhibition film 622 for the material of the plasma film 663. In this case, the plasma film 663 having a reverse-tapered shape is formed on the side wall of the connection hole 121. Providing the plasma film 663 (the plating inhibition film 622) having such a reverse-tapered shape makes it easier to grow the (111)nt-Cu in the desired direction, which in this case is toward the connection face side.

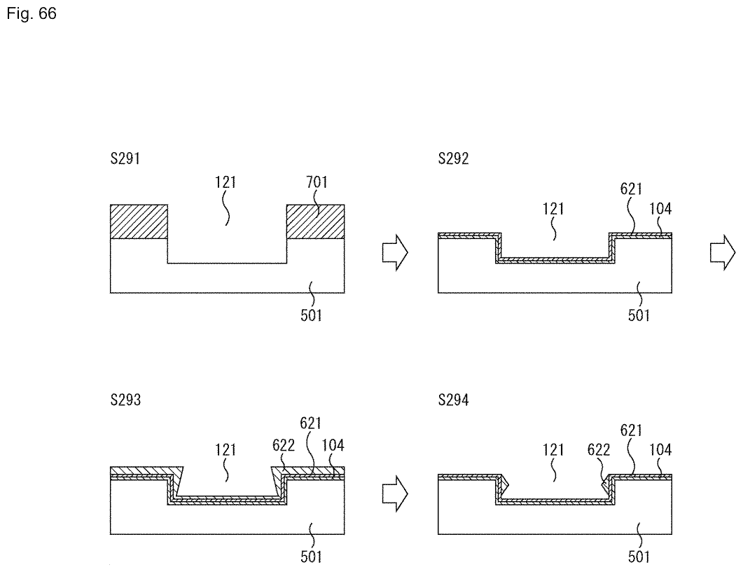

The manufacture of the pixel 12t having the plating inhibition film 622 with a reverse-tapered shape will be described with reference to FIG. 66.

In step S291, a substrate is prepared in which the insulating film 500 is formed, and etching is performed to form the connection hole 121. For example, a resist pattern 701 is generated in which the region to serve as the connection hole 121 is open, and dry etching is performed using the resist pattern 701 as a mask to form the connection hole 121.

In step S292, the barrier metal 104 and the Cu seed 621 are formed. The film of the barrier metal 104 and the Cu seed 621 can be formed by sputtering, for example. The Cu seed 621 can be formed by the same process as that described with reference to step S252 (FIG. 60).

In step S293, plasma SiO2 (P—SiO) having a thickness of, for example, about 100 nm to 200 nm is formed. The plasma SiO2 functions as the plating inhibition film 622, and is formed of a material that can be used as the plating inhibition film 622. Although SiO2 is given as an example here, other materials may be used.

In step S294, the plating inhibition film 622 formed on the surface of the insulating film 500 and the bottom face of the connection hole 121 is removed through an etch-back process.

When the plating inhibition film 622 is formed on the side wall of the connection hole 121 by such a process, and when the plating inhibition film 622 is formed on the side wall by such a process, the plating inhibition film 622 having a tapered shape can be obtained, as indicated in the depiction of step S294 in FIG. 66. The shape of the plating inhibition film 622 can be adjusted by adjusting the conditions used when forming the plasma SiO2 in step S293, the conditions used in the etch-back process in step S294, and the like.

After step S294, Cu having a (111) surface can be formed as the electrode 105 by executing the processes of steps S255 and S256 (FIG. 60).

### Embodiment 19

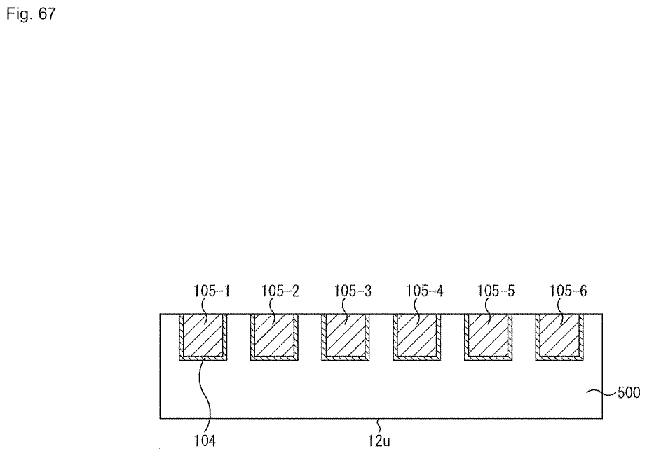

FIG. 67 is a diagram illustrating an example of the cross-sectional configuration of a pixel 12u according to Embodiment 19 in which the present technique is applied.

Although the foregoing embodiments described the electrode 105 as an example, as illustrated in FIG. 67, there are also regions in which a plurality of electrodes 105 are disposed. FIG. 67 illustrates an example in which electrodes 105-1 to 105-6 are arranged side by side in the insulating film 500. The electrodes 105-1 to 105-6 are formed of copper (Cu), and are configured such that the (111) surface is located in the bonded part.

For example, Embodiment 17 or 18 described above can be applied to each electrode 105 such that each electrode 105 is formed by a process in which (111)nt-Cu film is controlled to grow. However, each electrode 105 can also be formed through the processes described below.

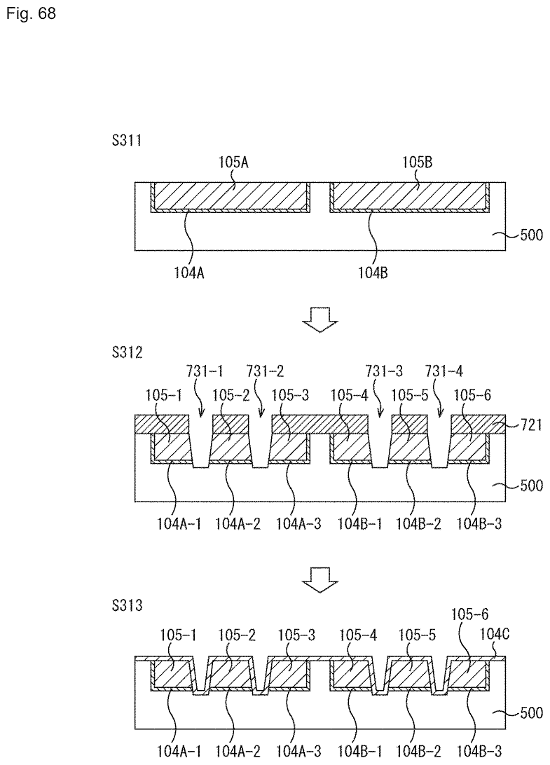

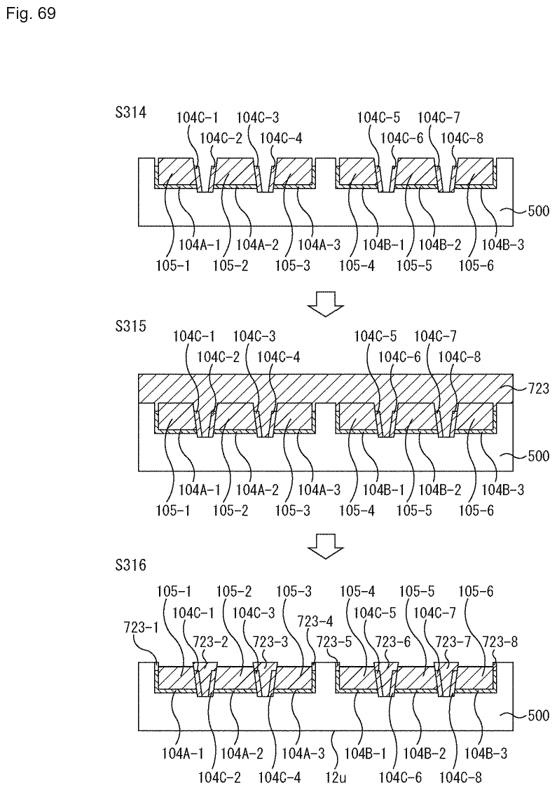

The manufacture of the pixel 12u having the electrode 105 in which the Cu (111) surface is arranged on the bonding face side, as illustrated in FIG. 67, will be described with reference to FIGS. 68 and 69.

In step S311, an electrode 105A and an electrode 105B are formed in the insulating film 500. The electrode 105A is a single large electrode formed in the region in which the electrode 105-1, the electrode 105-2, and the electrode 105-3 are formed. Likewise, the electrode 105B is a single large electrode formed in the region in which the electrode 105-4, the electrode 105-5, and the electrode 105-6 are formed. In this example, an electrode A (B) is formed at a size larger than the combined size of three electrodes 105.

The electrode 105A and the electrode 105B are formed of Cu having a uniform plane orientation (111). For example, if the electrode 105 is formed at a size of 10 μm φ or greater, the electrode 105 can be formed of Cu having a uniform plane orientation (111). The electrode 105A and the electrode 105B are, for example, electrodes 105 formed at a size of 10 μm φ or greater, and are electrodes 105 formed by growing Cu having a uniform plane orientation (111). Since similar steps (processing) are performed for the electrode 105A and the electrode 105B, the descriptions will continue using the electrode 105A as an example.

In step S311, a substrate is prepared in which the insulating film 500 is formed, and a groove of about the same size as the electrode 105A is formed by etching at the position where the electrode 105A is to be formed. For example, in a photolithography step, a photoresist is applied to generate a resist pattern for forming the groove, and dry etching is performed using the resist pattern as a mask to form the groove.

A barrier metal 104A is formed by sputtering, for example, in the groove formed in the position where the electrode 105A is to be formed. The barrier metal 104A formed in regions other than the side face and the bottom face of the groove is removed by processing such as an etch-back process. Cu having a surface orientation (111) is then formed through growth in the groove where the barrier metal 104A is formed, using a Cu plating process.

In step S312, the electrode 105A is divided. The electrode 105A is divided into the electrode 105-1, the electrode 105-2, and the electrode 105-3. For example, the electrode 105A is divided (reduced) to desired sizes by a lithography process, a dry etching process, or the like. A resist pattern 721 is generated in which the positions corresponding to the divisions are open, and etching is performed using the resist pattern 721 as a mask to form grooves in the division positions.

A groove 731-1 and a groove 731-2 are formed in the electrode 105A, and a groove 731-3 and a groove 731-4 are formed in the electrode 105B. The electrode 105A is divided into the electrode 105-1, the electrode 105-2, and the electrode 105-3 by forming the groove 731-1 and the groove 731-2. The electrode 105B is divided into the electrode 105-4, the electrode 105-5, and the electrode 105-6 by forming the groove 731-3 and the groove 731-4.

The shape of the grooves 731 can be made a desired shape by adjusting the shape of the resist pattern 721, the etching conditions, and the like. In the example illustrated in FIG. 68, the grooves 731 are formed in a shape having a taper. The grooves 731 are formed in a tapered shape in which the side faces are not vertical, but rather have an inclination.

The grooves 731 are formed at a depth that divides the barrier metal 104. When the barrier metal 104 is processed, the insulating film 500 is also processed, and recessed parts may form in the insulating film 500 as a result.

Forming the grooves 731 divides the barrier metal 104A into a barrier metal 104A-1, a barrier metal 104A-2, and a barrier metal 104A-3. Forming the grooves 731 divides the barrier metal 104B into a barrier metal 104B-1, a barrier metal 104B-2, and a barrier metal 104B-3. After processing such as removing the resist pattern 721 is performed, the process moves to step S313.

In step S313, a barrier metal 104C is formed. Forming the grooves 731 in step S312 divides the electrode 105A, and the Cu is exposed on the side walls at the divided parts. Referring to the figure depicting step S312, for example, the electrode 105-1 is in a state in which the barrier metal 104A is absent from the side wall on the right side in the figure due to the groove 731-1 being formed. The electrode 105-2 is in a state in which the barrier metal 104A is absent from the side walls on both the left side and the right side in the figure.

A process for forming the barrier metal 104 on the side wall of the electrode 105 where the barrier metal 104 is absent is performed in step S313. In step S313, the barrier metal 104C is formed on the surface of the electrode 105, and on the side walls and the bottom faces of the grooves 731.

In step S314 (FIG. 69), the barrier metal 104C formed on the surface of the electrode 105 and the bottom faces of the grooves 731 is removed through a process such as dry etching. Referring to step S314 in FIG. 69, by removing the extra barrier metal 104C, the electrode 105-1 is in a state in which the barrier metal 104A-1 is formed the side wall on the left side in the figure and the bottom face, and a barrier metal 104C-1 is formed on the side wall on the right side in the figure.

The electrode 105-2 is in a state in which the barrier metal 104A-2 is formed on the bottom face, a barrier metal 104C-2 is formed on the side wall on the left side in the figure, and a barrier metal 104C-3 is formed on the side wall on the right side in the figure. The electrode 105-3 is in a state in which the barrier metal 104A-3 is formed on the bottom face and the side face on the right side, and a barrier metal 104C-4 is formed on the side wall on the left side in the figure.

The electrode 105-4 is in a state in which the barrier metal 104B-1 is formed on the bottom face and the side face on the left side, and a barrier metal 104C-5 is formed on the side wall on the right side in the figure. The electrode 105-5 is in a state in which the barrier metal 104B-2 is formed on the bottom face, a barrier metal 104C-6 is formed on the side wall on the left side in the figure, and a barrier metal 104C-7 is formed on the side wall on the right side in the figure.

The electrode 105-6 is in a state in which the barrier metal 104B-3 is formed on the bottom face and the side face on the right side, and a barrier metal 104C-8 is formed on the side wall on the left side in the figure.

The barrier metal 104C remaining on the side wall of the electrode 105 is formed as far as a recessed part in the insulating film 500. For example, the barrier metal 104C-1 formed on the left side of the electrode 105-1 is formed to a position of the recessed part in the insulating film 500. The barrier metal 104A-1 is formed on the bottom face of the electrode 105-1, but the barrier metal 104C-1 is formed up to a position deeper than the barrier metal 104A-1. The other barrier metal 104C is also formed up to the position of the recessed part in the insulating film 500.

When the barrier metal 104C is removed, the parts of the barrier metals 104A and 104C formed at both ends of the uppermost surface of the electrode 105 are also removed, and the corresponding parts take on the shape of the recessed part. For example, the upper side (the uppermost surface side of the electrode 105-1) of the barrier metal 104C-1 formed on the left side of the electrode 105-1 is formed up to a position lower than the uppermost surface of the electrode 105-1 (a deeper position). This part becomes a recessed part with respect to the position of the uppermost surface of the electrode 105-1.

The other barrier metals 104A and 104C are also formed to a position lower than the uppermost surface side of the electrode 105, and are formed to a position to become a recessed parts with respect to the position of the uppermost surface of the electrode 105.

In step S315, an insulating film 723 is formed. The insulating film 723 is formed to fill the grooves 731 between the electrodes 105. The insulating film 723 is formed of the same material as the insulating film 500, and may be integrated with the insulating film 500 after being formed. Alternatively, the insulating film 723 may be formed of a material different from that of the insulating film 500. For example, a material having better film-formation properties than the insulating film 500 can be used as the insulating film 723.

In step S316, CMP is performed on the insulating film 723, exposing the surface of the electrode 105 and flattening the bonding face. Because the uppermost surface of the electrode 105 and the barrier metal 104 are not at the same height, it is sufficient to take only the selection ratio between the insulating film 723 and Cu into account when performing the CMP on the insulating film 723. The polishing of the barrier metal 104 need not be considered, and thus the amount of recessing in the Cu produced by the CMP is reduced. Reducing the amount of recessing makes it possible to reduce situations where contact defects occur in the bonding between the electrodes 105 when affixing the substrate to another substrate.

Because the uppermost surface of the electrode 105 and the barrier metal 104 are not at the same height, or in other words, because there is a recessed part in the barrier metal 104 as described above, the insulating film 723 remains in the recessed part. An insulating film 723-1 is formed in the recessed part of the barrier metal 104A-1 of the electrode 105-1. An insulating film 723-2 is formed between the electrode 105-2 and the electrode 105-3. Part of the insulating film 723-2 is formed in the recessed part in the barrier metal 104C-1 formed in the side wall of the electrode 105-1, and the other part is formed in the recessed part in the barrier metal 104C-2 formed on the side wall of the electrode 105-2.

An insulating film 723-3 is formed between the electrode 105-2 and the electrode 105-3. Part of the insulating film 723-3 is formed in the recessed part in the barrier metal 104C-3 formed in the side wall of the electrode 105-2, and the other part is formed in the recessed part in the barrier metal 104C-4 formed in the side wall of the electrode 105-3. An insulating film 723-4 is formed in the recessed part in the barrier metal 104A-3 of the electrode 105-3.

An insulating film 723-5 is formed in the recessed part of the barrier metal 104B-1 of the electrode 105-4. An insulating film 723-6 is formed between the electrode 105-4 and the electrode 105-5. Part of the insulating film 723-6 is formed in the recessed part in the barrier metal 104C-5 formed in the side wall of the electrode 105-4, and the other part is formed in the recessed part in the barrier metal 104C-6 formed in the side wall of the electrode 105-5.

An insulating film 723-7 is formed between the electrode 105-5 and the electrode 105-6. Part of the insulating film 723-7 is formed in the recessed part in the barrier metal 104C-7 formed in the side wall of the electrode 105-5, and the other part is formed in the recessed part in the barrier metal 104C-8 formed in the side wall of the electrode 105-6. An insulating film 723-8 is formed in the recessed part of the barrier metal 104B-3 of the electrode 105-6.

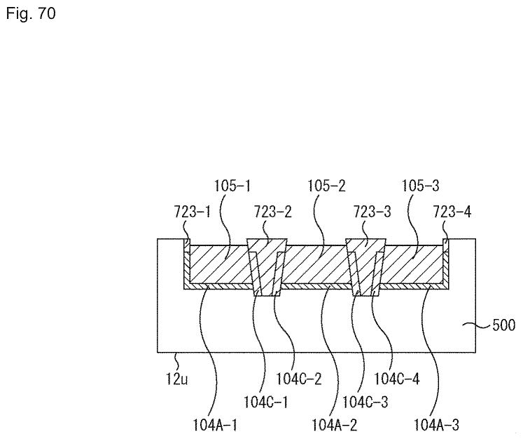

The electrode 105 at the bonded part of the pixel 12u has a configuration such as that indicated in the depiction of step S316. The electrodes 105-1 to 105-3 formed by dividing the electrode 105A are illustrated in FIG. 70, and the configuration of the electrode 105 at the bonded part of the pixel 12u will be described in further detail.

If the electrode 105 at the bonded part of the pixel 12u is formed through the process described with reference to FIGS. 68 and 69, the orientation of the barrier metal 104 formed on the side wall of one electrode 105 will be different.

The electrode 105-1 includes the vertical barrier metal 104A-1 on the left side in the figure, and the barrier metal 104C-1 having an inclination from the upper-left to the lower-right direction on the right side in the figure. The electrode 105-2 includes the barrier metal 104C-2 having an inclination from the upper-right to the lower-left on the left side in the figure, and the barrier metal 104C-4 having an inclination from the upper-left to the lower-right on the right side in the figure.

The electrode 105-3 includes the vertical barrier metal 104A-3 on the right side in the figure, and the barrier metal 104C-4 having an inclination from the upper-right to the lower-left on the left side in the figure. In this manner, when focusing on one electrode 105, the barrier metal 104 provided on the side wall of the electrode 105 is formed at different inclinations and in different directions.

The thickness of the barrier metal 104A and the thickness of the barrier metal 104C may be the same, or may be different. When the thicknesses are different, for example, the configuration is such that the barrier metal 104A-1 and the barrier metal 104C-1 having different thicknesses are formed in the side wall of the electrode 105-1.

When focusing on one electrode 105, the length of the bonding face side and the length of the bottom face side are different in the electrode 105. For example, the length of the bonding face side is shorter than the length of the bottom face side in the electrode 105-1. Likewise, the length of the bonding face side is shorter than the length of the bottom face side in the electrode 105-2. In this manner, the length of the bonding face side is shorter than the length of the bottom face side in the electrode 105.

The insulating film 723 is formed at the ends of the barrier metal 104 on the bonding face side thereof. For example, the insulating film 723-1 is formed at the end on the bonding face side of the barrier metal 104A-1 provided on the side wall of the electrode 105-1, and the insulating film 723-2 is formed at the end on the bonding face side of the barrier metal 104C-1.

The ends of the barrier metal 104 on the bonding face side and the opposite side are located deeper than the barrier metal 104 on the bottom side of the electrode 105. For example, the end of the barrier metal 104C-1 provided on the side wall of the electrode 105-1 is located deeper than the barrier metal 104A-1 on the bottom side of the electrode 105-1. The ends of the barrier metal 104C-2 and the ends of the barrier metal 104C-3 provided on the side walls of the electrode 105-2 are both deeper than the barrier metal 104A-2 on the bottom side of the electrode 105-2.

In other words, the barrier metal 104 on one or both side walls of the electrode 105 is formed up to a position deeper than the barrier metal 104 on the bottom side of the electrode 105.

If the insulating film 500 and the insulating film 723 are formed of different materials at the time of manufacture, the insulating film 723 formed between the electrodes 105 and the insulating film 500 formed around the electrode 105 will have different film properties. Different film properties means that the materials themselves are different, the types of the films (film types) are different, and the like.

The electrode 105 will have such configuration characteristics when an electrode pattern is formed by forming the large electrode 105 and then dividing (refining) the large electrode 105.

The electrode 105 can be constituted by Cu having a plane orientation (111) by forming the large electrode 105 and dividing (refining) the large electrode 105. Because Cu having a plane orientation (111) has a high thermal expansion coefficient even at a low temperatures, when the semiconductor substrate is affixed to another semiconductor substrate and the electrodes 105 are connected to each other, the electrodes 105 can be connected to each other even at a low temperature, e.g., 300 degrees or lower. Connecting the electrodes 105 at a low temperature makes it possible, for example, to implement a stacked device which uses an organic material limited to a temperature of 400 degrees or lower.

Even when the electrodes 105 are miniaturized, a situation where the electrodes 105 do not contact each other and contact defects occur can be prevented, which can improve the stability of the connection, ensure a certain yield, and the like.

Embodiments 1 to 19 described above can of course be carried out alone, and can also be carried out in combination with each other.

The foregoing Embodiments 1 to 19 described examples in which a plurality of semiconductor substrates are applied in an imaging device 1 having a stacked structure in which a plurality of semiconductor substrates are stacked.

However, the present technique can be broadly applied in semiconductor substrates that include an electrode having the configuration of the electrode 105 described above.

### Embodiment 20-1

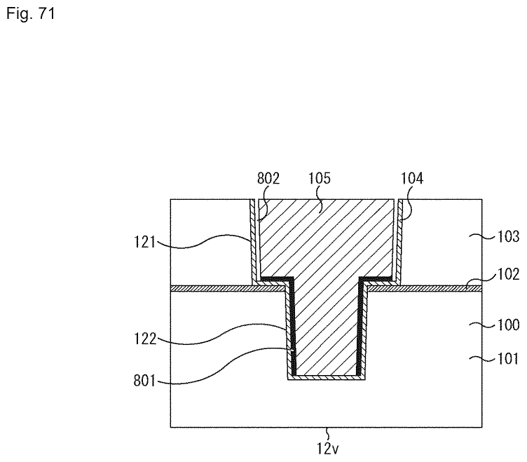

FIG. 71 is a diagram illustrating an example of the configuration of a pixel 12v according to Embodiment 20-1 in which the present technique is applied. Parts that are the same between the pixel 12v according to Embodiment 20-1, illustrated in FIG. 71, and the pixel 12a according to Embodiment 1, illustrated in FIG. 4, will be given the same reference signs, and descriptions thereof will be omitted as appropriate.

FIG. 71 illustrates a single electrode constituting the pixel 12v, and illustrates an electrode (electrode pad) which is provided on a bonding face side where the first semiconductor substrate 30 and the second semiconductor substrate 40 are bonded, and which is bonded using the pumping phenomenon described above to make the first semiconductor substrate 30 and the second semiconductor substrate 40 conductive.

As illustrated in FIG. 71, the electrode formed at the bonded part is configured by forming an electrode 105 in a stacked film 100 in which an interlayer insulating film 101, a liner insulating film 102, and an interlayer insulating film 103 are stacked.

The electrode 105 illustrated in FIG. 71 has a shape based on the dual damascene process, and is configured to have a connection hole 121 and an interconnect hole 122. As will be described later, the present technique can be applied to an electrode having a shape based on a single damascene process, and can also be applied in a configuration having only a connection hole.

The barrier metal 104 and a liner film 801 or an air layer 802 are formed between the stacked film 100 and the electrode 105. More specifically, the barrier metal 104 and the liner film 801 are formed between the stacked film 100 and the electrode 105 on a side face of the interconnect hole 122. The barrier metal 104 and the air layer 802 are formed between the stacked film 100 and the electrode 105 on a side face of the connection hole 121.

The air layer 802 is a film provided such that the material constituting the electrode 105 does not inhibit thermal expansion during heat treatment.

For example, as illustrated in FIG. 3, if only the barrier metal 104 is formed between the stacked film 100 and the electrode 105, the barrier metal 104 may inhibit the expansion of the electrode 105, and the amount of expansion of the electrode 105 may be reduced as a result. If the adhesion between the barrier metal 104 and the electrode 105 is high, the force of the expansion of the electrode 105 in the upward direction in FIG. 71 may be suppressed and weakened by the barrier metal 104, and the expansion may be insufficient.

The air layer 802 is provided between the barrier metal 104 and the electrode 105, and the structure is therefore such that the barrier metal 104 does not inhibit the expansion of the electrode 105. Providing the air layer 802 reduces (eliminates) the adhesion strength between the barrier metal 104 and the electrode 105, which suppresses the occurrence of situations where the liner film 801 suppresses and weakens the force of the expansion of the electrode 105 in the upward direction in FIG. 71. This ensures that sufficient expansion can be achieved.

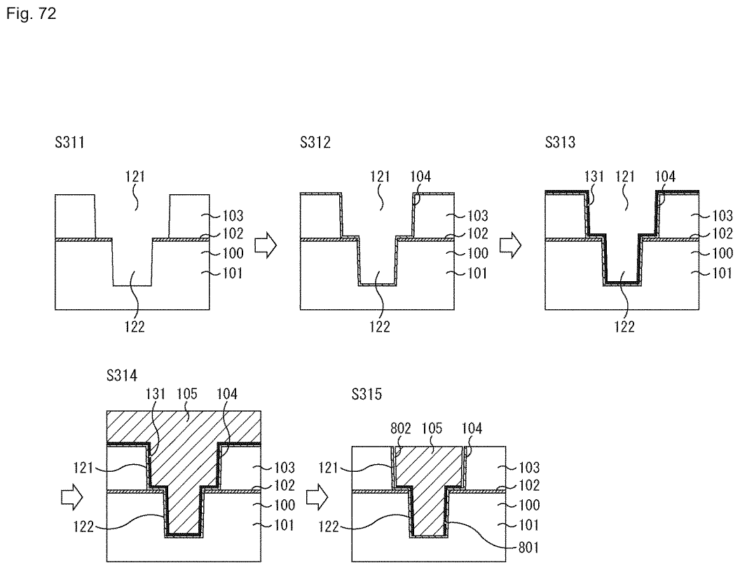

The air layer 802 is formed using the galvanic effect, as will be described later with reference to FIG. 72. Although the liner film 801 is formed in a region where the air layer 802 is present during manufacture, the liner film 801 is corroded by the galvanic effect and becomes the air layer 802. To make use of the galvanic effect, a material having an intermediate electronegativity, i.e., between the electronegativity of the material of the electrode 105 and the electronegativity of the material of the barrier metal 104, is used for the liner film 801.

For example, Cu (copper) is used as the material of the electrode 105. For example, Ta (tantalum), TaN (tantalum nitride), Ti (titanium), TiN (titanium nitride), or the like is used as the material of the barrier metal 104. When such a material is used, a material having an electronegativity between the electronegativity of Cu and the electronegativity of the material of the barrier metal 104 is used as the liner film 801.

For example, Al (aluminum), V (vanadium), Mn (manganese), Co (cobalt), Ni (nickel), Mo (molybdenum), Ru (ruthenium), or the like can be used as the liner film 801.

### Manufacture According to Embodiment 20-1

The manufacture of the pixel 12v having the configuration of the electrode 105 illustrated in FIG. 71 will be described with reference to FIG. 72. The manufacture of the part of the electrode 105 will be described with reference to FIG. 72.

In step S311, a substrate is prepared in which the stacked film 100 is formed, with the interlayer insulating film 101, the liner insulating film 102, and the interlayer insulating film 103 stacked therein. The connection hole 121 and the interconnect hole 122 are formed by etching the stacked film 100.

For example, in a photolithography step, a photoresist is applied to generate a resist pattern for forming the interconnect hole 122 (patterning). An etching step is performed, and dry etching is performed using the resist pattern generated in the photolithography step as a mask, which forms the interconnect hole 122. The connection hole 121 can be formed by repeating the same processing.

In step S312, the barrier metal 104 is formed by sputtering, for example. The barrier metal 104 is formed on the side faces and the bottom faces of the connection hole 121 and the interconnect hole 122, and is also formed on a top face of the interlayer insulating film 103.

In step S313, the liner film 801 is formed on the barrier metal 104. The liner film 801 can also be formed by sputtering.

In step S314, the material of the electrode 105, e.g., copper (Cu), is embedded in the connection hole 121 and the interconnect hole 122. The electrode 105, constituted by copper (Cu), is embedded in the connection hole 121 and the interconnect hole 122 by Cu sputtering followed by Cu plating.

In step S315, the Cu is polished and flattened. This step removes excess Cu, as well as the barrier metal 104 and the liner film 801 on the top face of the interlayer insulating film 103, through Chemical Mechanical Planarization (CMP). When the polishing of Cu is performed in step S315, the air layer 802 is formed through self-alignment.

An electrode including the air layer 802 illustrated in FIG. 71 can be formed through the foregoing steps. The air layer 802 can be formed through self-alignment, and can therefore be formed through a cost-effective process.

### Embodiment 20-2

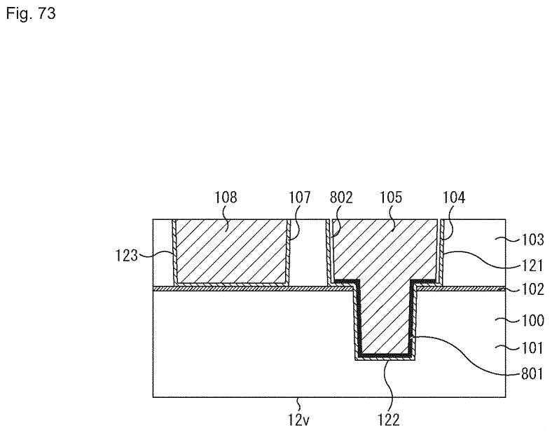

FIG. 73 is a diagram illustrating an example of the configuration of a pixel 12v according to Embodiment 20-2 in which the present technique is applied. Parts that are the same between the pixel 12v according to Embodiment 20-2, illustrated in FIG. 73, and the pixel 12v according to Embodiment 20-1, illustrated in FIG. 71, will be given the same reference signs, and descriptions thereof will be omitted as appropriate.

The pixel 12v according to Embodiment 20-2, illustrated in FIG. 73, differs from the pixel 12v according to Embodiment 20-1, illustrated in FIG. 71, in that the dummy electrode 108 is added. The other points are the same.

The pixel 12v illustrated in FIG. 73 includes the electrode 105 for conducting with another semiconductor substrate, and the dummy electrode 108 that does not need to conduct with the other semiconductor substrate. The electrode 105 disposed on the right side of the pixel 12v illustrated in FIG. 73 has the same configuration as the electrode 105 illustrated in FIG. 71, descriptions thereof will be omitted.

When a region where the electrode 105 is disposed and a region where the electrode 105 is not disposed are present due to the layout or the like, for example, the dummy electrode 108 is disposed in the region where the electrode 105 is not disposed. The dummy electrode 108 is disposed, for example, in a region where the bonding with other semiconductor substrate is weak, such that the bonding strength between the semiconductor substrates does not decrease. As such, the dummy electrode 108 can be formed relatively larger than the electrode 105 for which conductivity is required.

As illustrated in FIG. 73, the dummy electrode 108 illustrated on the left side of the figure is larger than the electrode 105 illustrated on the right side of the figure. Forming the dummy electrode 108 larger also increases the amount of copper embedded in a connection hole 123, and thus the amount of expansion during the heat treatment also increases. In such a case, a reduction in the amount of expansion, which is of concern with the miniaturized electrode 105, does not easily arise in the dummy electrode 108, which makes it possible to omit the air layer 802.

In the dummy electrode 108 illustrated in FIG. 73, only the barrier metal 107 is formed between the interlayer insulating film 103 and the dummy electrode 108, and the liner film 801, the air layer 802, and the like are not formed. In this manner, the configurations of the electrode including the dummy electrode 108 and the electrode including the electrode 105 can also be different.

### Manufacture According to Embodiment 20-2

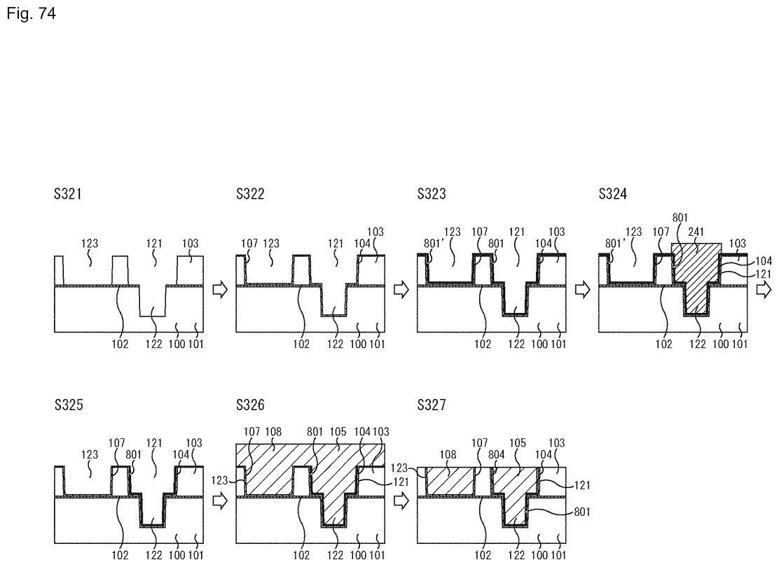

The manufacture of the pixel 12v having the configuration of the electrode 105 illustrated in FIG. 73 will be described with reference to FIG. 74. The manufacture of the part of the electrode 105 and the dummy electrode 108 will be described with reference to FIG. 74.

In step S321, a substrate is prepared in which the stacked film 100 is formed, with the interlayer insulating film 101, the liner insulating film 102, and the interlayer insulating film 103 stacked therein. The connection hole 121, the interconnect hole 122, and the connection hole 123 are formed by etching the stacked film 100. For example, in a photolithography step, a photoresist is applied to generate a resist pattern for forming the connection hole 121, the interconnect hole 122, and the connection hole 123, and dry etching is performed using the resist pattern as a mask to form the connection hole 121, the interconnect hole 122, and the connection hole 123.

In step S322, the barrier metal 104 is formed by sputtering, for example. The barrier metal 104 is formed on the side face and the bottom face of the connection hole 121, the side face and the bottom face of the interconnect hole 122, and the side face and the bottom face of the connection hole 123, and is also formed on the top face of the stacked film 100.

In step S323, the liner film 801 is formed on the barrier metal 104. The liner film 801 can also be formed by sputtering. In step S323, the liner film 801 is formed on the side face and the bottom face of the connection hole 121, the side face and the bottom face of the interconnect hole 122, the side face and the bottom face of the connection hole 123, and the top face of the stacked film 100. The liner film 801 formed on the side face and the bottom face of the connection hole 123 will be denoted as a liner film 801′.

In step S324, the parts to serve as the electrode 105, which in this case are the connection hole 121 and the interconnect hole 122, are filled (applied) with a resist 241. An etching step is performed, and dry etching is performed using the resist pattern generated in the photolithography step as a mask, which removes the liner film 801′ formed in the connection hole 123 that is to serve as the dummy electrode 108.

In step S325, an ashing and washing process is performed, the resist 241 is removed, and wet washing is performed.

In step S326, the material of the electrode 105, e.g., copper (Cu), is embedded in the connection hole 121 and the interconnect hole 122. The material of the dummy electrode 108, e.g., copper (Cu), is also embedded in the connection hole 123. The copper (Cu) is embedded in the connection hole 121, the interconnect hole 122, and the connection hole 123 by Cu sputtering followed by Cu plating.

In step S327, the Cu is polished and flattened. In this step, the excess part of the Cu and the barrier metal 104 on the top face of the stacked film 100 are removed by CMP. In step S327, the air layer 802 is formed.

The electrode 105 including the air layer 802 illustrated in FIG. 73, and the pixel 12v having the dummy electrode 108 which does not include the air layer 802, can be formed through the foregoing steps.

### Embodiment 20-3

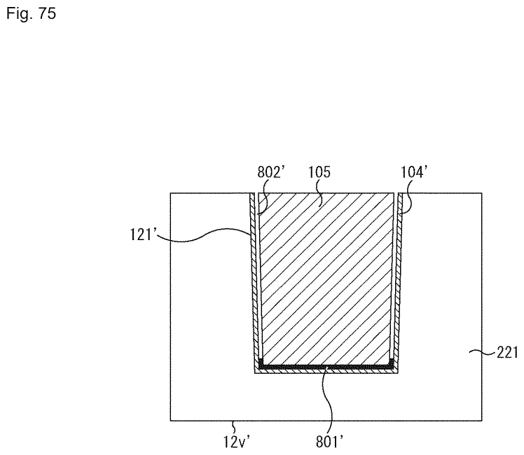

FIG. 75 is a diagram illustrating an example of the configuration of a pixel 12v′ according to Embodiment 20-3 in which the present technique is applied. Parts that are the same between the pixel 12v′ according to Embodiment 20-3, illustrated in FIG. 75, and the pixel 12v according to Embodiment 20-1, illustrated in FIG. 71, will be given the same reference signs, and descriptions thereof will be omitted as appropriate.

The pixel 12v according to Embodiment 20-1, illustrated in FIG. 71, has a dual damascene structure, whereas the pixel 12v′ according to Embodiment 20-3, illustrated in FIG. 75, has a single damascene structure.

As illustrated in FIG. 75, in the electrode formed at the bonded part, a connection hole 121′ is provided in an insulating film 221, and the barrier metal 104 is formed on the side face and the bottom face of the connection hole 121′. An air layer 802′ is formed between the barrier metal 104 formed on the side face of the connection hole 121′ and the electrode 105.

The air layer 802′ is provided as a film that does not inhibit thermal expansion of the material constituting the electrode 105 during heat treatment. Accordingly, the air layer 802′ does not inhibit the expansion of the copper of the electrode 105 within the connection hole 121′ during the heat treatment. The expansion of the electrode 105 is therefore not inhibited, and the bonding with the electrode provided on the substrate to be affixed is performed without problems.

### Manufacture According to Embodiment 20-3

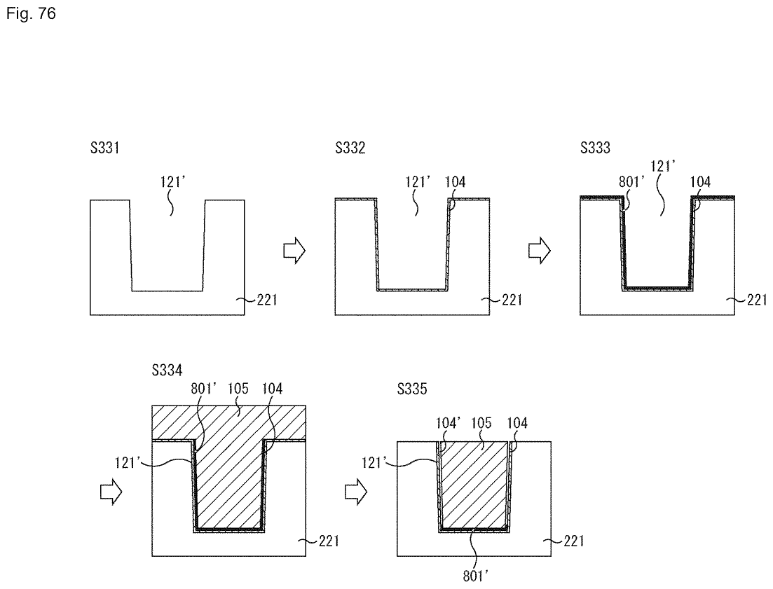

The manufacture of the pixel 12v′ having the configuration of the electrode 105 illustrated in FIG. 75 will be described with reference to FIG. 76. The manufacture of the part of the electrode 105 will be described with reference to FIG. 76.

In step S331, a semiconductor substrate in which the connection hole 121′ is formed in the insulating film 221 is prepared. The connection hole 121′ is formed by etching the semiconductor substrate. For example, in a photolithography step, a photoresist is applied to generate a resist pattern for forming the connection hole 121′. Dry etching is performed using the generated resist pattern as a mask, which forms the connection hole 121′.

In step S332, the barrier metal 104 is formed by sputtering, for example. The barrier metal 104 is formed on the side face and the bottom face of the connection hole 121′, and is also formed on the top face of the insulating film 221.

In step S333, the liner film 801′ is formed on the barrier metal 104. The liner film 801′ can also be formed by sputtering.

In step S334, the material of the electrode 105, e.g., copper (Cu), is embedded in the connection hole 121′. The electrode 105, constituted by copper (Cu), is embedded in the connection hole 121′ by Cu sputtering followed by Cu plating.

In step S335, the Cu is polished and flattened. In this step, the excess part of the Cu, as well as the barrier metal 104 and the liner film 801′ on the top face of the insulating film 221, are removed by CMP. In this step, the liner film 801′ formed on the side face of the connection hole 121′ is corroded, and the air layer 802′ is formed.

An electrode including the air layer 802′ illustrated in FIG. 75 can be formed through the foregoing steps.

### Embodiment 20-4

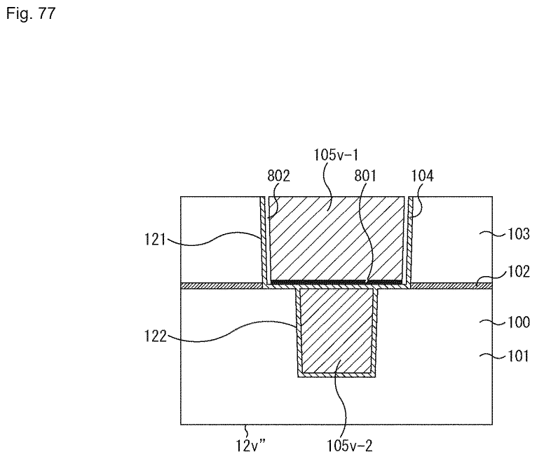

FIG. 77 is a diagram illustrating an example of the configuration of a pixel 12v″ according to Embodiment 20-4 in which the present technique is applied. Parts that are the same between the pixel 12v″ according to Embodiment 20-4, illustrated in FIG. 77, and the pixel 12v according to Embodiment 20-1, illustrated in FIG. 71, will be given the same reference signs, and descriptions thereof will be omitted as appropriate.

When comparing the pixel 12v″ according to Embodiment 20-4, illustrated in FIG. 77, and the pixel 12v according to Embodiment 20-1, illustrated in FIG. 71, the pixel 12v differs in that the electrode 105 is constituted by an electrode 105v-1 and an electrode 105v-2 formed of different materials. The other points are the same.

The electrode 105 of the pixel 12v″ illustrated in FIG. 77 is constituted by the electrode 105v-1, which is formed of a first material, and the electrode 105v-2, which is formed of a second material different from the first material. In the example illustrated in FIG. 77, the electrode 105v-1 is an electrode formed in the connection hole 121, and the electrode 105v-2 is an electrode formed in the interconnect hole 122.

The barrier metal 104 and the air layer 802 are formed on the side wall of the connection hole 121. The barrier metal 104 and the liner film 801 are formed on the bottom face of the connection hole 121. The barrier metal 104 is formed on the side wall and the bottom face of the interconnect hole 122.

The electrode 105v-1 formed in the connection hole 121 is formed of the first material, which is susceptible to expansion, e.g., Cu, and the air layer 802 is also formed to prevent the expansion of the electrode from being inhibited. Accordingly, the amount of expansion of the electrode 105v-1 formed in the connection hole 121 can be increased, and the electrode 105v-1 can expand sufficiently. Co can be used as the second material constituting the electrode 105v-2, for example.

In the configuration illustrated in FIG. 77 too, the expansion of the electrode 105 is not inhibited, and the bonding with the electrode provided on the substrate to be affixed can be performed without problems.

### Embodiment 20-5

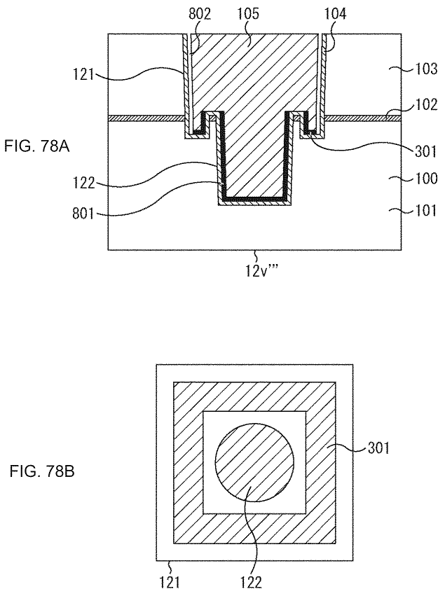

A in FIG. 78 is a diagram illustrating an example of the cross-sectional configuration of a pixel 12v′″ according to Embodiment 20-5 in which the present technique is applied, and B in FIG. 78 is a diagram illustrating the planar configuration of the pixel 12v″. Parts that are the same between the pixel 12v″ according to Embodiment 20-5, illustrated in FIG. 78, and the pixel 12v according to Embodiment 20-1, illustrated in FIG. 71, will be given the same reference signs, and descriptions thereof will be omitted as appropriate.

When comparing the pixel 12v′″ according to Embodiment 20-5, illustrated in FIG. 78, and the pixel 12v according to Embodiment 20-1, illustrated in FIG. 71, the pixel 12v′″ has a different configuration in that the trench 301 is added to the pixel 12v. The other points are the same.

The trench 301 is formed in the bottom face of the connection hole 121 of the pixel 12v′″ illustrated in FIG. 78. The trench 301 is formed in a region corresponding to the difference between the bottom face of the connection hole 121 and the face of the interconnect hole 122 on the connection hole 121 side thereof.

Referring to the example of the planar configuration illustrated in B in FIG. 78, the connection hole 121 is formed in a square shape, and the interconnect hole 122 is formed as a circle in the center of the connection hole 121. The trench 301 is formed in a square shape within the connection hole 121, in the region outside of the interconnect hole 122, so as to surround the interconnect hole 122.

Referring to the example of the cross-sectional configuration illustrated in A in FIG. 78, the barrier metal 104 is formed on the side face and the bottom faces of the trench 301. Furthermore, the liner film 801 is also formed on the side face of the trench 301. The air layer 802 is formed on the side face of the connection hole 121, as in Embodiments 20-1 to 20-4.

In the pixel 12v′″, providing the trench 301 increases the amount of copper (Cu), for example, constituting the electrode 105, and thus the amount of expansion can be increased.

In the configuration illustrated in FIG. 78 too, the electrode 105 is configured to be in contact with the air layer 802. Using the configuration in which the air layer 802 is provided enables the copper of the electrode 105 within the connection hole 121 to expand during the heat treatment without being inhibited, and thus the bonding with the electrode provided on the substrate to be affixed can be performed without problems.

### Embodiment 21-1

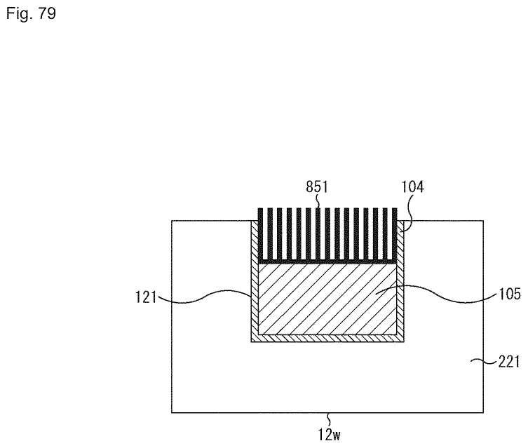

FIG. 79 is a diagram illustrating an example of the configuration of a pixel 12w according to Embodiment 21-1 in which the present technique is applied. FIG. 79 illustrates a single electrode constituting the pixel 12w, and illustrates an electrode (electrode pad) which is provided on the bonding face side where the first semiconductor substrate 30 and the second semiconductor substrate 40 are bonded, to make the first semiconductor substrate 30 and the second semiconductor substrate 40 conductive with each other.

As illustrated in FIG. 79, the electrode formed at the bonded part is configured by forming the electrode 105 in the insulating film 221.

The electrode 105 illustrated in FIG. 79 has a shape based on the single damascene process, and is configured to have the connection hole 121. Note that the present technique can be applied to an electrode having a shape based on the dual damascene process, and can also be applied in a configuration having a connection hole and an interconnect hole.

As illustrated in FIG. 79, in the electrode formed at the bonded part, the connection hole 121 is provided in the insulating film 221, and the barrier metal 104 is formed on the side face and the bottom face of the connection hole 121. Carbon nanotubes 851 are formed on the bonding face side of the electrode 105. Prior to the bonding with the other semiconductor substrate, the carbon nanotubes 851 are formed to a position higher than the bonding face of the insulating film 221.

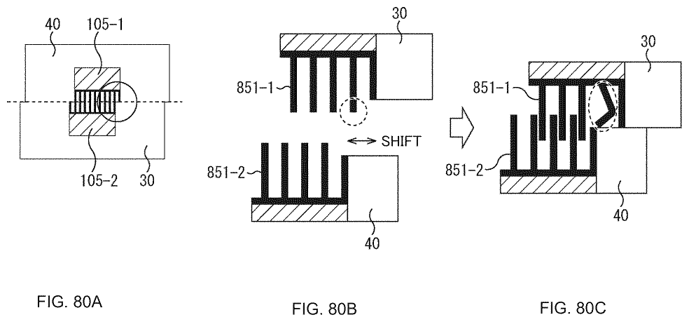

A in FIG. 80 is a diagram illustrating the state of one electrode when the first semiconductor substrate 30 and the second semiconductor substrate 40, including the electrode 105 illustrated in FIG. 79, are bonded. The first semiconductor substrate 30 located on the upper side and the second semiconductor substrate 40 located on the lower side are bonded in a slightly shifted state. The first semiconductor substrate 30 and the second semiconductor substrate 40 are electrically connected by connecting carbon nanotubes 851-1 formed on the electrode 105-1 of the first semiconductor substrate 30 with carbon nanotubes 851-2 formed on the electrode 105-2 of the second semiconductor substrate 40.

B in FIG. 80 is a diagram illustrating the state before the bonding of the pixel in the bonding state illustrated in A in FIG. 80, with a part thereof enlarged. A pixel 12w-1 is bonded to a pixel 12w-2 having been shifted to the right side in the figure. The carbon nanotubes 851-1 in the dotted line circle in B in FIG. 80 are the part that is bonded to the insulating film 221 of the pixel 12w-2 in the bonding. The carbon nanotube 851-1 in the shifted position is broken at the time of bonding, as illustrated in C in FIG. 80, and therefore does not inhibit the bonding of the first semiconductor substrate 30 and the second semiconductor substrate 40. However, the carbon nanotubes 851 located in positions other than the shifted position are bonded to each other, and thus the first semiconductor substrate 30 and the second semiconductor substrate 40 can be electrically bonded more reliably.

Although FIG. 80 illustrates a case where the carbon nanotubes 851 are formed in the electrodes 105 of both the first semiconductor substrate 30 and the second semiconductor substrate 40, forming the carbon nanotubes 851 in only one electrode and bonding the electrode directly the other electrode 105 (Cu) also falls within the scope of the present technique.

### First Example of Manufacture According to Embodiment 21

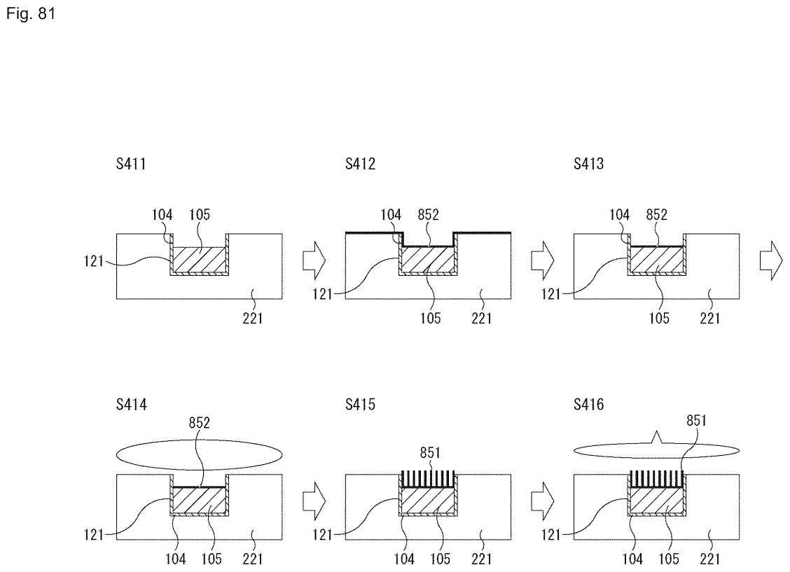

A first example of the manufacture of the pixel 12w having the configuration of the electrode 105 illustrated in FIG. 79 will be described with reference to FIG. 81.

The manufacture of the part of the electrode 105 will be described with reference to FIG. 81.

In step S411, a semiconductor substrate is prepared in which the connection hole 121 is formed in the insulating film 221, the barrier metal 104 is formed in the connection hole 121, and copper (Cu), which is part of the electrode 105, is embedded therein. The copper is embedded to a position lower than the bonding face of the insulating film 221.

In step S412, a catalyst metal 852 is formed by sputtering, for example. The catalyst metal 852 is a material used to form the carbon nanotubes 851. The catalyst metal 852 is formed on the side face of the connection hole 121, the top face of the electrode 105, and the top face of the insulating film 221.

For example, Ti (titanium), Ni (nickel), Ru (ruthenium), Mo (molybdenum), Co (cobalt), Fe (iron), or the like can be used as the catalyst metal 852. The catalyst metal 852 may be a single layer constituted by these metals, or may be multiple layers in which two or more metals are stacked. The catalyst metal 852 may be a mixture of these metals. If the catalyst metal 852 is multiple layers or a mixture, the uppermost layer is preferably a layer of Co (cobalt).

In step S413, the catalyst metal 852 is polished and flattened. In this step, the catalyst metal 852 on the top face of the insulating film 221 is removed by CMP.

In step S414, a plasma activation treatment is performed. N2 gas is used for the plasma activation treatment, for example. In step S415, the carbon nanotubes 851 are formed by performing Chemical Vapor Deposition (CVD) using CH4 or C2H6, for example.

Then, by performing cleaning as indicated in step S416, an electrode can be formed in which the carbon nanotubes 851 illustrated in FIG. 79 are formed.

### Second Example of Manufacture According to Embodiment 21

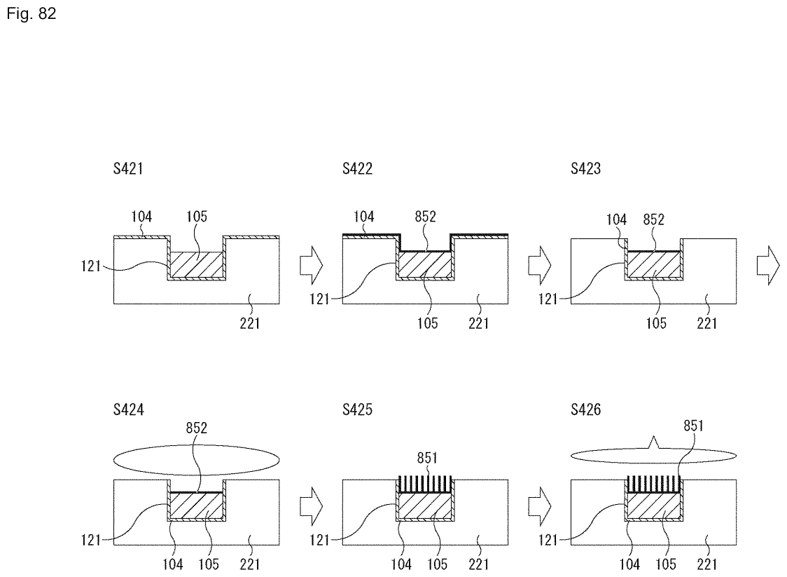

A second example of the manufacture of the pixel 12w having the configuration of the electrode 105 illustrated in FIG. 79 will be described with reference to FIG. 82.

In step S421, a semiconductor substrate is prepared in which the connection hole 121 is formed in the insulating film 221, the barrier metal 104 is formed in the connection hole 121 and on the insulating film 221, and copper (Cu), which is part of the electrode 105, is embedded therein. In step S411 described with reference to FIG. 81, the semiconductor substrate after the polishing of the barrier metal 104 has been prepared and the semiconductor substrate is therefore in a state where the barrier metal 104 is not formed on the insulating film 221. However, in step S421 described with reference to FIG. 82, the semiconductor substrate before the polishing of the barrier metal 104 has been prepared, and the semiconductor substrate is therefore in a state where the barrier metal 104 is on the insulating film 221.

In step S422, the catalyst metal 852 is formed by sputtering, for example. The catalyst metal 852 is formed on the side face of the connection hole 121, the top face of the electrode 105, and the barrier metal 104 of the insulating film 221.

In step S423, the catalyst metal 852 and the barrier metal 104 are polished and flattened. In this step, the catalyst metal 852 and the barrier metal 104 on the top face of the insulating film 221 are removed by CMP.

In step S424, plasma activation treatment using N2 gas is performed, for example. In step S425, the carbon nanotubes 851 are formed by performing CVD using CH4 or C2H6, for example.

Then, by performing cleaning as indicated in step S426, an electrode can be formed in which the carbon nanotubes 851 illustrated in FIG. 79 are formed.

### Third Example of Manufacture According to Embodiment 21

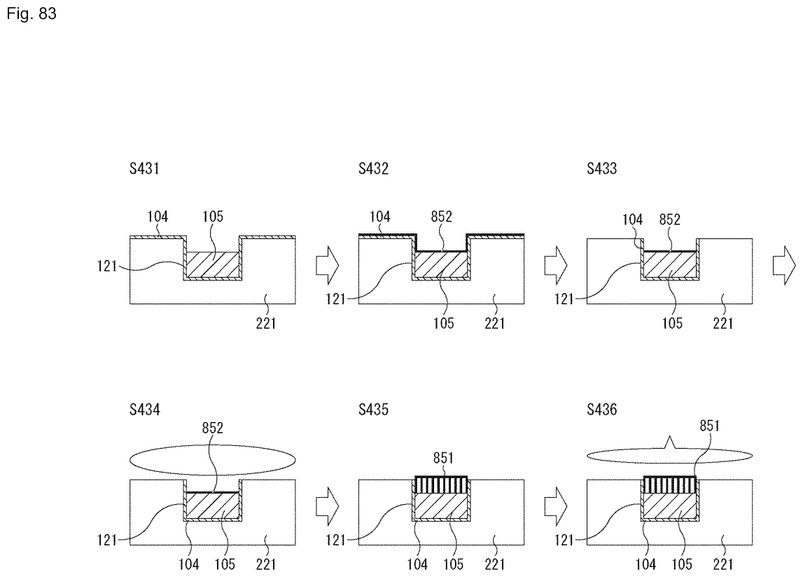

A third example of the manufacture of the pixel 12w having the configuration of the electrode 105 illustrated in FIG. 79 will be described with reference to FIG. 83. The third example of the manufacture described with reference to FIG. 83 is the same process as the second example of the manufacture described with reference to FIG. 82, except that when Fe (iron), for example, is used for the catalyst metal 852, the carbon nanotubes 851 are formed under the catalyst metal 852.

In step S431, a semiconductor substrate is prepared in which the connection hole 121 is formed in the insulating film 221, the barrier metal 104 is formed in the connection hole 121 and on the insulating film 221, and copper (Cu), which is part of the electrode 105, is embedded therein.

In step S432, the catalyst metal 852 is formed by sputtering, for example. The catalyst metal 852 is formed on the side face of the connection hole 121, the top face of the electrode 105, and the barrier metal 104 of the insulating film 221. Fe (iron) is used as the catalyst metal 852, for example.

In step S433, the catalyst metal 852 and the barrier metal 104 on the top face of the insulating film 221 are removed by CMP.

In step S434, plasma activation treatment using N2 gas is performed, for example. In step S435, the carbon nanotubes 851 are formed by performing CVD using CH4 or C2H6, for example. The carbon nanotubes 851 are grown and formed between the catalyst metal 852 and the electrode 105.

Then, by performing cleaning as indicated in step S436, an electrode can be formed in which the carbon nanotubes 851 are formed on the lower side of the catalyst metal 852.

### Embodiment 21-2

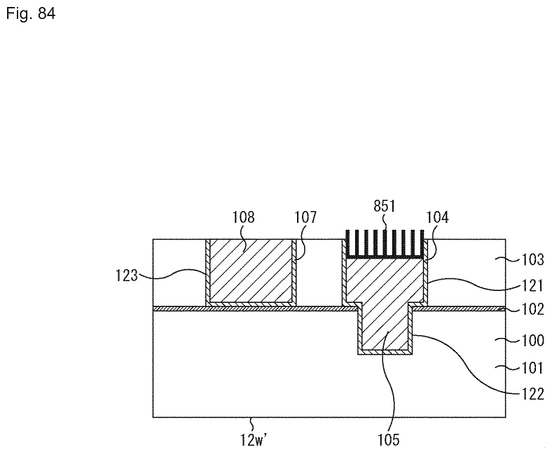

FIG. 84 is a diagram illustrating an example of the configuration of a pixel 12w′ according to Embodiment 21-2 in which the present technique is applied. Parts that are the same between the pixel 12w′ according to Embodiment 21-2, illustrated in FIG. 84, and the pixel 12w according to Embodiment 21-1, illustrated in FIG. 79, will be given the same reference signs, and descriptions thereof will be omitted as appropriate.

The pixel 12w′ according to Embodiment 21-2, illustrated in FIG. 84, differs from the pixel 12w according to Embodiment 21-1, illustrated in FIG. 79, in that the dummy electrode 108 has been added and the pixel is formed in a dual damascene structure. The other points are the same.

As illustrated in FIG. 84, the electrode formed at the bonded part is configured by forming an electrode 105 in a stacked film 100 in which an interlayer insulating film 101, a liner insulating film 102, and an interlayer insulating film 103 are stacked.

The electrode 105 illustrated in FIG. 84 has a shape based on the dual damascene process, and is configured to have a connection hole 121 and an interconnect hole 122. The barrier metal 104 is formed between the stacked film 100 and the electrode 105. The electrode 105 is filled with Cu to a position lower than the bonding face of the stacked film 100, and the carbon nanotubes 851 are formed on the top face.

The pixel 12w illustrated in FIG. 84 includes the electrode 105 for conducting with another semiconductor substrate, and the dummy electrode 108 that does not need to conduct with the other semiconductor substrate. When a region where the electrode 105 is disposed and a region where the electrode 105 is not disposed are present due to the layout or the like, for example, the dummy electrode 108 is disposed in the region where the electrode 105 is not disposed. The dummy electrode 108 is disposed, for example, in a region where the bonding with other semiconductor substrate is weak, such that the bonding strength between the semiconductor substrates does not decrease. As such, the dummy electrode 108 can be formed relatively larger than the electrode 105 for which conductivity is required.

In the dummy electrode 108 illustrated in FIG. 84, only the barrier metal 107 is formed between the interlayer insulating film 103 and the dummy electrode 108, and the carbon nanotubes 851 are not formed. In this manner, the configurations of the electrode including the dummy electrode 108 and the electrode including the electrode 105 can also be different.

### Manufacture According to Embodiment 21-2

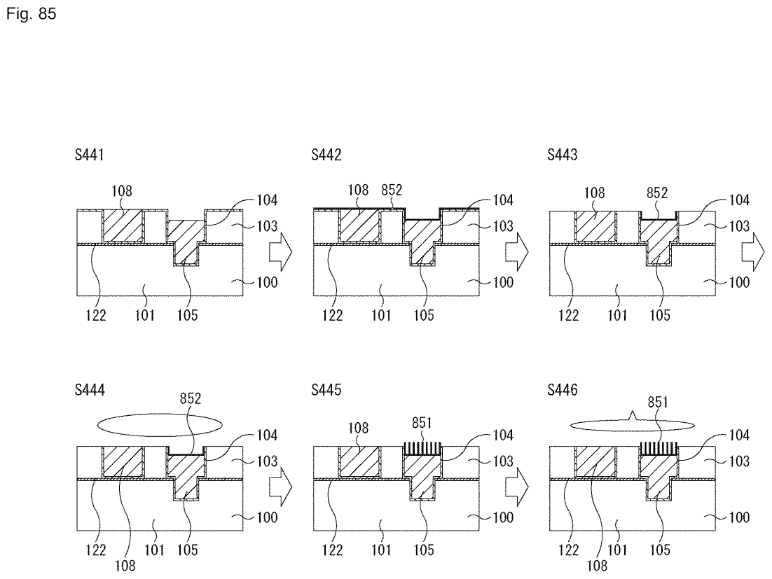

The manufacture of the pixel 12w′ having the configuration of the electrode 105 illustrated in FIG. 84 will be described with reference to FIG. 85.

In step S441, a semiconductor substrate is prepared in which the connection hole 121 and the interconnect hole 122 are formed in the stacked film 100, the barrier metal 104 is formed in the connection hole 121, the interconnect hole 122, and the stacked film 100, and copper (Cu), serving as part of the electrode 105, is embedded therein. The connection hole 123 to serve as the dummy electrode 108 is also formed in the semiconductor substrate, the barrier metal 107 is formed in the connection hole 123, and copper (Cu) serving as the dummy electrode 108 is embedded therein.

In step S442, the catalyst metal 852 is formed by sputtering, for example. The catalyst metal 852 is formed on the side face of the connection hole 121, the top face of the electrode 105, the top face of the dummy electrode 108, and the barrier metal 104 on the stacked film 100.

In step S443, the catalyst metal 852 and the barrier metal 104 are polished and flattened. In this step, the catalyst metal 852 and the barrier metal 104 formed on the top face of the stacked film 100 and the top face of the dummy electrode 108 are removed by CMP.

In step S444, plasma activation treatment using N2 gas is performed, for example. In step S445, the carbon nanotubes 851 are formed on the electrode 105 by performing CVD using CH4 or C2H6, for example.

Then, by performing cleaning as indicated in step S446, the electrode 105 in which the carbon nanotubes 851 are formed on the catalyst metal 852, and the dummy electrode 108, can be formed.

### <Adjusting Density of Carbon Nanotubes>

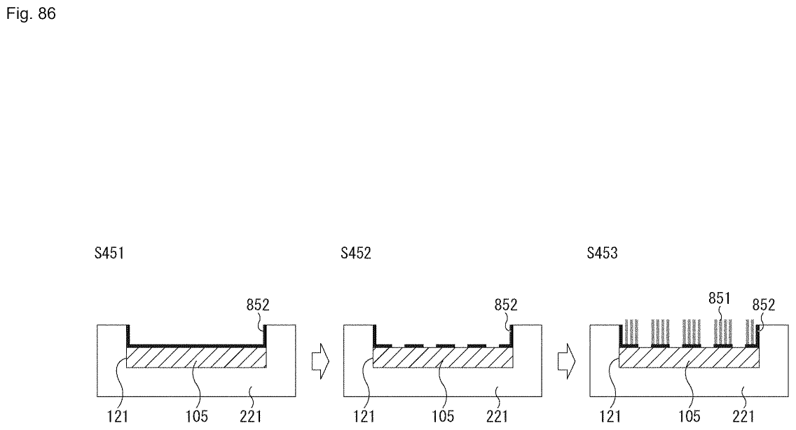

Adjusting the density of the carbon nanotubes 851 will be described. The density of the carbon nanotubes 851 can be adjusted to a desired density by including the process illustrated in FIG. 86 in the manufacturing process described above and patterning the catalyst metal 852.

The descriptions will continue using the process of manufacturing the electrode of the pixel 12w according to Embodiment 21-1, described with reference to FIG. 81, as an example. The state in which the catalyst metal 852 is formed on the electrode 105 in step S413 in FIG. 81 is assumed to be the state in step S451 of FIG. 86. As indicated in the depiction of step S451 (FIG. 86), when the catalyst metal 852 is formed on the electrode 105, the catalyst metal 852, e.g., Ti (titanium), is patterned performed in step S452.

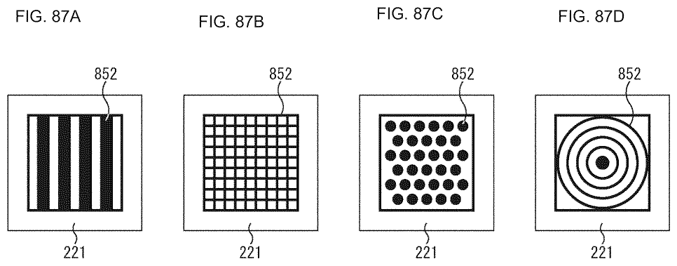

FIG. 87 illustrates examples of the shape of the patterning. FIG. 87 illustrates diagrams of the shape of the catalyst metal 852 after patterning, and is plan views of the catalyst metal 852 when viewed from above. As illustrated in A in FIG. 87, the catalyst metal 852 can be patterned in a stripe shape. The density of the carbon nanotubes 851 formed can be adjusted by adjusting the width of the stripes, the number of stripes, and the like.

As illustrated in B in FIG. 87, the catalyst metal 852 can be patterned in a grid shape. The density of the carbon nanotubes 851 formed can be adjusted by adjusting the thicknesses of the grid lines, the number of lines, and the like.

As illustrated in C in FIG. 87, the catalyst metal 852 can be patterned in a circular pattern (a hexagonal grid). The density of the carbon nanotubes 851 formed can be adjusted by adjusting the size of each circle, the number of circles, and the like.

As illustrated in D in FIG. 87, the catalyst metal 852 can be patterned as concentric circles. The density of the carbon nanotubes 851 formed can be adjusted by adjusting the thickness of the line constituting one of the concentric circles, the number of circles, and the like.

### Embodiment 22-1

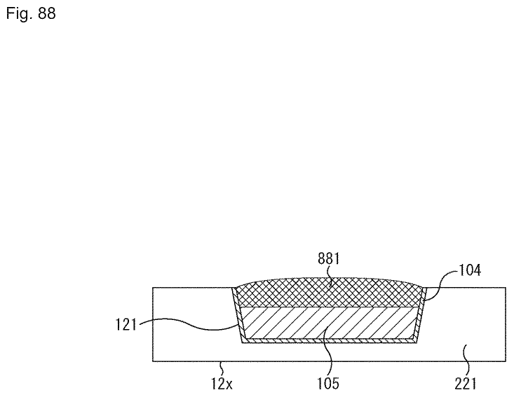

FIG. 88 is a diagram illustrating an example of the configuration of a pixel 12x according to Embodiment 22-1 in which the present technique is applied. FIG. 88 illustrates a single electrode constituting the pixel 12x, and illustrates an electrode (electrode pad) which is provided on the bonding face side where the first semiconductor substrate 30 and the second semiconductor substrate 40 are bonded, to make the first semiconductor substrate 30 and the second semiconductor substrate 40 conductive with each other.

As illustrated in FIG. 88, the electrode formed at the bonded part is configured by forming the electrode 105 in the insulating film 221.

The electrode 105 illustrated in FIG. 88 has a shape based on the single damascene process, and is configured to have the connection hole 121. Note that the present technique can be applied to an electrode having a shape based on the dual damascene process, and can also be applied in a configuration having a connection hole and an interconnect hole. The present technique can also be applied to a structure having a dummy electrode.

As illustrated in FIG. 88, in the electrode formed at the bonded part, the connection hole 121 is provided in the insulating film 221, and the barrier metal 104 is formed on the side face and the bottom face of the connection hole 121. A porous metal 881 is formed on the bonding face side of the electrode 105. The porous metal 881 is formed up to a position higher than the bonding face of the insulating film 221.

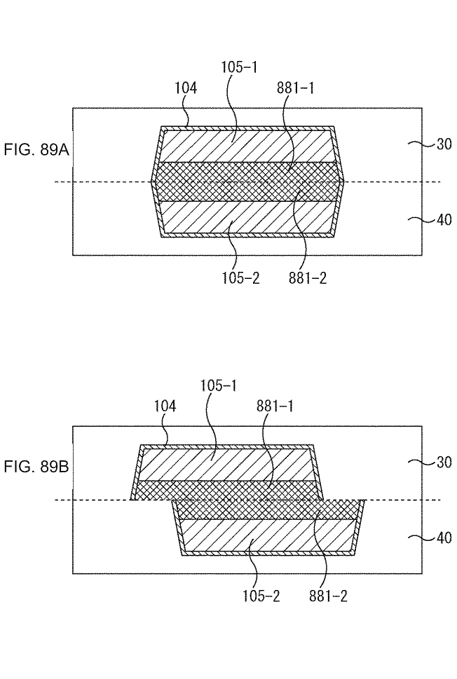

A in FIG. 89 is a diagram illustrating the state of one electrode when the first semiconductor substrate 30 and the second semiconductor substrate 40, including the electrode 105 illustrated in FIG. 88, are bonded. The first semiconductor substrate 30 located on the upper side and the second semiconductor substrate 40 located on the lower side are bonded in an unshifted state. The first semiconductor substrate 30 and the second semiconductor substrate 40 are electrically connected by bonding a porous metal 881-1 formed on the electrode 105-1 of the first semiconductor substrate 30 with a porous metal 881-2 formed on the electrode 105-2 of the second semiconductor substrate 40. The porous metal 881 can be compressed during the bonding to strengthen the bond between the porous metals 881.

The bonding state illustrated in B in FIG. 89 is a state in which the first semiconductor substrate 30 located on the upper side and the second semiconductor substrate 40 located on the lower side are bonded in a slightly shifted state. The first semiconductor substrate 30 and the second semiconductor substrate 40 are electrically connected by bonding the overlapping parts of the porous metal 881-1 formed on the electrode 105-1 of the first semiconductor substrate 30 and the porous metal 881-2 formed on the electrode 105-2 of the second semiconductor substrate 40.

Although FIG. 89 illustrates a case where the porous metal 881 is formed in the electrodes 105 of both the first semiconductor substrate 30 and the second semiconductor substrate 40, forming the porous metal 881 in only one electrode and bonding the electrode directly the other electrode 105 (Cu) also falls within the scope of the present technique.

### First Example of Manufacture According to Embodiment 22-1

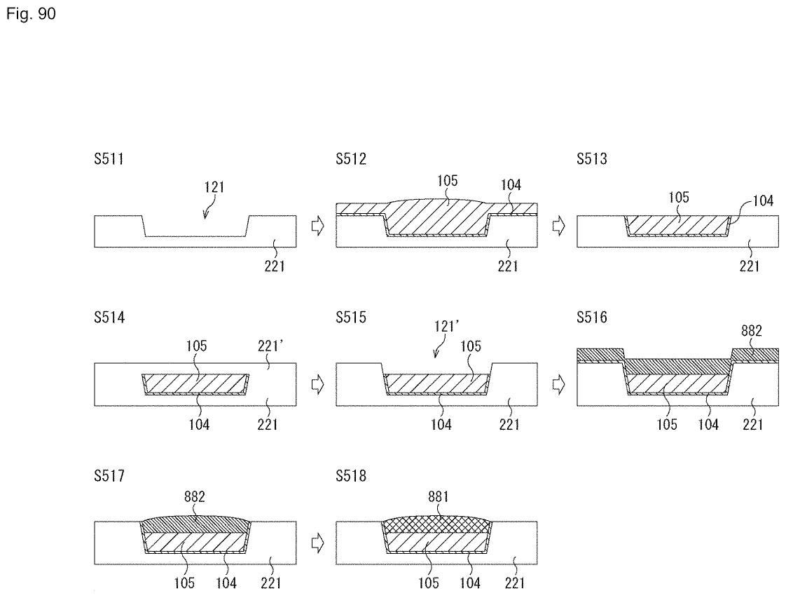

A first example of the manufacture of the pixel 12x having the configuration of the electrode 105 illustrated in FIG. 88 will be described with reference to FIG. 90. The manufacture of the part of the electrode 105 will be described with reference to FIG. 90.

In step S511, the connection hole 121 is formed in the insulating film 221. In step S512, the barrier metal 104 is formed in the connection hole 121, and the copper (Cu) to serve as the electrode 105 is embedded therein. The barrier metal 104 and the copper are also formed on the bonding face of the insulating film 221. Although the description will continue assuming that copper is used as the electrode material, other materials may be used. Because the porous metal 881 is formed in a subsequent step, a material that can be made porous is used as the material of the electrode 105.

In step S513, the electrode 105 and the barrier metal 104 are polished and flattened. In this step, the electrode 105 (copper) and the barrier metal 104 on the top face of the insulating film 221 are removed by CMP.

In step S514, an insulating film 221′ is formed on the electrode 105 and the insulating film 221. The insulating film 221′ uses the same material as that of the insulating film 221, and is a part that will serve as the insulating film 221. SiO₂, SION, SiCN, or the like, for example, is used for the insulating film 221 and the insulating film 221′, which are formed by CVD, ALD, or the like.

In step S515, the connection hole 121′ is formed. The insulating film 221′ is processed to form a part to serve as the connection hole 121, i.e., the part where the porous metal 881 is to be formed.

In step S516, the barrier metal 104 and an alloy 882 are formed. The barrier metal 104 is formed in step S516 in order to form the barrier metal 104 on the side wall in the connection hole 121′ formed in step S515. The barrier metal 104 and the alloy 882 are formed on the electrode 105 (copper), the side face of the connection hole 121′, and the insulating film 221. An alloy of Cu and Zn is used as the alloy 882, for example.

In step S517, the alloy 882 and the barrier metal 104 on the top face of the insulating film 221 are removed by CMP. The alloy 882 formed on the electrode 105 in this step is processed to be made convex and extend to a position higher than the bonding face of the insulating film 221.

In step S518, the porous metal 881 is formed. For example, if an alloy of Cu and Zn is used for the alloy 882, pores are formed by etching the Zn. For example, the porous metal 881 is formed by etching using an azole-based additive in a copper sulfate plating solution.

The pores (the porous metal 881) will be described here. The porous metal has a porosity of about 10 to 50%, and the depth of the porous part (the length from the highest point of the porous metal 881 to Cu) is about several nm to several tens of nm.

The porous metal is shaped in a convex shape, as indicated in the depiction of step S518. Being formed in a convex shape, the porous metal can be compressed during bonding so as to reliably connect to the other porous metal or the electrode. As such, it is preferable that the porous metal 881 have a strength that satisfies the following relationship:
yield stress during compression (plateau stress)<stress applied during bonding

An electrode including the porous metal 881 illustrated in FIG. 88 can be formed through the foregoing steps.

### First Example of Manufacture According to Embodiment 22-1

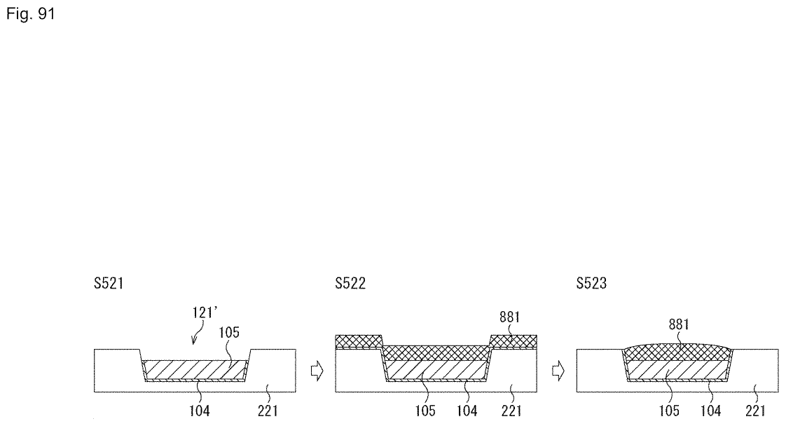

A second example of the manufacture of the pixel 12x having the configuration of the electrode 105 illustrated in FIG. 88 will be described with reference to FIG. 91.

In step S521, a semiconductor substrate is prepared in which the connection hole 121′ is formed as a result of steps S511 to S514 (FIG. 90) being performed.

In step S522, the barrier metal 104 and the porous metal 881 are formed. The porous metal 881 is formed by electrochemically etching (Cu—Zn→Zn) in hydrochloric acid.

In step S523, the porous metal 881 and the barrier metal 104 on the top face of the insulating film 221 are removed by CMP. The porous metal 881 formed on the electrode 105 in this step is processed to be made convex and extend to a position higher than the bonding face of the insulating film 221.

An electrode including the porous metal 881 illustrated in FIG. 88 can be formed through the foregoing steps.

### Third Example of Manufacture According to Embodiment 22-1

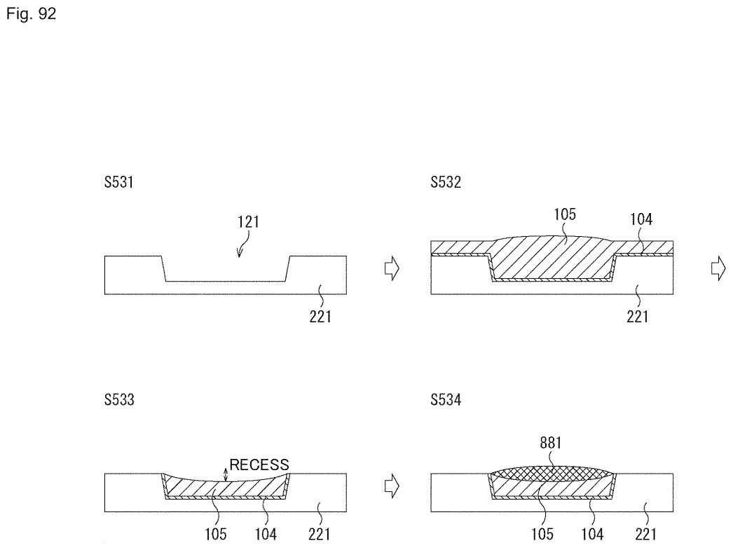

A third example of the manufacture of the pixel 12x having the configuration of the electrode 105 illustrated in FIG. 88 will be described with reference to FIG. 92.

In step S531, a semiconductor substrate is prepared in which the connection hole 121 is formed in the insulating film 221.

In step S532, the barrier metal 104 is formed in the connection hole 121, and the copper (Cu) to serve as the electrode 105 is embedded therein. In this step, the barrier metal 104 and the copper are also formed on the bonding face of the insulating film 221.

In step S533, the electrode 105 and the barrier metal 104 on the top face of the insulating film 221 are removed by CMP. The copper (electrode 105) embedded in the connection hole 121 in this step has a recessed shape due to recessing.

In step S534, the porous metal 881 is formed. For example, the porous metal 881 is formed by electroless plating (Cu—Ni—P) on the Cu serving as the electrode 105.

An electrode including the porous metal 881 illustrated in FIG. 88 can be formed through the foregoing steps.

### Fourth Example of Manufacture According to Embodiment 22-1

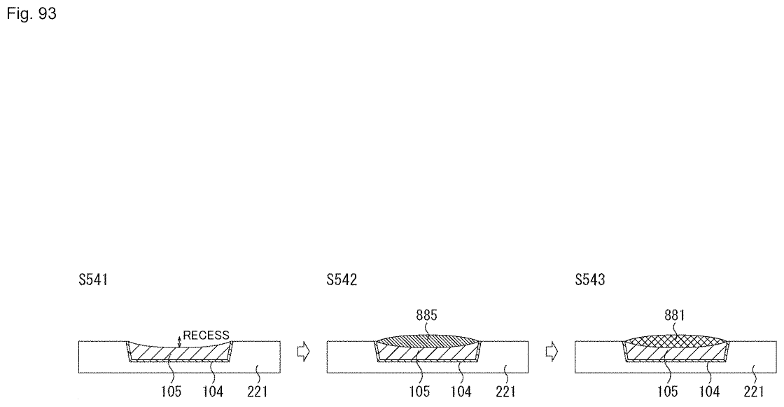

A fourth example of the manufacture of the pixel 12x having the configuration of the electrode 105 illustrated in FIG. 88 will be described with reference to FIG. 93.

In step S541, a semiconductor substrate is prepared in which an electrode 105 having a recessed shape due to recessing is formed as a result of performing steps S531 to S533 (FIG. 92).

In step S542, a metal 885 is formed (through plating) on the electrode 105. For example, Ag is used as the metal 885, and the Ag is formed through electroless plating.

In step S543, the porous metal 881 is formed. For example, an atmospheric pressure plasma in which H2 is diluted with He or Ar is generated for the Ag formed on the electrode 105, and the Ag surface is modified to form the pores.

An electrode including the porous metal 881 illustrated in FIG. 88 can be formed through the foregoing steps.

### Embodiment 22-2

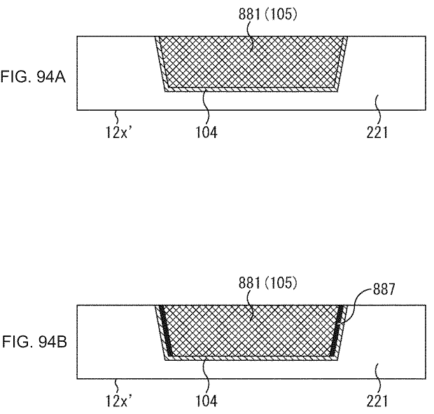

FIG. 94 is a diagram illustrating an example of the configuration of a pixel 12x′ according to Embodiment 22-2 in which the present technique is applied. Parts that are the same between the pixel 12x′ according to Embodiment 22-2, illustrated in FIG. 94, and the pixel 12x according to Embodiment 22-1, illustrated in FIG. 88, will be given the same reference signs, and descriptions thereof will be omitted as appropriate.

The electrode formed in the pixel 12x′ illustrated in A in FIG. 94 is configured by forming the porous metal 881 as the electrode 105 in the insulating film 221. In the electrode formed at the bonded part, the connection hole 121 is provided in the insulating film 221, and the barrier metal 104 is formed on the side face and the bottom face of the connection hole 121. At the part where the electrode 105 was formed in Embodiment 22-1, the porous metal 881 is formed, and the porous metal 881 functions as an electrode.

The electrode formed in the pixel 12x′ illustrated in B in FIG. 94 is configured by forming the porous metal 881 as the electrode 105 in the insulating film 221, and forming an insulating film 887 between the stacked film 100 and the porous metal 881. The insulating film 887 is provided to suppress the formation of the film from the side wall of the connection hole 121 and to increase the ease of embedding the porous metal 881.

### Manufacture According to Embodiment 22-2

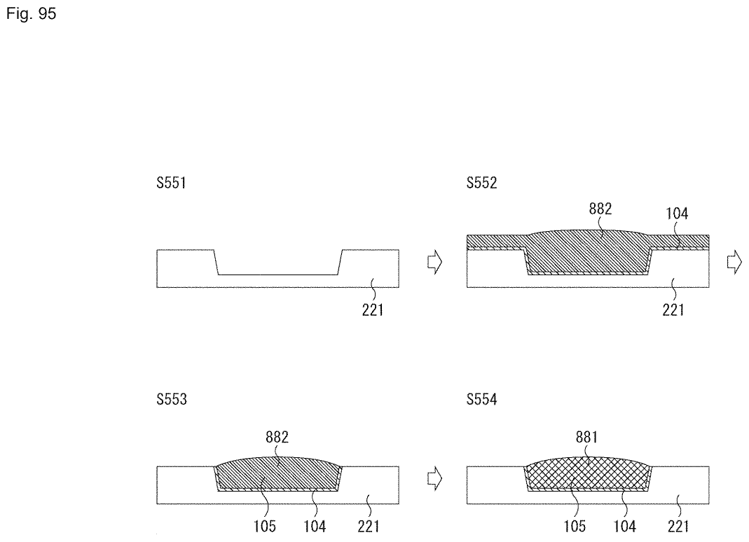

The manufacture of the pixel 12x′ having the configuration of the electrode 105 illustrated in A in FIG. 94 will be described with reference to FIG. 95. The manufacture of the part of the porous metal 881 that functions as the electrode will be described with reference to FIG. 95.

In step S551, the connection hole 121 is formed in the insulating film 221. In step S552, the barrier metal 104 is formed in the connection hole 121, and the alloy 882, which serves as the porous metal 881, is embedded (formed) therein. An alloy of Cu and Zn is used as the alloy 882, for example.

In step S553, the alloy 882 and the barrier metal 104 on the top face of the insulating film 221 are removed by CMP. The alloy 882 in this step is processed to be made convex and extend to a position higher than the bonding face of the insulating film 221.

In step S554, the porous metal 881 is formed. For example, if an alloy of Cu and Zn is used for the alloy 882, pores are formed by etching the Zn. For example, the porous metal 881 is formed by etching using an azole-based additive in a copper sulfate plating solution. The porous metal is formed by electrochemically etching (Cu—Zn→Zn) in hydrochloric acid.

The porous metal 881 has a porosity of about 10 to 50%, as in Embodiment 22-1. The depth of the porous part (the length from the highest point of the porous metal 881 to the insulating film 221) is about several hundred nm, which is at least the depth of the connection hole 121.

The porous metal 881 is shaped in a convex shape, as indicated in the depiction of step S554. Being formed in a convex shape, the porous metal can be compressed during bonding so as to reliably connect to the other porous metal or the electrode. As such, it is preferable that the porous metal 881 has a strength that satisfies the following relationship:
yield stress during compression (plateau stress)<stress applied during bonding

An electrode including the porous metal 881 illustrated in A in FIG. 94 can be formed through the foregoing steps.

### Manufacture According to Embodiment 22-2

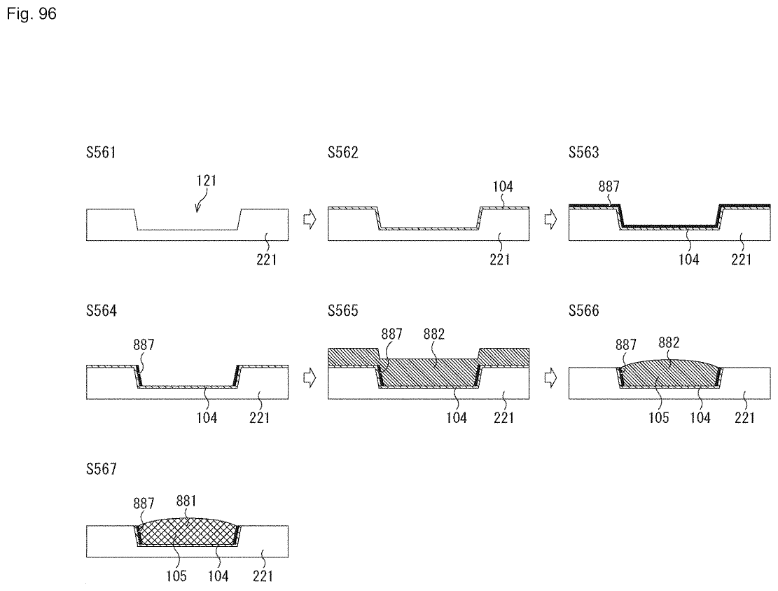

The manufacture of the pixel 12x′ having the configuration of the porous metal 881 illustrated in B in FIG. 94 will be described with reference to FIG. 96. The manufacture of the part of the porous metal 881 will be described with reference to FIG. 96.

In step S561, the connection hole 121 is formed in the insulating film 221. In step S562, the barrier metal 104 is formed in the connection hole 121 and on the bonding face of the insulating film 221. In step S563, the insulating film 887 is formed on the barrier metal 104.

In step S564, the barrier metal 104 and the insulating film 887 are polished and flattened. In this step, the barrier metal 104 and the insulating film 887 on the top face of the insulating film 221 are removed by CMP.

In step S565, the alloy 882, which serves as the porous metal 881, is embedded (formed) therein. An alloy of Cu and Zn is used as the alloy 882, for example.

In step S566, the alloy 882 on the top face of the insulating film 221 is removed by CMP. The alloy 882 in this step is processed to be made convex and extend to a position higher than the bonding face of the insulating film 221.

In step S567, the porous metal 881 is formed. For example, if an alloy of Cu and Zn is used for the alloy 882, pores are formed by etching the Zn. The process in step S567 can be performed as a step similar to step S554 (FIG. 95).

An electrode including the porous metal 881 illustrated in B in FIG. 94 can be formed through the foregoing steps.

### Example of Application in Electronic Device

The present technique can be applied broadly in electronic devices in which an image sensor is used in an image capturing unit (a photoelectric conversion unit), including imaging devices such as digital still cameras and video cameras, mobile terminal devices having imaging functions, copiers which use an image sensor in an image reading unit, and the like. The image sensor may be formed as a single chip, or may be formed as a module having an imaging function, in which an imaging unit and a signal processing unit or an optical system are packaged together.

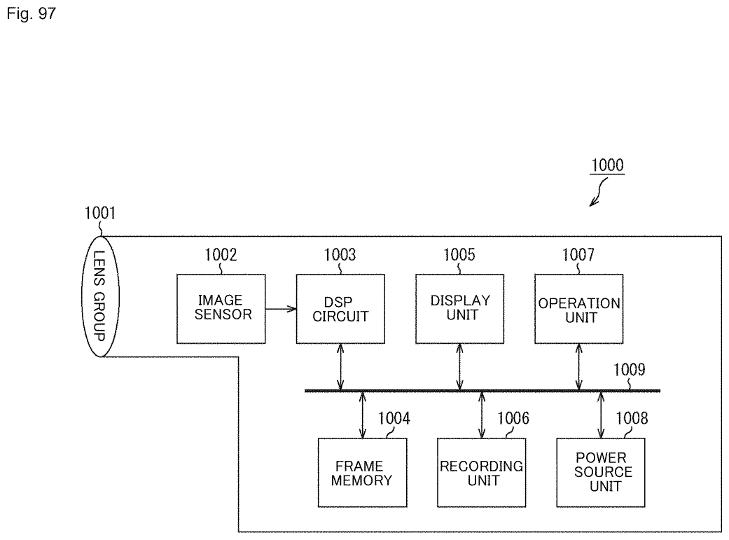

FIG. 97 is a block diagram illustrating an example of the configuration of an imaging device serving as an electronic device to which the present technique is applied.

An image sensor 1000 in FIG. 97 includes an optical unit 1001 constituted by a lens group and the like, an image sensor (an image capturing device) 1002, and a digital signal processor (DSP) circuit 1003 serving as a camera signal processing circuit. The image sensor 1000 also includes a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected to each other by a bus line 1009.

The optical unit 1001 captures incident light (image light) from a subject and forms an image on an imaging plane of the image sensor 1002. The image sensor 1002 converts the amount of incident light, with which an image is formed on the imaging plane by the optical unit 1001, into an electrical signal in units of pixels, and outputs the electrical signal as a pixel signal.

The display unit 1005 includes, for example, a low-profile display such as a Liquid Crystal Display (LCD) or an organic Electro Luminescence (EL) display, and displays moving images or still images captured by the image sensor 1002. The recording unit 1006 records the moving images or the still images captured by the image sensor 1002 in a recording medium such as a hard disk or a semiconductor memory.

The operation unit 1007 issues operation commands for various functions of the image sensor 1000 in response to operations by a user. The power source unit 1008 appropriately supplies various types of power serving as operation power for the DSP circuit 1003, the frame memory 1004, the display unit 1005, the recording unit 1006, and the operation unit 1007, to those units.

An image sensor 1 including pixels 12 according to Embodiments 1 to 19 can be applied to a part of the imaging device illustrated in FIG. 97.

### Example of Application in Endoscopic Surgery System

The technique according to the present disclosure (the present technique) can be applied in various products. For example, the technique according to the present disclosure may be applied in an endoscopic surgery system.

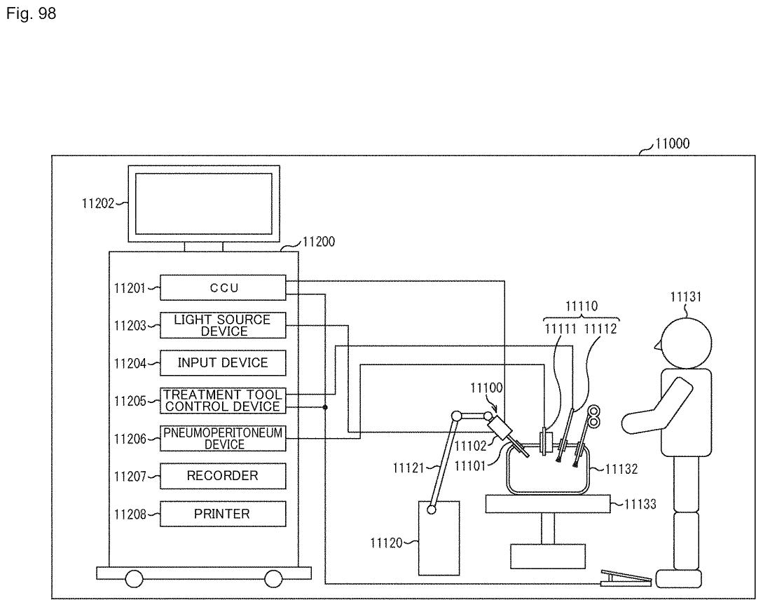

FIG. 98 is a diagram illustrating an example of the schematic configuration of an endoscopic surgery system to which the technique according to the present disclosure (the present technique) is applied.

FIG. 98 illustrates a state where an operator (doctor) 11131 is using an endoscopic surgery system 11000 to perform a surgical operation on a patient 11132 laying on a patient bed 11133. As illustrated here, the endoscopic surgery system 11000 is constituted by an endoscope 11100, another surgical instrument 11110 such as a pneumoperitoneum tube 11111 or an energized treatment tool 11112, a support arm device 11120 that supports the endoscope 11100, and a cart 11200 mounted with various devices for endoscopic surgery.

The endoscope 11100 includes a lens barrel 11101, of which a region having a predetermined length from a tip thereof is inserted into a body cavity of the patient 11132, and a camera head 11102 connected to a base end of the lens barrel 11101. In the example illustrated here, the endoscope 11100 is configured as what is known as a rigid endoscope having a rigid lens barrel 11101, but the endoscope 11100 may be configured as what is known as a flexible endoscope having a flexible lens barrel.

The tip of the lens barrel 11101 is provided with an opening into which an objective lens is fitted. A light source device 11203 is connected to the endoscope 11100, light generated by the light source device 11203 is guided to the tip of the lens barrel 11101 by a light guide provided extending along the inside of the lens barrel 11101, and the light is emitted toward an observation target in the body cavity of the patient 11132 through the objective lens. The endoscope 11100 may be a direct-view endoscope, an oblique-view endoscope, or a side-view endoscope.

An optical system and an image sensor are provided inside of the camera head 11102, and reflected light (observation light) from the observation target is focused on the image sensor by the optical system. The observation light is photoelectrically converted by the image sensor, and an electrical signal corresponding to the observation light, i.e., an image signal corresponding to an observation image, is generated. The image signal is transmitted to a camera control unit (CCU) 11201 as RAW data.

The CCU 11201 is constituted by a central processing unit (CPU), a graphics processing unit (GPU), and the like, and comprehensively controls the operations of the endoscope 11100 and a display device 11202. In addition, the CCU 11201 receives an image signal from the camera head 11102 and performs various types of image processing on the image signal to display an image based on the image signal, such as, for example, development processing (demosaicing) and the like.

The display device 11202 displays the image based on the image signal subjected to the image processing by the CCU 11201 under the control of the CCU 11201.

The light source device 11203 is constituted by, for example, a light source such as a light emitting diode (LED), and supplies the endoscope 11100 with emitted light when capturing an image of a surgical site or the like.

An input device 11204 is an input interface for the endoscopic surgery system 11000. The user can input various types of information or instructions to the endoscopic surgery system 11000 through the input device 11204. For example, the user inputs an instruction to change image capturing conditions (the type of emitted light, the magnification, the focal length, or the like) of the endoscope 11100.

A treatment tool control device 11205 controls driving of the energized treatment tool 11112 for the cauterization or incision of tissues, sealing blood vessels, or the like. The pneumoperitoneum device 11206 sends a gas into the body cavity of the patient 11132 through the pneumoperitoneum tube 11111 in order to inflate the body cavity and secure a field of view for the endoscope 11100 and a working space of the operator. A recorder 11207 is a device capable of recording various types of information pertaining to the surgery. A printer 11208 is a device capable of printing various types of information pertaining to the surgery in various formats such as text, images, and graphs.

The light source device 11203 that supplies the endoscope 11100 with the emitted light for capturing images of the surgical site can be constituted by, for example, an LED, a laser light source, or a white light source constituted by a combination thereof. When a white light source is constituted by a combination of RGB laser light sources, the output intensity and output timing of each color (each wavelength) can be controlled with high precision, and thus the white balance of the captured image can be adjusted in the light source device 11203. In this case, by irradiating the observation target with laser light from each of the RGB laser light sources in time-division and controlling the driving of the image sensor in the camera head 11102 in synchronization with that irradiation timing, images corresponding to each of the RGB colors can be captured in time-division as well. According to this method, color images can be obtained even without providing the image sensor with a color filter.

In addition, the driving of the light source device 11203 may be controlled to change the intensity of the output light every predetermined interval. By controlling the driving of the image sensor of the camera head 11102 and obtaining an image through time-division in synchronization with the timing at which the intensity of the light is changed, and then compositing those images, a high-dynamic range image without blocked-up shadows or blowouts can be generated.

The light source device 11203 may be configured to supply light in a predetermined wavelength band corresponding to special light observation. In the special light observation, for example, by emitting light in a band narrower than that of emitted light during normal observation (that is, white light) using wavelength dependence of light absorption in a body tissue, what is known as narrow band light observation (narrow band imaging) in which a predetermined tissue such as a blood vessel in a mucous membrane surface layer is imaged with a high contrast is performed. Alternatively, in special light observation, fluorescence observation may be used to obtain an image from fluorescence generated by emitting excitation light. In fluorescence observation, body tissue is irradiated with excitation light and the fluorescence from the body tissue is observed (autofluorescence observation), or a reagent such as indocyanine green (ICG) is injected into the body tissue and the tissue is irradiated with excitation light corresponding to the fluorescence wavelength of the reagent to obtain a fluorescent image. The light source device 11203 can be configured to supply narrow-band and/or excitation light corresponding to such special light observation.

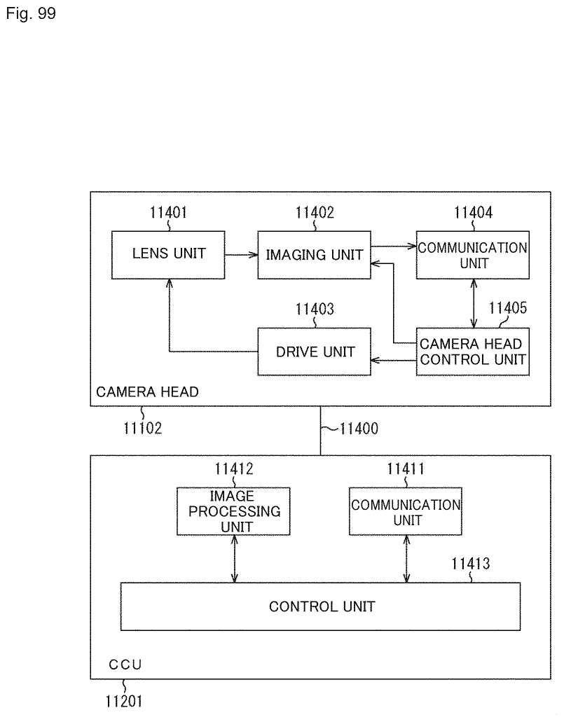

FIG. 99 is a block diagram illustrating an example of functional configurations of the camera head 11102 and the CCU 11201 illustrated in FIG. 98.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection part for connection to the lens barrel 11101. Observation light taken in from the tip of the lens barrel 11101 is guided to the camera head 11102 and is incident on the lens unit 11401. The lens unit 11401 is configured as a combination of a plurality of lenses including a zoom lens and a focus lens.

The image sensor constituting the imaging unit 11402 may be a single element (what is known as a single-plate type) or a plurality of elements (what is known as a multi-plate type). When the imaging unit 11402 is configured as a multi-plate type, for example, image signals corresponding to each color of R, G, and B may be generated by the image sensors, and a color image may be obtained by compositing the image signals. Alternatively, the imaging unit 11402 may be configured to include a pair of image sensors for obtaining image signals for the right eye and the left eye, respectively, so as to implement a three-dimensional (3D) display. Implementing a 3D display enables the operator 11131 to ascertain the depth of biological tissues in the surgical site more accurately. When the imaging unit 11402 is configured as a multi-plate type, a plurality of lens units 11401 may be provided so as to correspond to the respective image sensors.

The imaging unit 11402 does not necessarily have to be provided in the camera head 11102. For example, the imaging unit 11402 may be provided immediately after the objective lens inside of the lens barrel 11101.

The drive unit 11403 is constituted by an actuator, and the zoom lens and the focus lens of the lens unit 11401 are moved by a predetermined distance along an optical axis under the control of the camera head control unit 11405. The magnification and focus of the image captured by the imaging unit 11402 can therefore be adjusted appropriately.

The communication unit 11404 is constituted by a communication device for exchanging various types of information with the CCU 11201. The communication unit 11404 transmits the image signal obtained from the imaging unit 11402 as RAW data to the CCU 11201 over the transmission cable 11400.

The communication unit 11404 receives a control signal for controlling the driving of the camera head 11102 from the CCU 11201 and supplies that control signal to the camera head control unit 11405. The control signal includes, for example, information regarding image capturing conditions, such as information indicating a designation of a framerate of a captured image, information indicating a designation of an exposure value when an image is captured, and/or information indicating a designation of the magnification and the focus of the captured image.

The image capturing conditions such as the framerate, the exposure value, the magnification, and the focus may be designated by the user as appropriate, or may be automatically set by the control unit 11413 of the CCU 11201 on the basis of the obtained image signal. In the latter case, what are known as an auto exposure (AE) function, an auto focus (AF) function, and an auto white balance (AWB) function are provided in the endoscope 11100.

The camera head control unit 11405 controls the driving of the camera head 11102 on the basis of on a control signal from the CCU 11201 received via the communication unit 11404.

The communication unit 11411 is constituted by a communication device that exchanges various kinds of information with the camera head 11102. The communication unit 11411 receives an image signal transmitted over the transmission cable 11400 from the camera head 11102.

The communication unit 11411 also transmits control signals for controlling the driving of the camera head 11102 to the camera head 11102. The image signals and the control signals can be transmitted through electric communication, optical communication, or the like.

The image processing unit 11412 performs various types of image processing on the image signal that is the RAW data transmitted from the camera head 11102.

The control unit 11413 performs various types of control pertaining to capturing images of a surgical site by the endoscope 11100, displaying captured images obtained by capturing images of a surgical site, or the like. For example, the control unit 11413 generates control signals for controlling the driving of the camera head 11102.

In addition, the control unit 11413 causes the display device 11202 to display a captured image showing a surgical site or the like on the basis of an image signal subjected to the image processing by the image processing unit 11412. At this time, the control unit 11413 may recognize various objects in the captured image using various image recognition techniques. For example, the control unit 11413 can recognize a surgical instrument such as forceps, a specific biological site, bleeding, mist or the like produced when using the energized treatment tool 11112, or the like by detecting a shape, a color, or the like of an edge of an object present in the captured image. When causing the display device 11202 to display a captured image, the control unit 11413 may superimpose various types of surgery support information on an image of the surgical site for display using a result of the recognition. Displaying the surgery support information in a superimposed manner and presenting that information to the operator 11131 makes it possible to lighten the burden on the operator 11131 and enable the operator 11131 to proceed with the surgery with confidence.

The transmission cable 11400 that connects the camera head 11102 and the CCU 11201 is an electrical signal cable that supports communication of electrical signals, an optical fiber that supports optical communication, or a composite cable thereof.

Although wired communication is performed using the transmission cable 11400 in the example illustrated here, the camera head 11102 and the CCU 11201 may communicate wirelessly.

### Example of Application in Moving Body

The technique according to the present disclosure (the present technique) can be applied in various products. For example, the technique according to the present disclosure may be realized as a device mounted on any type of moving body, such as an automobile, an electric automobile, a hybrid electric automobile, a motorcycle, a bicycle, a personal mobility device, an airplane, a drone, a ship, a robot, or the like.

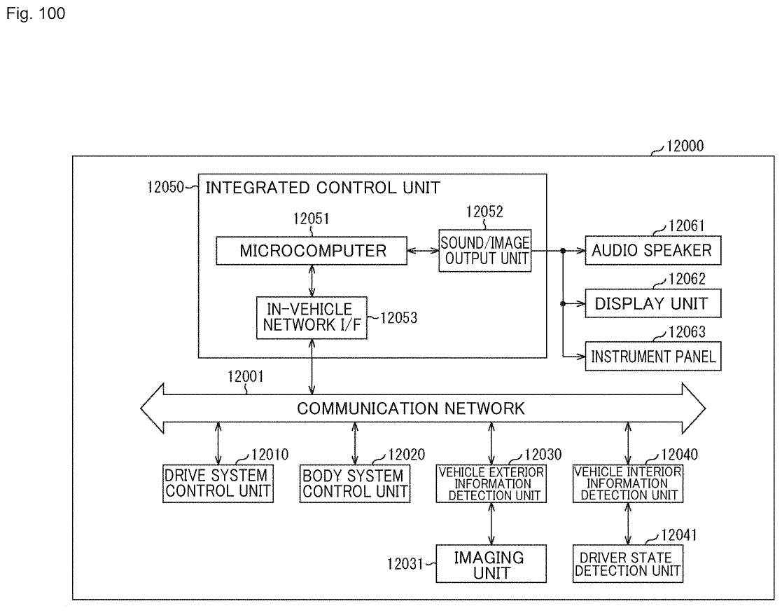

FIG. 100 is a block diagram schematically illustrating an example of the configuration of a vehicle control system, which is an example of a moving body control system to which the technique according to the present disclosure can be applied.

A vehicle control system 12000 includes a plurality of electronic control units connected over a communication network 12001. In the example illustrated in FIG. 100, the vehicle control system 12000 includes a drive system control unit 12010, a body system control unit 12020, a vehicle exterior information detection unit 12030, a vehicle interior information detection unit 12040, and an integrated control unit 12050. In addition, a microcomputer 12051, a sound/image output unit 12052, and an in-vehicle network interface (I/F) 12053 are illustrated as functional configurations of the integrated control unit 12050.

The drive system control unit 12010 controls operations of devices related to a drive system of the vehicle according to various types of programs. For example, the drive system control unit 12010 functions as control devices, such as a driving force generation device for generating driving force for the vehicle, such as an internal combustion engine or a driving motor; a driving force transmission mechanism for transmitting driving force to wheels; a steering mechanism for adjusting a turning angle of the vehicle; a braking device that generates braking force for the vehicle; and the like.

The body system control unit 12020 controls operations of various devices mounted in the vehicle body according to various programs. For example, the body system control unit 12020 functions as control devices for a keyless entry system, a smart key system, power window devices, or various lamps such as headlights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle exterior information detection unit 12030 detects information on the exterior of the vehicle in which the vehicle control system 12000 is installed. For example, an imaging unit 12031 is connected to the vehicle exterior information detection unit 12030. The vehicle exterior information detection unit 12030 causes the imaging unit 12031 to capture an image of the exterior of the vehicle, and receives the captured image. The vehicle exterior information detection unit 12030 may perform object detection processing or distance detection processing for people, cars, obstacles, traffic signs, letters on the road, and the like on the basis of the received image.

The imaging unit 12031 is an optical sensor that receives light and outputs an electrical signal according to the intensity of the received light. The imaging unit 12031 can also output the electrical signal as an image or as distance measurement information. In addition, the light received by the imaging unit 12031 may be visible light or non-visible light such as infrared light.

The vehicle interior information detection unit 12040 detects information on the interior of the vehicle. For example, a driver state detection unit 12041 that detects a state of a driver is connected to the vehicle interior information detection unit 12040. The driver state detection unit 12041 includes, for example, a camera that captures an image of the driver, and the vehicle interior information detection unit 12040 may calculate the level of the driver's fatigue or concentration, or may determine whether the driver is dozing, on the basis of detection information input from the driver state detection unit 12041.

For example, the microcomputer 12051 can calculate control target values for the driving force generation device, the steering mechanism, or the braking device on the basis of information on the inside and outside of the vehicle obtained by the vehicle exterior information detection unit 12030 and the vehicle interior information detection unit 12040, and output control commands to the drive system control unit 12010. For example, the microcomputer 12051 can perform coordinated control for the purpose of implementing functions of an Advanced Driver Assistance System (ADAS) including vehicle collision avoidance, impact mitigation, following traveling based on an inter-vehicle distance, cruise control, vehicle collision warnings, and lane departure warnings.

In addition, the microcomputer 12051 can perform coordinated control for the purpose of automated driving or the like in which autonomous travel is performed without requiring operations of the driver, by controlling the driving force generation device, the steering mechanism, the braking device, or the like on the basis of information about the surroundings of the vehicle, the information being obtained by the vehicle exterior information detection unit 12030 or the vehicle interior information detection unit 12040.

In addition, the microcomputer 12051 can output control commands to the body system control unit 12030 on the basis of the information on the exterior of the vehicle obtained by the vehicle exterior information detection unit 12030. For example, the microcomputer 12051 can perform coordinated control for the purpose of suppressing glare, such as switching from high beams to low beams by controlling the headlights according to the position of a preceding vehicle or an oncoming vehicle detected by the vehicle exterior information detection unit 12030.

The sound/image output unit 12052 transmits an output signal of at least one of sound and an image to an output device capable of visually or audibly providing information to an occupant or to the exterior of the vehicle. In the example illustrated in FIG. 100, an audio speaker 12061, a display unit 12062, and an instrument panel 12063 are illustrated as examples of the output device. The display unit 12062 may include at least one of an on-board display and a heads-up display, for example.

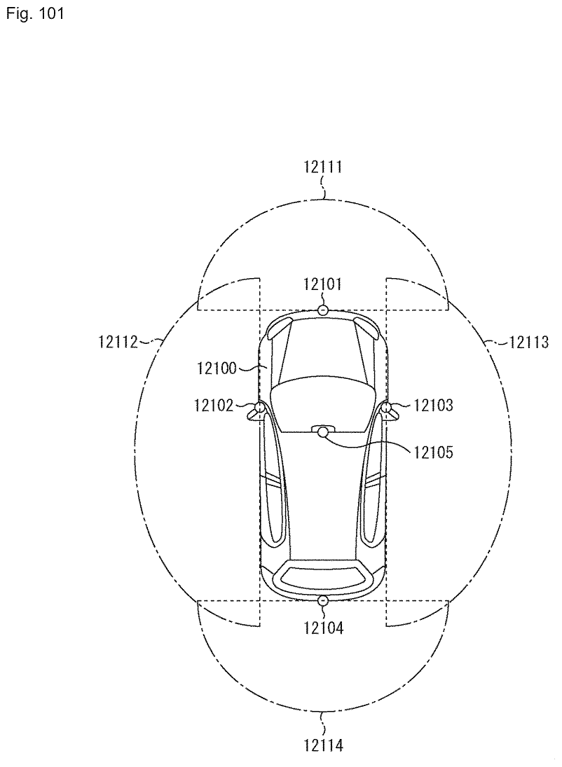

FIG. 101 is a diagram illustrating an example of an installation position of the imaging unit 12031.

In FIG. 101, the imaging unit 12031 includes imaging units 12101, 12102, 12103, 12104, and 12105.

The imaging units 12101, 12102, 12103, 12104, and 12105 are provided at the positions of the front nose, the side-view mirrors, the rear bumper, the trunk door, an upper part of the windshield within the vehicle cabin, and the like of a vehicle 12100, for example. The imaging unit 12101 provided on the front nose and the imaging unit 12105 provided in an upper part of the windshield within the vehicle cabin mainly obtain images from in front of the vehicle 12100. The imaging units 12102 and 12103 provided in the side-view mirrors mainly obtain images from the sides of the vehicle 12100. The imaging unit 12104 provided on the rear bumper or the trunk door mainly obtains images of an area behind the vehicle 12100. The imaging unit 12105 provided on an upper part of the windshield within the vehicle cabin is mainly used for detecting preceding vehicles, pedestrians, obstacles, traffic signals, traffic signs, lanes, and the like.

FIG. 101 illustrates an example of imaging ranges of the imaging units 12101 to 12104. An imaging range 12111 indicates an imaging range of the imaging unit 12101 provided on the front nose; imaging ranges 12112 and 12113 respectively indicate the imaging ranges of the imaging units 12102 and 12103 provided in the side-view mirrors; and an imaging range 12114 indicates the imaging range of the imaging unit 12104 provided on the rear bumper or the trunk door. For example, by superimposing image data captured by the imaging units 12101 to 12104, it is possible to obtain a bird's-eye view image seen from above the vehicle 12100.

At least one of the imaging units 12101 to 12104 may have a function for obtaining distance information. For example, at least one of the imaging units 12101 to 12104 may be a stereo camera constituted by a plurality of image sensors, or may be an image sensor that has pixels for phase difference detection.

For example, the microcomputer 12051 can extract, in particular, a closest three-dimensional object on a path through which the vehicle 12100 is traveling, which is a three-dimensional object traveling at a predetermined speed (e.g., at least 0 km/h) in substantially the same direction as the vehicle 12100, as a preceding vehicle by obtaining a distance to each three-dimensional object in the imaging ranges 12111 to 12114 and temporal changes in the distance (a relative speed with respect to the vehicle 12100) based on distance information obtained from the imaging units 12101 to 12104. The microcomputer 12051 can also set an inter-vehicle distance to the preceding vehicle to be maintained in advance and perform automatic braking control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects as two-wheeled vehicles, normal vehicles, large vehicles, pedestrians, and other three-dimensional objects such as electrical poles based on the distance information obtained from the imaging units 12101 to 12104, and can use the three-dimensional data to automatically avoid obstacles. For example, the microcomputer 12051 classifies obstacles around the vehicle 12100 into obstacles visible to the driver of the vehicle 12100 and obstacles which are difficult to see. Then, the microcomputer 12051 determines a collision risk indicating the degree of risk of collision with each obstacle, and when the collision risk is at least a set value and there is a possibility of a collision, an alarm is output to the driver through the audio speaker 12061 or the display unit 12062, forced deceleration or avoidance steering is performed through the drive system control unit 12010, and the like, making it possible to provide driving assistance for collision avoidance.

At least one of the imaging units 12101 to 12104 may be an infrared camera that detects infrared rays. For example, the microcomputer 12051 can recognize a pedestrian by determining whether there is a pedestrian in an image captured by the imaging units 12101 to 12104. Such pedestrian recognition is performed by, for example, a sequence in which feature points in the images captured by the imaging units 12101 to 12104 as infrared cameras are extracted and a sequence in which pattern matching processing is performed on a series of feature points indicating an outline of an object to determine whether the object is a pedestrian. When the microcomputer 12051 determines that there is a pedestrian in the image captured by the imaging units 12101 to 12104 and the pedestrian is recognized, the sound/image output unit 12052 controls the display unit 12062 such that a square contour line for emphasis is superimposed on and displayed with the recognized pedestrian. In addition, the sound/image output unit 12052 may control the display unit 12062 such that an icon indicating a pedestrian or the like is displayed at a desired position.

System as used herein refers to an entire device constituted by a plurality of devices.

The effects described herein are merely examples and are not intended to be limiting, and other effects may be obtained.

Embodiments of the present technique are not limited to the above-described embodiments, and various modifications can be made within the scope of the present technique without departing from the essential spirit of the present technique.

The present technique can also be configured as follows.

(1)

A semiconductor substrate including:
an insulating film;
an electrode that is bonded to an electrode provided on another semiconductor substrate when the semiconductor substrate is affixed to the other semiconductor substrate, the electrode being provided in the insulating film;
a barrier metal that is provided between the insulating film and the electrode; and
a film that is provided between the barrier metal and the electrode.
   (2)

The semiconductor substrate according to (1),
wherein a first adhesion strength when a first material constituting the electrode and a second material constituting the film are adhered is less than a second adhesion strength when the first material and a third material constituting the barrier metal are adhered.
   (3)

The semiconductor substrate according to (2),
wherein the first material is copper, and the second material is any one of indium tin oxide (ITO), SiO2 formed by plasma deposition, or SiO formed by atomic layer deposition (ALD).
   (4)

The semiconductor substrate according to (1),
wherein a material constituting the film is a material having a coefficient of friction that is less than a coefficient of friction of a material constituting the electrode.
   (5)

The semiconductor substrate according to (4),
wherein the film is any one of carbon, molybdenum disulfide, tungsten disulfide, tungsten selenide, hafnium sulfide, boron nitride, or a composition having carbon as a principal component, the composition including graphite, graphene, fullerene, carbon nanotubes, diamond-like carbon, or diamond.
   (6)

The semiconductor substrate according to (4),
wherein the coefficient of friction of the film is no greater than 0.2 (p).
   (7)

The semiconductor substrate according to (1),
wherein a material constituting the film is a material having a potential that is higher than a potential of a material constituting the electrode.
   (8)

The semiconductor substrate according to (7),
wherein the material constituting the film is any one of graphite, platinum, zirconium, titanium, silver, nickel, or an alloy having one thereof as a principal component.
   (9)

The semiconductor substrate according to (1),
wherein a material constituting the film is a material having a coefficient of thermal expansion that is greater than a coefficient of thermal expansion of a material constituting the electrode.
   (10)

The semiconductor substrate according to (9),
wherein the material constituting the film is any one of a resin, a metal, or an insulating material.
   (11)

The semiconductor substrate according to (9),
wherein the material constituting the film is any one of polyimide, epoxy resin, fluorine resin, aluminum, tin, zinc, lead, magnesium, solder, lithium titanium oxide (LTO), or Low-k.
   (12)

The semiconductor substrate according to (1),
wherein the film is provided on a side wall of the electrode and is formed of a material that inhibits growth of plating of the copper.
   (13)

The semiconductor substrate according to (12),
wherein the material constituting the film is any one of SiO₂, Ta₂O₅, TiO₂, SiN, SiCN, or SiOF.
   (14)

The semiconductor substrate according to (12),
wherein the side wall of the electrode is formed in a reverse-tapered shape.
   (15)

The semiconductor substrate according to any one of (1) to (14),
wherein a material constituting the electrode is copper, and at least an uppermost surface of the electrode is a (111) surface.
   (16)

The semiconductor substrate according to any one of (1) to (15),
wherein the film is provided on a side face of the electrode.
   (17)

The semiconductor substrate according to any one of (1) to (15),
wherein the film is provided on a side face and a bottom face of the electrode.
   (18)

A semiconductor substrate including:
an insulating film;
an electrode that is bonded to an electrode provided on another semiconductor substrate when the semiconductor substrate is affixed to the other semiconductor substrate, the electrode being provided in the insulating film; and
a barrier metal that is provided between the insulating film and the electrode,
wherein an inclination of the barrier metal that is provided on one side wall of the electrode is different from an inclination of the barrier metal that is provided on another side wall of the electrode.
   (19)

The semiconductor substrate according to (18),
wherein a material constituting the electrode is copper, and at least an uppermost surface of the electrode is a (111) surface.

### REFERENCE SIGNS LIST

1 Imaging device
11 First substrate
12 Pixel
13 Pixel region
14 Pixel drive line
15 Vertical signal line
21 Second substrate
22 Vertical drive circuit
23 Column signal processing circuit
24 Horizontal drive circuit
25 System control circuit
30 First semiconductor substrate
31 First interconnect layer
32 Second interconnect layer
33 Si substrate
34 Transistor
35 Photoelectric conversion layer
36 Color filter
37 Microlens
38 Insulating film
39 Interlayer insulating film
40 Second semiconductor substrate
41 Diffusion prevention film
42 Diffusion prevention film
43 Interlayer insulating film
54 First electrode pad
55 Dummy electrode
57 Second electrode pad
58 Dummy electrode
81 Reaction film
100 Stacked film
101 Interlayer insulating film
102 Liner insulating film
103 Interlayer insulating film
104 Barrier metal
105 Electrode
107 Barrier metal
108 Dummy electrode
121 Connection hole
122 Interconnect hole
123 Connection hole
131 Expansion inhibition suppression film
221 Insulating film
261 Via
301 Trench
381 Reaction film
500 Insulating film
511 Expansion support film
512 Interlayer film
551 Oxide film
601 (111) region
602 Random region
621 Cu seed
622 Plating inhibition film
631 Side wall region
641, 661 Resist pattern
663 Plasma film
723 Insulating film

1. A semiconductor substrate comprising:
an insulating film;
an electrode that is bonded to an electrode provided on another semiconductor substrate when the semiconductor substrate is affixed to the other semiconductor substrate, the electrode being provided in the insulating film;
a barrier metal that is provided between the insulating film and the electrode; and
a film that is provided between the barrier metal and the electrode.

2. The semiconductor substrate according to claim 1,
wherein a first adhesion strength when a first material constituting the electrode and a second material constituting the film are adhered is less than a second adhesion strength when the first material and a third material constituting the barrier metal are adhered.

3. The semiconductor substrate according to claim 2,
wherein the first material is copper, and the second material is any one of indium tin oxide (ITO), SiO2 formed by plasma deposition, or SiO formed by atomic layer deposition (ALD).

4. The semiconductor substrate according to claim 1,
wherein a material constituting the film is a material having a coefficient of friction that is less than a coefficient of friction of a material constituting the electrode.

5. The semiconductor substrate according to claim 4,
wherein the film is any one of carbon, molybdenum disulfide, tungsten disulfide, tungsten selenide, hafnium sulfide, boron nitride, or a composition having carbon as a principal component, the composition including graphite, graphene, fullerene, carbon nanotubes, diamond-like carbon, or diamond.

6. The semiconductor substrate according to claim 4,
wherein the coefficient of friction of the film is no greater than 0.2 (μ).

7. The semiconductor substrate according to claim 1,
wherein a material constituting the film is a material having a potential that is higher than a potential of a material constituting the electrode.

8. The semiconductor substrate according to claim 7,
wherein the material constituting the film is any one of graphite, platinum, zirconium, titanium, silver, nickel, or an alloy having one thereof as a principal component.

9. The semiconductor substrate according to claim 1,
wherein a material constituting the film is a material having a coefficient of thermal expansion that is greater than a coefficient of thermal expansion of a material constituting the electrode.

10. The semiconductor substrate according to claim 9,
wherein the material constituting the film is any one of a resin, a metal, or an insulating material.

11. The semiconductor substrate according to claim 9,
wherein the material constituting the film is any one of polyimide, epoxy resin, fluorine resin, aluminum, tin, zinc, lead, magnesium, solder, lithium titanium oxide (LTO), or Low-k.

12. The semiconductor substrate according to claim 1,
wherein the film is provided on a side wall of the electrode and is formed of a material that inhibits growth of plating of the copper.

13. The semiconductor substrate according to claim 12,
wherein the material constituting the film is any one of SiO₂, Ta₂O₅, TiO₂, SiN, SiCN, or SiOF.

14. The semiconductor substrate according to claim 12,
wherein the side wall of the electrode is formed in a reverse-tapered shape.

15. The semiconductor substrate according to claim 1,
wherein a material constituting the electrode is copper, and at least an uppermost surface of the electrode is a (111) surface.

16. The semiconductor substrate according to claim 1,
wherein the film is provided on a side face of the electrode.

17. The semiconductor substrate according to claim 1,
wherein the film is provided on a side face and a bottom face of the electrode.

18. A semiconductor substrate comprising:
an insulating film;
an electrode that is bonded to an electrode provided on another semiconductor substrate when the semiconductor substrate is affixed to the other semiconductor substrate, the electrode being provided in the insulating film; and
a barrier metal that is provided between the insulating film and the electrode,
wherein an inclination of the barrier metal that is provided on one side wall of the electrode is different from an inclination of the barrier metal that is provided on another side wall of the electrode.

19. The semiconductor substrate according to claim 18,
wherein a material constituting the electrode is copper, and at least an uppermost surface of the electrode is a (111) surface.
